(19) United States
(12) Patent Application Publication
(10) Pub. No.: US 2010/0039028 A1
(43) Pub. Date: Feb. 18, 2010

(54) DISPLAY DEVICE

(75) Inventors: Shigekazu SUZUKI, Shizuoka-ken (JP); Keisuke MATSUMOTO, Shizuoka-ken (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/535,697

(22) Filed: Aug. 5, 2009

(30) Foreign Application Priority Data
Aug. 15, 2008 (JP) 2008-209375

(51) Int. Cl. H01J 1/63

(52) U.S. Cl. 313/504

(57) ABSTRACT

A display device includes an organic light-emitting device and red, green and blue color filter layers, wherein each of the color filter layers contains a pigment, a pigment derivative and a dispersant, the pigment contained in a colored pattern constituting the green color filter layer contains Pigment Yellow 185 and at least one of an aluminum phthalocyanine or Pigment Green 7, and the concentration of the pigment in the green filter layer is 60% or less.

### CROSS-REFERENCE TO RELATED APPLICATION

This application claims priority under 35 USC 119 from Japanese Patent Application No. 2008-209375 filed on Aug. 15, 2008, the disclosure of which is incorporated by reference herein.

### BACKGROUND OF THE INVENTION

1. Field of the Invention

The invention relates to a display device including an organic electroluminescent device and color filter layers.

2. Description of the Related Art

An organic electroluminescent (EL) device, which is also called an organic light-emitting diode (LED) device, has a configuration in which an organic layer containing a light-emitting material is sandwiched between an anode and a cathode and light is emitted by conducting electricity between the electrodes. Specifically, holes and electrons injected by each of opposing electrodes are combined in an emitting layer to give energy, whereby a light-emitting material in the emitting layer is excited to emit light having a color depending on the light-emitting material. The organic EL display device having such an organic EL device is a self-light-emitting display device, and thus has a wide viewing angle and a high response speed. This display device does not require a backlight, enabling the display device to be thinner and lighter. For these reasons, the organic EL display device has drawn attention in recent years as a display device to replace a liquid crystal display device and is coming into use in various fields such as cell phones, in-vehicle devices, and PDAs (personal digital assistants). Organic EL display devices are used mainly as small- to middle-sized devices but are also being developed for application to large-screen TVs (see, for example, Michael Long, “Cost Competitive Vacuum Deposition Technology for Small Molecule OLED Manufacturing” SID 08 DIGEST, p. 508, 2008).

For improving color purity and producing vivid colors in an organic EL display, a method in which light emitted from an emitting layer is displayed through a color filter has also been examined in recent years.

Known methods of allowing an organic EL display to serve as a full-color type display include a 3-color light-emitting method in which organic EL devices that can emit lights corresponding to each of the three primary colors (blue (B), green (G) and red (R)) are disposed respectively on a substrate, a white-color method in which a white light emitted by a white light-emitting organic EL device is divided into the three primary colors via color filters, and a color conversion method of converting a blue light emitted by a blue light-emitting organic EL device, through a fluorescent dye layer, into red (R) and green (G) lights, as shown in for example “Gekkan Display” (Display Monthly), September 2000, pp. 33 to 37.

To increase the NTSC ratio, the color purity of each filter segment should be increased. However, when the color purity is increased, the light use efficiency (expressed as luminosity Y value) of a backlight is decreased. Therefore, there has been a problem of higher power consumption.

In order to address the above, it is effective to use a pigment formed into fine particles having a small primary particle diameter. The method of forming a pigment into fine particles having a small primary particle diameter includes a method in which a pigment, together with a synthetic resin that is solid at room temperature and insoluble in water, a water-soluble inorganic salt such as sodium chloride, and a water-soluble organic solvent that can partially dissolve the synthetic resin, is mechanically kneaded by using a kneader or the like (hereinafter, kneading of a mixture containing a pigment, a water-soluble inorganic salt and a water-soluble organic solvent is referred to as “salt milling”) and then washed with water to remove the water-soluble inorganic salt and the water-soluble organic solvent (see, for example, Japanese Patent Application Laid-Open (JP-A) Nos. 2004-258586 and 2004-265752). This method allows pulverization of primary particles of the pigment and crystal growth of the pigment to occur simultaneously, thus giving a final pigment with a narrow particle-diameter distribution and with a small surface area for its small average particle diameter. Therefore, this is method suitable for application of a pigment to a color filter or the like where a pigment having a small particle diameter should be dispersed at high density.

However, if the crystal growth rate in salt milling is high, the pigment produced in this way may instead have a large primary particle diameter, and may also cause significant aggregation in a drying process after desalting. Therefore, forming the pigment into desired fine particles has been difficult. When such pigments are used in a display device, the display device has a strong light shielding property and low transmittance, so that there easily arises a problem of reduction in the light use efficiency (expressed as luminosity Y value) of the display device.

As described above, improving color reproducibility and improving luminance in a full-color display have conventionally had a trade-off relationship, and it has been long desired to satisfy both of these major two functions of a display.

When a technique of combining the organic EL device with color filters is used, it is possible to satisfy both high color reproducibility and high luminance. However, the organic EL display device using such light sources has the problem that an image observed in an oblique direction is significantly darker than when observed in a normal direction. It is also noted that when an image is observed in the normal direction and then observed in an oblique direction, the hue of the image is changed. Therefore, there is room for improvement in these respects. To reduce the influence of the direction of observation on the viewing experience, proposals have been made from the viewpoint of improving the structure of a device (see JP-A No. 2007-27042) and the effects thereof have been demonstrated. However, all of these methods increase the complexity of the device resulting in higher costs, and so there has been desire for improvement by an easier method.

Color filter materials developed for liquid crystal displays can be applied to an organic EL display device in a color filter system. Among the pixels for the three primary colors (blue (B), green (G) and red (R)), the pixel for green (G) often uses C.I. Pigment Green 36. This pigment was considered advantageous in that by making the pigment fine, transmittance is improved and high luminance is attained, but was found to be insufficient for satisfying high color reproducibility and high luminance in the organic EL display device. Accordingly, there has been demand for a color filter satisfying high color reproducibility and high luminance in an organic EL display device.

### SUMMARY OF THE INVENTION

The invention was made in view of the problems in the related art described above.

The invention provides a display device including an organic electroluminescent (EL) device and a color filter with high transmittance and excellent color reproducibility.

As a result of extensive study, the inventors found that, in a display device including a specific light-emitting device, a fine-grained, treated pigment can be obtained by selecting a specific pigment, and, in a preferable embodiment, adding a specific pigment derivative when salt-milling of the pigment, and found that the effect is more conspicuous when this pigment is dispersed using a specific dispersant.

Aspects of the invention include those described below.

<1> A display device including an organic light-emitting device and red, green and blue color filter layers, wherein each of the color filter layers contains at least a pigment, a pigment derivative and a dispersant, the pigment contained in a colored pattern constituting the green color filter layer contains Pigment Yellow 185 and at least one of an aluminum phthalocyanine or Pigment Green 7, and the concentration of the pigment in the green filter layer is 60% or less.

<2> The display device of <1>, wherein the organic light-emitting device is a light-emitting device having a peak wavelength (λ1) with the maximum emission intensity in the range of from 430 nm to 480 nm, or a light-emitting device having a first emission intensity peak wavelength (λ1′) in the range of from 430 nm to 480 nm, a second emission intensity peak wavelength (λ2) in the range of from 500 nm to 550 nm, and a third emission intensity peak wavelength (λ3) in the range of from 600 nm to 650 nm.

<3> The display device of <1> or <2>, wherein the average particle diameter of primary particles of Pigment Yellow 185 is from 10 nm to 40 nm.

<4> The display device of <3>, wherein the average particle diameter of primary particles of the at least one of an aluminum phthalocyanine or Pigment Green 7 is from 10 nm to 40 nm.

<5> The display device any one of <1> to <4>, wherein the total content of C.I. Pigment Yellow 185, aluminum phthalocyanine and C.I. Pigment Green 7 is 30 parts by mass or more with respect to the total amount of pigment contained in the green color filter layer.

<6> The display device of any one of <1> to <5>, wherein the pigment derivative is a compound represented by the following Formula (1):

A-N═N—X—Y Formula (1)

In Formula (1), A represents a component which can form an azo dye together with X—Y, wherein X represents a single bond or a group selected from divalent linking groups represented by the following structural formulae, and Y represents a group represented by the following Formula (2):

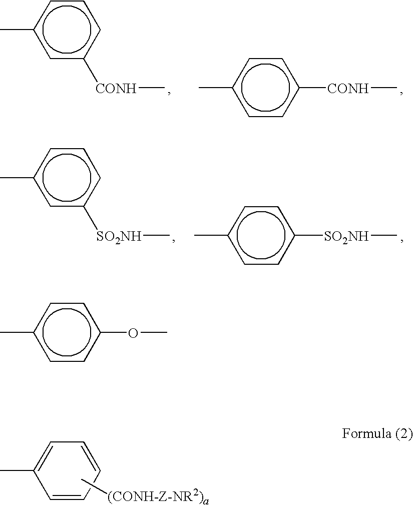

In Formula (2), Z represents an alkylene group having 1 to 5 carbon atoms, —NR² represents a dialkylamino group in which each alkyl group has 1 to 4 carbon atoms, or a saturated 5- to 6-membered heterocyclic group containing a nitrogen atom, and a represents 1 or2.

<7> The display device of any one of <1> to <6>, wherein the dispersant is a polymer compound represented by the following Formula (3):

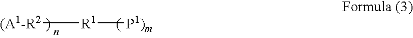

In Formula (3), R′ represents an organic linking group having a valency of (m+n), R² represents a single bond or a divalent organic linking group; A¹ represents a monovalent organic group containing at least one moiety selected from an organic dye structure, a heterocyclic structure, an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group and a hydroxyl group; each A¹, the number of which is n, may be the same as or different from each other; each R², the number of which is n, may be the same as or different from each other; m represents 1 to 8 and n represents 2 to 9 provided m+n represents 3 to 10; P¹ represents a polymer skeleton; and each P¹, the number of which is m, may be the same as or different from each other.

<8> The display device of any one of <1> to <7>, wherein the aluminum phthalocyanine is represented by the following Structural Formula (II).

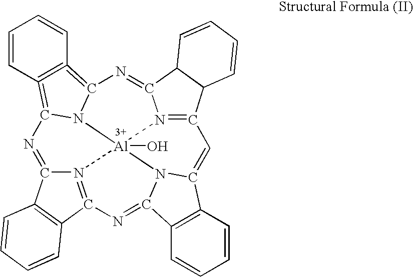

<9> The display device of any one of <1> to <8>, wherein the total content of aluminum phthalocyanine or Pigment Green 7 in the green color filter layer is from 5 parts by mass to 200 parts by mass with respect to 100 parts by mass of Pigment Yellow 185.

### BRIEF DESCRIPTION OF THE DRAWINGS

Exemplary embodiments of the present invention will be described in detail based on the following figures, wherein:

FIG. 1 is a schematic diagram including sectional and plan views, illustrating an aspect of the process of forming a second electrode layer on a substrate (steps (1) to (4) of FIG. 1) in the method for manufacturing the display device of the invention;

FIG. 2 is a schematic diagram including sectional and plan views, illustrating an aspect of the processes from formation of a third semiconductor layer to patterning of a fourth electrode layer (steps (1) to (4) of FIG. 2) in the method for manufacturing the display device of the invention;

FIG. 3 is a schematic diagram including sectional and plan views, illustrating an aspect of the processes from formation of an organic EL layer to coverage with a sealing glass (steps (1) to (4) of FIG. 3) in the method for manufacturing the display device of the invention; and

FIG. 4 is a graph showing the emission property of the organic EL layer in the display device used in the Examples.

### DETAILED DESCRIPTION OF THE INVENTION

In the display device of the invention, Pigment Yellow 185 and at least one of an aluminum phthalocyanine or Pigment Green 7 are used in combination for a colored pattern of a green color filter layer. In a preferable embodiment, an excellent effect can be achieved by using, among the above pigments, a pigment with an average primary particle diameter of from 10 nm to 40 nm, which is prepared by mechanically kneading Pigment Yellow 185 and a specific pigment derivative in the presence of a water-soluble inorganic salt and a water-soluble organic solvent, and then removing the water-soluble inorganic salt and the water-soluble organic solvent from the resulting kneaded material.

The above preferable pigment that can be used in the invention retains surface activity even though the particles thereof are the same size as those of a pigment formed into fine particles by a conventional salt milling method. Thereby, a pigment derivative is easily adsorbed to the surface of the pigment, and fine particles are easily formed.

The working mechanism of the above is not clear, but is thought to be as follows:

It is assumed that when a Pigment Yellow 185 having a large particle diameter is pulverized at high temperature into fine particles, chemical changes such as cleavage of chemical bonds on the surface of the pigment, or changes in the crystal structure occurs, making it difficult for the pigment to maintain a highly active surface on which strong interactions remain such as hydrogen bonding intrinsically possessed by its constituent pigment molecules. In a preferable embodiment of the invention, on the other hand, it is assumed that since a pigment is mechanically kneaded with a specific pigment derivative in the presence of a water-soluble inorganic salt and a water-soluble solvent, the pigment derivative can be adsorbed onto the surface of the pulverized pigment before the above chemical changes occur on the surface of the pigment, thereby preventing the crystal growth of the pigment. Accordingly, it is assumed in the invention that Pigment Yellow 185 can be formed into fine particles having an average primary particle diameter as small as 10 nm to 40 nm, whereby both excellent transmittance and color reproducibility can be obtained by a green color filter having a colored pattern in which such a pigment is dispersed.

Hereinafter, the display device of the invention will be described in detail.

The display device of the invention is a display device provided with an organic light-emitting device and red, green and blue color filter layers, in which each of the color filter layers contains at least a pigment, a pigment derivative and a dispersant, the pigment contained in a colored pattern constituting the green color filter layer contains Pigment Yellow 185 and at least one of an aluminum phthalocyanine or Pigment Green 7, and the concentration of the pigment in the green color filter layer is 60% or less. The “concentration of a pigment in a color filter layer” as used herein refers to a ratio of the weight of the pigment to the weight of the color filter layer. Hereinafter, the structure of the display device will be described.

<<Green Color Filter Layer>>

First, the green color filter layer as a characteristic structure of a display device of the invention will be described.

The green color filter layer contains at least a pigment, a pigment derivative, and a dispersant, in which the pigment contains Pigment Yellow 185 and at least one of an aluminum phthalocyanine or Pigment Green 7, and the concentration of the pigment in a cured film constituting the green colored pattern is 60% or less.

Pigment

As the pigment of the green color filter layer in the invention, Pigment Yellow 185 as a yellow pigment and at least one of an aluminum phthalocyanine or Pigment Green 7 as a green pigment are used in combination.

In the invention, Pigment Yellow 185 (yellow pigment) and at least one of an aluminum phthalocyanine pigment or Pigment Green 7 (green pigment) are used in combination as the colorant of green pixel, whereby a green color filter layer with high chromaticity and high color density and being excellent in optical transparency is obtained even when the total amount of the pigment is reduced to 60% by mass or less.

The aluminum phthalocyanine pigment is preferably a compound represented by the following Structural Formula (I):

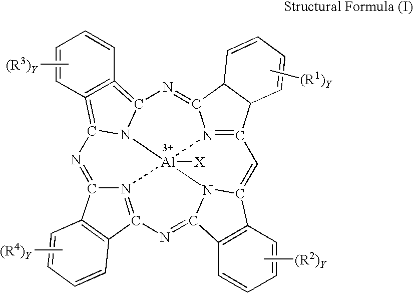

In Structural Formula (I), X represents OH, Cl or Br; R¹, R², R³ and R⁴ each independently represent a halogen atom or an alkyl group having 1 to 4 carbon atoms, and may be the same or different from each other; and Y represents an integer of from 0 to 4.

The aluminum phthalocyanine pigment is preferably a compound represented by Structural Formula (I), and may be a dimer consisting of two molecules of this compound bound to each other.

Among the aluminum phthalocyanine pigments represented by Structural Formula (I), a compound represented by the following Structural Formula (II) is more preferable. A dimer consisting of two molecules of this compound bound to each other via an oxygen atom of an OH group thereof is also preferable.

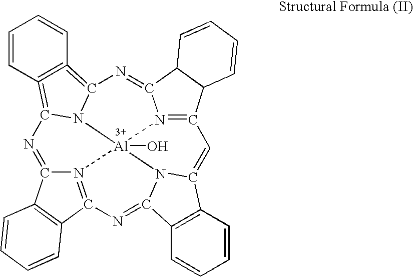

In the invention, at least one of the aluminum phthalocyanine pigment or C.I. Pigment Green 7 is used as the green pigment, which may be used in combination with an additional known green pigment. The additional known green pigment may be an organic or inorganic pigment, and examples thereof include a halogenated phthalocyanine-based pigment, such as C.I. Pigment Green 36, and C.I. Pigment Green 37. The at least one of the aluminum phthalocyanine pigment or C.I. Pigment Green 7 may be used with only one kind of additional known pigment or with two or more kinds of additional known pigments. The additional known pigment may be used in an amount of 50% by mass or less with respect to the total amount of aluminum phthalocyanine pigment and C.I. Pigment Green 7 to be used.

In the invention, C.I. Pigment Yellow 185 is used as the yellow pigment, and a known yellow pigment may be used in combination with the yellow pigment of the invention. The yellow pigment may be an organic or inorganic pigment including, for example, a pigment such as C.I. Pigment Yellow 138, C.I. Pigment Yellow 139, or C.I. Pigment Yellow 150. The known pigment may be used singly or in combination of two or more kinds thereof. The known pigment may be used in an amount of 50% by mass or less with respect to the amount of C.I. Pigment Yellow 185 to be used.

Regarding the ratio of the amount of the at least one of an aluminum phthalocyanine pigment or Pigment Green 7 (green pigment) to Pigment Yellow 185 (yellow pigment) used in the green pixel of the invention, the amount of the yellow pigment is preferably in the range of from 5 parts by mass to 200 parts by mass, more preferably in the range of from 10 parts by mass to 170 parts by mass, with respect to 100 parts by mass of the green pigment. A ratio within this range is preferable in that color reproducibility and transmittance are improved.

In consideration of color unevenness and contrast, the average primary particle diameters of the aluminum phthalocyanine pigment, C.I. Pigment Green 7 and C.I. Pigment Yellow 185 are each preferably from 10 nm to 100 nm, more preferably from 10 nm to 70 nm, still more preferably from 10 nm to 50 nm, and even preferably from 10 nm to 40 nm. When the particle diameter is within the above range, a colored photosensitive composition excellent in brightness may be provided. In order to maintain excellent dispersibility of the fine pigment particles having a particle diameter of 10 nm to 40 nm and avoid aggregation of the pigment particles, it is preferable to use a pigment derivative and a specific dispersant described in detail below in combination with the pigment particles when forming the green color filter layer in the invention.

For the measurement of the average primary particle diameter, particles are observed under SEM or TEM, the diameters of 100 particles that are present in a portion of the obtained micrograph at which aggregation of particles is not observed, and the mean value of the measured diameters is calculated to give the average primary particle diameter.

As the pigments contained in a colored photosensitive composition for forming the color filter layer of the invention, a wide variety of conventional known pigments (additional pigments) besides the pigments described above may be mixed and used in such a range that the effects of the invention are not impaired. When various pigments are mixed and used, the total content of C.I. Pigment Yellow 185, aluminum phthalocyanine and C.I. Pigment Green 7 is 30 parts by mass or more, preferably 50 parts by mass or more, and still more preferably 99 parts by mass or less, with respect to 100 parts by mass of the total pigment amount, in consideration of color density.

In the invention, the pigments described above and the additional pigments are preferably treated with various resins in advance. In general, a pigment after synthesis is dried using various methods, usually from an aqueous medium containing the pigment, and is supplied as powder. Since removal of water by drying requires great evaporative latent heat, great heat energy is supplied to the pigment when converting the pigment into dried powder. As a result, the pigment ordinarily takes a form of aggregates (secondary particles) composed of aggregated primary particles of the pigment, and the pigment in the form of such aggregates is not easily dispersed to fine particles, and therefore, treating the pigment in advance with a resin is desirable for facilitating dispersion. The resin used herein may be, for example, the alkali-soluble resin described below.

Examples of the method of dispersing the pigment include a flushing treatment and a kneading method using, for example, a kneader, an extruder, a ball mill, or a two- or three-roll mill. Among them, the flushing treatment or the kneading method using a two- or three-roll mill is preferable in respect of converting pigments into fine particles.

The flushing treatment is a method in which an aqueous dispersion of a pigment is mixed with a solution of a resin dissolved in a water-immiscible organic solvent, whereby the pigment is extracted from the aqueous medium into the organic medium and treated with the resin. This method does not involve drying the pigment and can prevent the aggregation of the pigment, thereby facilitating dispersion of the pigment. The kneading method using a two- or three-roll mill is a method in which a pigment is treated by mixing the pigment with a resin or a resin solution and then kneading the pigment with the resin under high shearing (shear force) thereby coating the surface of the pigment with the resin. By this process, the aggregated pigment particles are dispersed from the low-order aggregates to primary particles.

A processed pigment that has been treated with an acrylic resin, a vinyl chloride-vinyl acetate resin, a maleic acid resin, an ethyl cellulose resin, or a nitrocellulose resin in advance may be used as a pigment in the invention. This processed pigment is preferably in the form of a powder, paste or pellet in which a resin and a pigment are dispersed uniformly therein. A processed pigment in a nonuniform massive form in which a resin is gelled is unfavorable.

<<Red and Blue Color Filter Layers>>

Pigments used in the red and blue pixels other than the green pixel of the invention may be arbitrarily selected with a view to achieving high transmittance and high color reproducibility.

As the pigment used in the red pixel in the invention, a red pigment alone, a combination of a red pigment and a yellow pigment, or a combination of two or more kinds of red pigments may be arbitrarily selected. In an embodiment, three or more kinds of pigments are used in combination.

Examples of the red pigment include C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279;

Examples of the yellow pigment include C.I. Pigment 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214;

and C.I. Pigment Orange 2, 5, 13, 16, 17:1, 31, 34, 36, 38, 43, 46, 48, 49, 51, 52, 55, 59, 60, 61, 62, 64, 71, and 73.

As the pigment used in the blue pixel in the invention, a blue pigment alone, a combination of a blue pigment and a violet pigment, or a combination of two or more kinds of blue pigments may be arbitrarily selected. In an embodiment, three or more kinds of pigments are used in combination.

Examples of the blue pigment include C.I. Pigment Blue 1, 2, 15, 15:1, 15:2, 15:3, 15:4, 15:6, 16, 22, 60, 64, 66 and 79, a pigment obtained by substituting a Cl substituent of C.I. Pigment Blue 79 with OH, and C.I. Pigment Blue 80.

Examples of the violet pigment include C.I. Pigment Violet 1, 19, 23, 27, 32, 37, and 42.

Usable pigments are not limited to those described above, and include subphthalocyanine pigments.

<Size-Reduction Treatment of Pigment>

When forming each color filter layer in the invention, it is preferable to use a pigment having a small and uniform size, as needed.

When reducing the size of an organic pigment, it is preferable to use a method including a step of pulverizing a highly viscous liquid composition containing an organic pigment, a water-soluble organic solvent and a water-soluble inorganic salt.

In the invention, the following method is preferably used in reducing the size of an organic pigment.

In the method, first, a kneader such as a two-roll, a three-roll, a ball mill, a trommel, a disper mill, a kneader, a co-kneader, a homogenizer, a blender or a single- or twin-screw extruder is used to apply a strong shear force to a mixture (liquid composition) of an organic pigment, a water-soluble organic solvent and a water-soluble inorganic salt, thereby pulverizing the organic pigment in the mixture, and then the mixture is added into water and formed into a slurry using a stirrer or the like. Subsequently, this slurry is filtered, washed with water to remove the water-soluble organic solvent and the water-soluble inorganic salt and then dried, thereby obtaining the finely pulverized pigment described above.

Examples of the water-soluble organic solvent used in the pulverization method include methanol, ethanol, isopropanol, n-propanol, isobutanol, n-butanol, ethylene glycol, diethylene glycol, diethylene glycol monomethyl ether, diethylene glycol monoethyl ether, diethylene glycol monobutyl ether, propylene glycol, and propylene glycol monomethyl ether acetate.

Another solvent may be used as long as the solvent is used in such a small amount that the solvent is adsorbed onto the pigment and is not incorporated into waste water. Examples of another solvent include benzene, toluene, xylene, ethylbenzene, chlorobenzene, nitrobenzene, aniline, pyridine, quinoline, tetrahydrofuran, dioxane, ethyl acetate, isopropyl acetate, butyl acetate, hexane, heptane, octane, nonane, decane, undecane, dodecane, cyclohexane, methyl cyclohexane, halogenated hydrocarbons, acetone, methyl ethyl ketone, methyl isobutyl ketone, cyclohexanone, dimethylformamide, dimethylsulfoxide and N-methyl pyrrolidone. If necessary, a mixture of two or more solvents may be used.

The amount of the water-soluble organic solvent is preferably in the range of from 50% by mass to 300% by mass, more preferably in the range of from 100% by mass to 200% by mass, with respect to the organic pigment.

Examples of the water-soluble inorganic salt used in the invention include sodium chloride, potassium chloride, calcium chloride, barium chloride and sodium sulfate.

The amount of the water-soluble inorganic salt by mass is preferably from 1 to 50 times the mass of the pigment. While a higher pulverizing effect can be obtained when the water-soluble inorganic salt is used in a larger amount, the mass of the water-soluble inorganic salt is more preferably from 1 to 10 times the mass of the pigment from the viewpoint of productivity.

To prevent dissolution of the water-soluble inorganic salt, the water content of the liquid composition to be subjected to pulverization is preferably 1% or less.

When the liquid composition containing a pigment, a water-soluble organic solvent and a water-soluble inorganic salt is subjected to pulverization in the invention, a wet grinding apparatus such as the kneader described above may be used. The operation conditions of the wet grinding apparatus are not particularly limited. Regarding the operation conditions when a kneader is used as the grinding apparatus, the number of revolutions of a blade in the apparatus is preferably from 10 rpm to 200 rpm for efficient progress of grinding with a grinding medium (water-soluble inorganic salt), and a ratio between the twin screw revolution numbers is preferably relatively higher in view of obtaining a higher grinding effect. The operation time, including dry grinding time, is preferably from 1 hour to 8 hours, and the temperature in the apparatus is preferably from 50° C. to 150° C. The water-soluble inorganic salt, serving as a grinding medium, is preferably spherical and preferably has a particle diameter of from 5 μm to 50 μm and a sharp particle-diameter distribution.

The mixture after the pulverization as described above may be mixed with hot water at 80° C. to dissolve the water-soluble organic solvent and the water-soluble inorganic salt, and the particles in the resultant liquid are then collected by filtration, washed with water and dried in an oven, whereby a fine-grained organic pigment can be obtained.

<Pigment-Dispersed Composition>

When the pigment obtained in the above manner is used to form a color filter layer, a colored photosensitive composition containing the pigment may be prepared and then cured by exposure, followed by development to remove a non-exposed region.

To allow the pigment to be present uniformly in a color filter layer, it is usually preferable that before preparation of a colored photosensitive composition, a pigment-dispersed composition (also called a pigment dispersion liquid) is prepared to improve the dispersibility of the pigment, and the pigment in this form is compounded into the colored photosensitive composition.

The content of the pigment in the pigment-dispersed composition is preferably from 10% by mass to 80% by mass, and more preferably from 20% by mass to 70% by mass, with respect to the total solid (mass) of the composition. The content of the pigment in this range is effective for securing excellent color properties with sufficient color density.

To prepare such a pigment-dispersed composition, a pigment dispersant (also simply referred to as a dispersant) and a pigment derivative may be compounded into the pigment in a suitable solvent. In preparing the pigment-dispersed composition in the invention, it is preferable that a compound represented by Formula (1) described in detail below is used as the pigment derivative and a compound represented by Formula (3) below is used as the dispersant.

Pigment Derivative

The pigment dispersant that can be used in preparation of the color filter layer of the invention may contain a compound represented by the following Formula (1) as the pigment derivative, and, as necessary, may contain appropriately selected other components.

A-N═N—X—Y Formula (1)

In Formula (1), A represents a component which can form an azo dye together with X—Y, and A may be arbitrarily selected as long as it is a residue that can be coupled with a diazonium compound to form an azo dye. Hereinafter, specific examples of A are shown, but the invention is not limited to these specific examples.

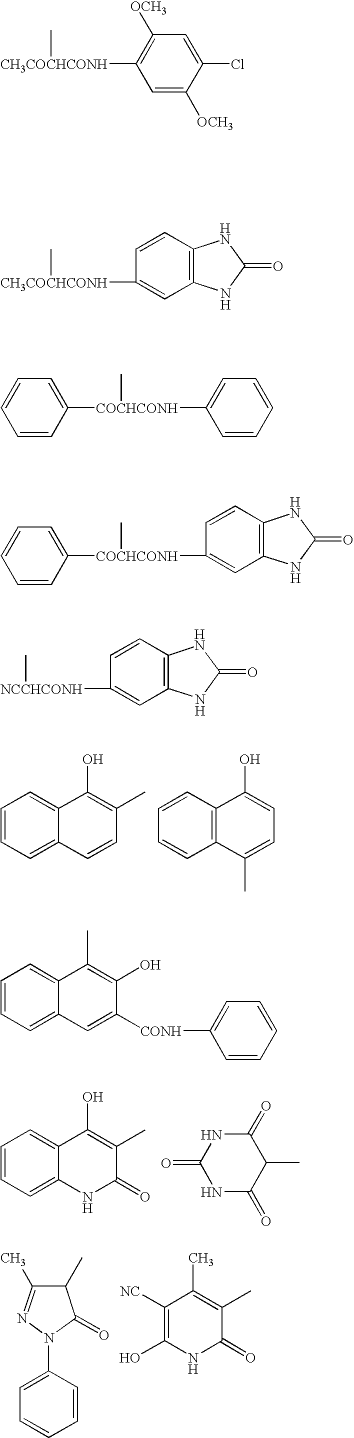

In Formula (1), X represents a single bond (it is meant that Y is connected directly to —N═N—) or a group selected from divalent linking groups represented by the following structural formulae:

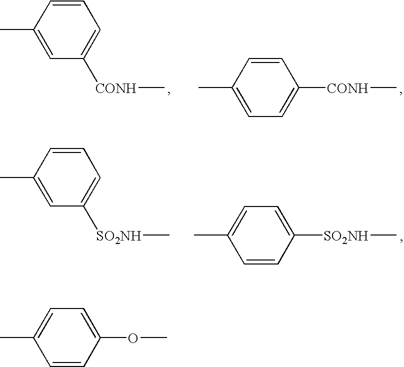

In Formula (1), Y represents a group represented by the following Formula (2):

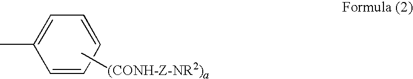

In Formula (2), Z represents an alkylene group having 1 to 5 carbon atoms, more specifically, Z represents —(CH₂)_{b}— (where b represents an integer of from 1 to 5, preferably 2 or 3). In Formula (2), —NR² represents a dialkylamino group in which each alkyl group has 1 to 4 carbon atoms, or a saturated 5- to 6-membered heterocyclic group containing the nitrogen atom. When —NR² represents a di(lower alkyl)amino group, the di(lower alkyl)amino group is represented by —N(CₙH₂ₙ₊₁)₂ (where n represents an integer of from 1 to 4, preferably 1 or 2). When —NR² represents saturated 5- to 6-membered heterocyclic group containing the nitrogen atom, the heterocycle of the heterocyclic group is preferably one represented by any of the following structural formula:

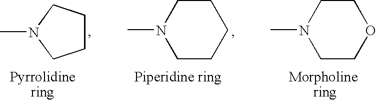

In Formula (2), Z and —NR² each may independently have a substituent selected from a lower alkyl group or an alkoxy group. In Formula (2), a represents 1 or 2, preferably 2.

Hereinafter, specific examples (Exemplary Compound 1 to Exemplary Compound 22) represented by Formula (1) are shown, but the invention is not limited to these specific examples.

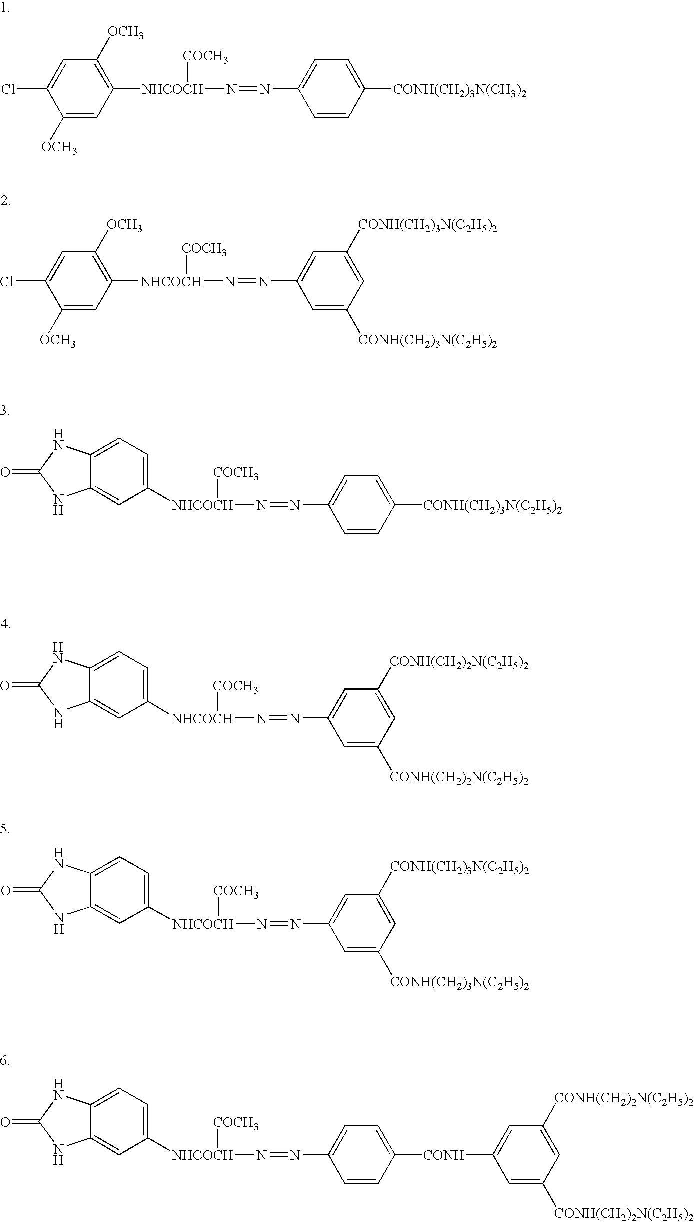

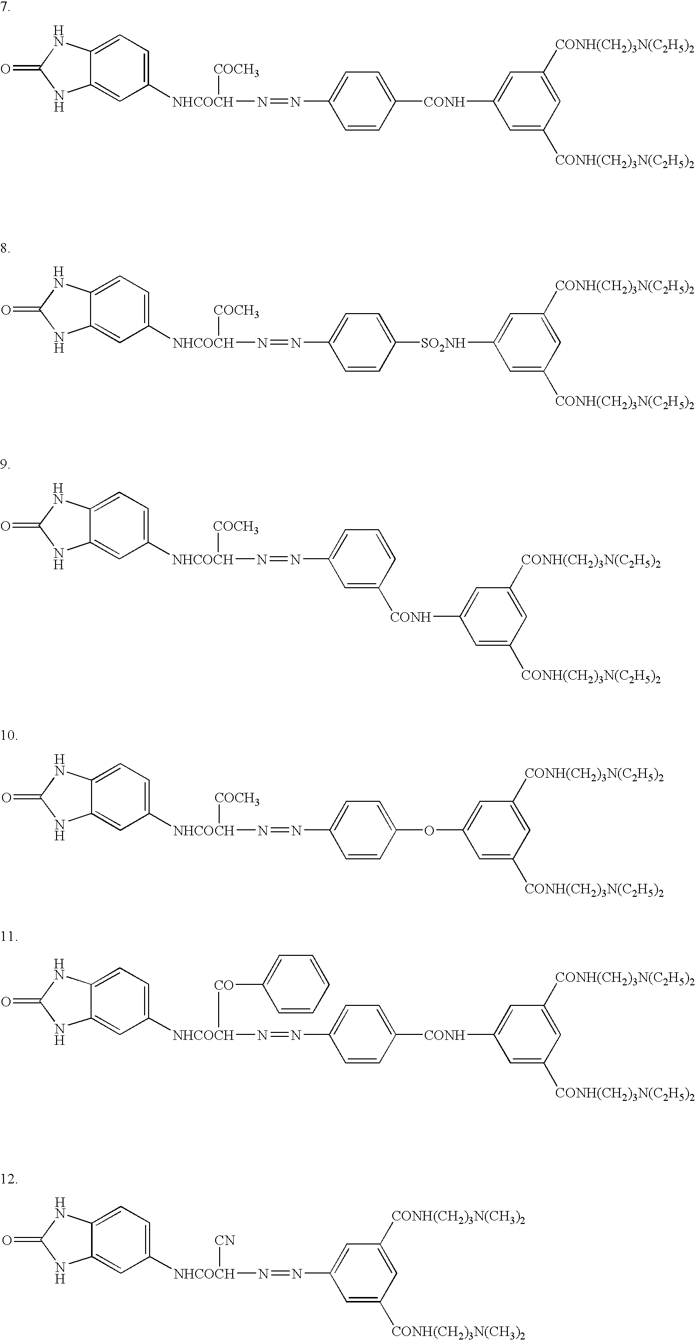

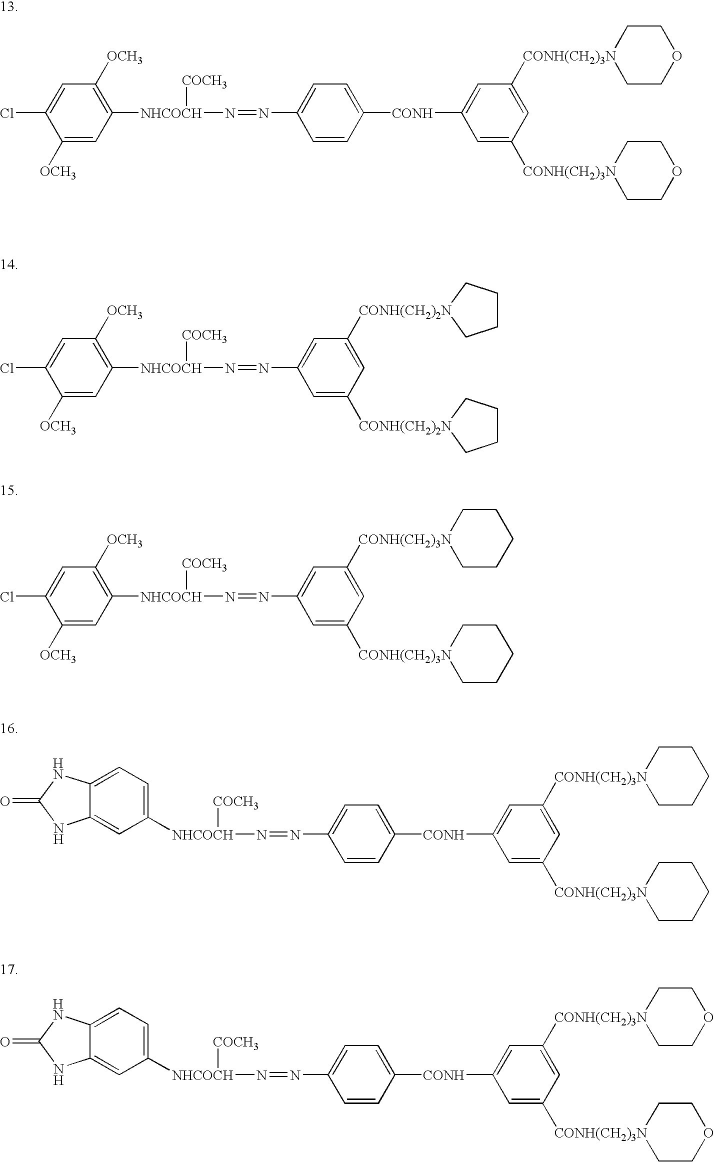

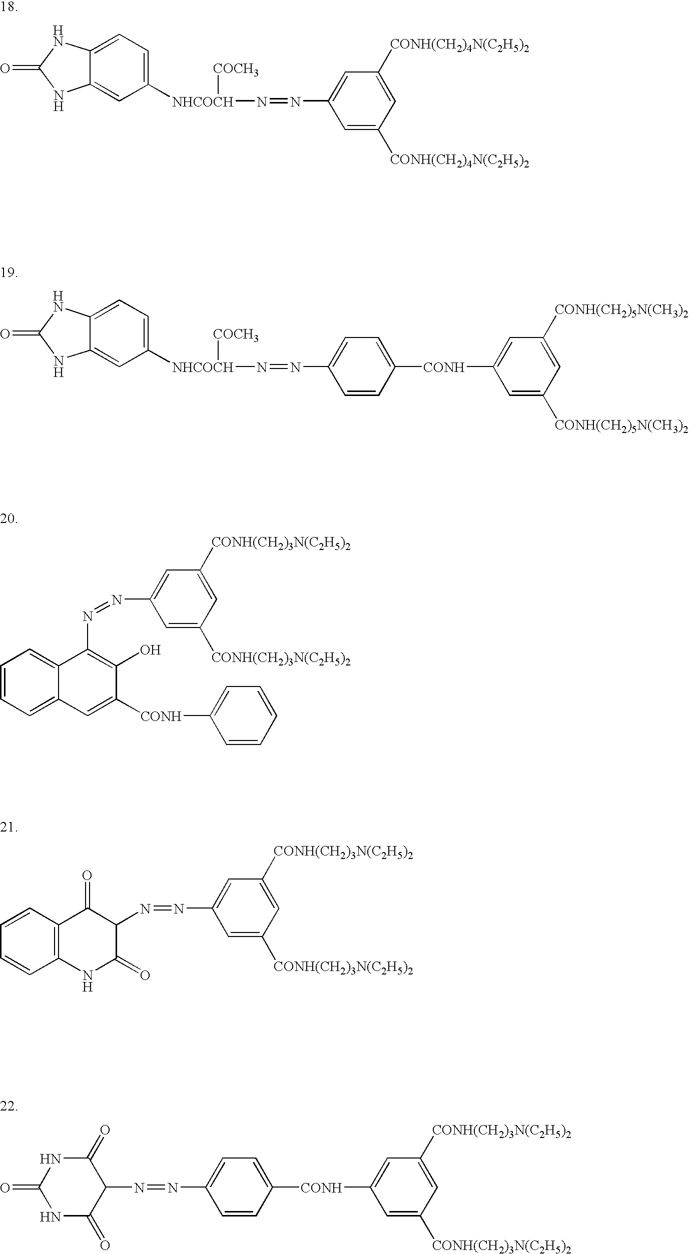

Hereinafter, Synthesis Examples of the compounds represented by Formula (1) will be described.

### SYNTHESIS EXAMPLE 1

Synthesis of Exemplary Compound 5

(1) 50 parts of dimethyl 5-nitroisophthalate and 130 parts of N,N-diethyl-1,3-propanediamine were reacted at 80° C. to 100° C. for about 4 hours under slightly reduced pressure. After confirming the disappearance of the starting material, dimethyl 5-nitroisophthalate and a monoamide compound, an excess of N,N-diethyl-1,3-propanediamine was removed under reduced pressure to give 92 parts of 5-nitroisophthalic acid bis-3-diethylaminopropylamide.

(2) 92 parts of the resulting 5-nitroisophthalic acid bis-3-diethylaminopropylamide, together with 112 parts of reduced iron and 12 parts of ammonium chloride, was reduced under reflux in 200 parts of isopropanol and 35 parts of water, to give 86 parts of 5-amino-isophthalic acid bis-3-diethylaminopropylamide.

(3) 18.3 parts of the resulting 5-amino-isophthalic acid bis-3-diethylaminopropylamide was added to 250 parts of methanol, and then 32 parts of hydrochloric acid was added thereto under cooling on ice. The mixture was cooled further to −15° C. This reaction mixture was diazotized by adding an aqueous solution of 3.4 parts of NaNO₂ (in 35 parts of water) dropwise thereto (preparation of a diazo solution).

Separately, a coupling component solution consisting of 9.3 parts of 5-acetoacetylamino-benzimidazolone, 400 parts of methanol, 800 parts of water and 19 parts of Na₂CO₃ was prepared and cooled to 10° C. or less. The diazo solution obtained above was added dropwise to the coupling component solution and the two solutions were subjected to diazo coupling. The system was made basic with K₂CO₃, to precipitate a yellow product which was then collected by filtration. This product was recrystallized from chloroform and acetonitrile to give 19 parts of Exemplary Compound 5 mentioned above. The maximum absorption wavelength of the resulting compound was λmax 380 nm (in CHCl₃).

### SYNTHESIS EXAMPLE 2

Synthesis of Exemplary Compound 7

(1) 18.5 parts of the 5-nitroisophthalic acid bis-3-diethylaminopropylamide obtained in (2) in Synthesis Example 1 and 5.1 parts of triethylamine were dissolved in 60 parts of DMF and then cooled on ice. The mixture was amidated by adding a solution of 9.3 parts of 4-nitrobenzoyl chloride in 60 parts of acetone. After the reaction, 800 parts of water was added, and the resulting crystals were collected by filtration and then recrystallized from ethyl acetate, to give 14 parts of 4-nitrobenzoyl-4-[3,5-bis(3-diethylaminopropylcarbamoyl)]phenylamide.

(2) The resulting compound was reduced in the same manner as in (2) in Synthesis Example 1 to give 13.2 parts of an aniline derivative.

(3) 13.2 parts of the resulting aniline derivative was added to 120 parts of methanol, and then 18 parts of hydrochloric acid was added thereto under cooling on ice. The mixture was then cooled further to −15° C.

This reaction mixture was diazotized by adding an aqueous solution of 1.8 parts of NaNO₂ (in 20 parts of water) dropwise thereto (preparation of a diazo solution). Separately, a coupling component solution consisting of 5.9 parts of 5-acetoacetylaminobenzimidazolone, 260 parts of methanol, 530 parts of water and 10.8 parts of NaCO₃ was prepared and cooled to 10° C. or less. The diazo solution obtained above was added dropwise to, and reacted with, the coupling component solution such that the temperature thereof of 10° C. was not exceeded. The system was made basic with K₂CO₃, to precipitate a yellow product which was then collected by filtration. This product was recrystallized from DMF and acetonitrile to give 19 parts of Exemplary Compound 7 mentioned above. The maximum absorption wavelength of the resulting compound was λmax 391 nm (in CHCl₃).

### SYNTHESIS EXAMPLE 3

Synthesis of Exemplary Compound 22

(1) In the same manner as in (3) in Example 2, 22.9 parts of the aniline derivative was used to prepare a diazo solution containing 180 parts of methanol, 31 parts of hydrochloric acid, 3.1 parts of NaNO₂ and 30 parts of water.

(2) A coupling component solution consisting of 5.6 parts of barbituric acid, 600 parts of methanol, 1100 parts of water and 19 parts of Na₂CO₃ was prepared.

The diazo solution obtained in (1) was added dropwise to, and reacted with, the coupling component solution. After the reaction, the system was made basic with K₂CO₃, and the precipitated crystals were collected by filtration and then recrystallized from DMF and acetonitrile, to give 16.3 parts of Exemplary Compound 22 mentioned above. The maximum absorption wavelength of the resulting compound was λmax 378 nm (in CHCl₃).

Dispersion

Next, dispersion of the pigment using the pigment dispersant of the invention will be described. When the pigment dispersant of the invention is used, the pigment dispersant is adsorbed onto the surfaces of the pigment particles. At this time, nitrogen atoms in the pigment dispersant are adsorbed onto the surfaces of the pigment particles. The pigment particles thus become covered with the compounds represented by Formula (1). Since the compounds represented by Formula (1) have been adsorbed on the surfaces of the individual pigment particles, the pigment particles do not mutually adhere or aggregate and remain in a finely pulverized state, and are dispersed evenly by the compounds represented by Formula (1), thus becoming readily fluidized.

When an ordinary pigment dispersant is used in a colored photosensitive composition, acidic groups possessed by a binder polymer contained in the colored photosensitive composition, and nitrogen atoms in the pigment dispersant, often form salts or are bound to each other via strong intermolecular force; However, the pigment dispersant of the invention has a pigment core and thus has high affinity for the pigment, thereby suppressing the behavior mentioned above, and simultaneously improving the stability of the pigment after dispersion, and improving the effect of nitrogen atoms on the improvement of dispersibility. The organic pigment, when dispersed with the compound represented by Formula (1), is imparted with excellent dispersibility without thickening, and particularly an acidic organic pigment is imparted with excellent dispersibility.

The dispersion of the pigment by the pigment dispersant in the invention means that the pigment particles occurring generally in the state of secondary particles are broken into primary particles and prevented from re-aggregating. The pigment dispersant of the invention has a site for adsorption onto the pigment, and a binder having acidic groups is allowed to coexist with the pigment dispersant, thereby allowing the pigment particles to sterically repel each other to prevent re-aggregation of the pigment after being dispersed in the form of primary particles. The dispersion of the pigment by the pigment dispersant of the invention is effectively achieved by mixing the pigment dispersant directly with the pigment, which is carried out preferably in a state where as far as possible there are no dispersible particles other than the pigment. When the pigment is dispersed in such a state, the pigment dispersant of the invention is adsorbed instantly at the peripheries of the pigment particles, thereby well dispersing and well fluidizing the pigment particles, thus effectively preventing the pigment particles from aggregating. On the other hand, when the pigment is dispersed in a state where dispersible particles other than the pigment particles exist, the pigment dispersant of the invention may not be adsorbed onto the surfaces of the objective pigment particles and adsorbed onto the surfaces of the other particles, which may reduce the effect of the pigment dispersant on the dispersion of the pigment. Accordingly, when the pigment is incorporated in a well-dispersed state into, for example, a photosensitive material in order to produce the photosensitive material, it is preferable that the pigment and the pigment dispersant of the invention are mixed at an early stage and the binder polymer having acidic groups is added before or while the pigment is dispersed, and it is not preferable that the pigment dispersant of the invention is added to and mixed with the pigment at a later stage to prepare a photosensitive layer coating solution.

The pigment dispersant of the invention can be used suitably in dispersing known pigments, and can be used preferably in the pigment-dispersed composition and colored photosensitive composition of the invention as described later.

<Polymer Compound>

The dispersant of the invention described above may be a polymer compound represented by the following Formula (3). Since the polymer compound represented by Formula (3) has, at a terminal of the polymer, plural monovalent organic groups each containing at least one moiety selected from an organic dye structure, a heterocyclic structure, an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group or a hydroxyl group, the polymer compound has various characteristics, such as excellent adsorbability to solid surfaces, excellent micelle forming ability, and surface-active properties. For example, the polymer compound may be suitably used as a pigment dispersant.

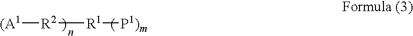

In Formula (3), A¹ represents a monovalent organic group containing at least one moiety selected from an organic dye structure, a heterocyclic structure, an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group or a hydroxyl group. Each A¹, the number of which is n, may be the same as or different from one other.

In other words, the above A¹ represents a monovalent organic group containing at least one structure having an ability to be adsorbed to pigments, such as an organic dye structure or a heterocyclic structure, and/or at least one functional group having an ability to be adsorbed to pigments, such as an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group or a hydroxyl group.

In the following explanation, this moiety having an ability to be adsorbed to pigments (the above-mentioned structures and functional groups) will sometimes be collectively referred to as “adsorptive moiety”.

Each A¹ should include at least one kind of adsorptive moiety, and may include two or more kinds of adsorptive moieties.

According to the invention, the “monovalent organic group containing at least one kind of adsorptive moiety” is a monovalent organic group formed by bonding of the above adsorptive moiety to an organic linking group that is composed of 1 to 200 carbon atoms, 0 to 20 nitrogen atoms, 0 to 100 oxygen atoms, 1 to 400 hydrogen atoms, and 0 to 40 sulfur atoms. Furthermore, when the adsorptive moiety itself can constitute a monovalent organic group, the adsorptive moiety itself may be the monovalent organic group represented by A¹.

First, the adsorptive moiety as a constituent component of A¹ will be described in the following.

Preferable examples of the organic dye structure include phthalocyanine dye structures, insoluble azo dye structures, azo lake dye structures, anthraquinone dye structures, quinacridone dye structures, dioxazine dye structures, diketopyrrolopyrrole dye structures, anthrapyridine dye structures, anthanthrone dye structures, indanthrone dye structures, flavanthrone dye structures, perinone dye structures, perylene dye structures, and thioindigo dye structures. Among them, phthalocyanine dye structures, azo lake dye structures, anthraquinone dye structures, dioxazine dye structures, and diketopyrrolopyrrole dye structures are more preferable, and phthalocyanine dye structures, anthraquinone dye structures, and diketopyrrolopyrrole dye structures are still more preferable.

Preferable examples of the heterocyclic structure include thiophene, furan, xanthene, pyrrole, pyrroline, pyrrolidine, dioxolane, pyrazole, pyrazoline, pyrazolidine, imidazole, oxazole, thiazole, oxadiazole, triazole, thiadiazole, pyran, pyridine, piperidine, dioxane, morpholine, pyridazine, pyrimidine, piperazine, triazine, trithiane, isoindoline, isoindolinone, benzimidazolone, benzothiazole, succinimide, phthalimide, naphthalimide, hydantoin, indole, quinoline, carbazole, acridine, acridone, and anthraquinone. Among them, pyrroline, pyrrolidine, pyrazole, pyrazoline, pyrazolidine, imidazole, triazole, pyridine, piperidine, morpholine, pyridazine, pyrimidine, piperazine, triazine, isoindoline, isoindolinone, benzimidazolone, benzothiazole, succinimide, phthalimide, naphthalimide, hydantoin, carbazole, acridine, acridone, and anthraquinone are more preferable.

The organic dye structure or heterocyclic structure may be unsubstituted or may further have a substituent, and examples of the substituent include an alkyl group having 1 to 20 carbon atoms, such as a methyl group or an ethyl group; an aryl group having 6 to 16 carbon atoms, such as a phenyl group or a naphthyl group; a hydroxyl group; an amino group; a carboxyl group; a sulfonamide group; an N-sulfonylamide group; an acyloxy group having 1 to 6 carbon atoms, such as an acetoxy group; an alkoxy group having 1 to 20 carbon atoms, such as a methoxy group or an ethoxy group; a halogen atom such as chlorine or bromine; an alkoxycarbonyl group having 2 to 7 carbon atoms, such as a methoxycarbonyl group, an ethoxycarbonyl group or a cyclohexyloxycarbonyl group; a cyano group; and a carbonic acid ester group such as a t-butyl carbonate. Here, these substituents may be bound to the organic dye structure or heterocyclic ring through a linking group constituted by one of the following structural units or a combination of two or more structural units each of which is selected from the following structural units.

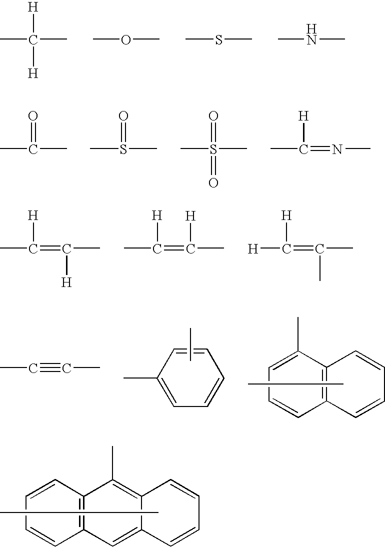

Preferable examples of the acidic group include a carboxylic acid group, a sulfonic acid group, a monosulfuric acid ester group, a phosphoric acid group, a monophosphoric acid ester group, and a boric acid group. Among them, a carboxylic acid group, a sulfonic acid group, a monosulfuric acid ester group, a phosphoric acid group, and a monophosphoric acid ester group are more preferable, and a carboxylic acid group, a sulfonic acid group and a phosphoric acid group are still more preferable.

Preferable examples of the group having a basic nitrogen atom include an amino group (—NH₂), a substituted imino group (—NHR⁸or —NR⁹R¹⁰, where R⁸, R⁹ and R¹⁰ each independently represent an alkyl group having 1 to 20 carbon atoms, an aryl group having 6 or more carbon atoms, or an aralkyl group having 7 or more carbon atoms), a guanidyl group represented by the following Formula (a1), and an amidinyl group represented by the following Formula (a2).

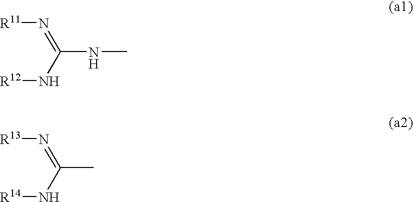

In Formula (a1), R¹¹ and R¹² each independently represent an alkyl group having 1 to 20 carbon atoms, an aryl group having 6 or more carbon atoms, or an aralkyl group having 7 or more carbon atoms.

In Formula (a2), R¹³ and R¹⁴ each independently represent an alkyl group having 1 to 20 carbon atoms, an aryl group having 6 or more carbon atoms, or an aralkyl group having 7 or more carbon atoms.

Among these, an amino group (—NH₂), a substituted imino group (—NHR⁸ or —NR⁹R¹⁰, where R⁸, R⁹ and R¹⁰ each independently represent an alkyl group having 1 to 10 carbon atoms, a phenyl group or a benzyl group), a guanidyl group represented by Formula (a1) [in Formula (a1), R¹¹ and R¹² each independently represent an alkyl group having 1 to 10 carbon atoms, a phenyl group, or a benzyl group], and an amidinyl group represented by Formula (a2) [in Formula (a2), R¹³ and R¹⁴ each independently represent an alkyl group having 1 to 10 carbon atoms, a phenyl group, or a benzyl group] are more preferable.

In particular, an amino group (—NH₂), a substituted imino group (—NHR⁸, —NR⁹R¹⁰, where R⁸, R⁹ and R¹⁰ each independently represent an alkyl group having 1 to 5 carbon atoms, a phenyl group or a benzyl group), a guanidyl group represented by Formula (a1) [in Formula (a1), R¹¹ and R¹² each independently represent an alkyl group having 1 to 5 carbon atoms, a phenyl group or a benzyl group], or an amidinyl group represented by Formula (a2) [in Formula (a2), R¹³ and R¹⁴ each independently represent an alkyl group having 1 to 5 carbon atoms, a phenyl group or a benzyl group] are preferably used.

Preferable examples of the urea group include —NR¹⁵CONR¹⁶R¹⁷ (where R¹⁵, R¹⁶ and R¹⁷ each independently represent a hydrogen atom, an alkyl group having 1 to 20 carbon atoms, an aryl group having 6 or more carbon atoms, or an aralkyl group having 7 or more carbon atoms). Among them, —NR¹⁵CONHR¹⁷ (where R¹⁵ and R¹⁷ each independently represent a hydrogen atom, an alkyl group having 1 to 10 carbon atoms, an aryl group having 6 or more carbon atoms, or an aralkyl group having 7 or more carbon atoms) is more preferable, and —NHCONHR¹⁷ (where R¹⁷ represents a hydrogen atom, an alkyl group having 1 to 10 carbon atoms, an aryl group having 6 or more carbon atoms, or an aralkyl group having 7 or more carbon atoms) is still more preferable.

Preferable examples of the urethane group include —NHCOOR¹⁸, —NR¹⁹COOR²⁰, —OCONHR²¹, —OCONR²²R²³ (where R¹⁸, R¹⁹, R²⁰, R²¹, R²² and R²³ each independently represent an alkyl group having 1 to 20 carbon atoms, an aryl group having 6 or more carbon atoms, or an aralkyl group having 7 or more carbon atoms). Among them, —NHCOOR¹⁸ and —OCONHR²¹ (where R¹⁸ and R²¹ each independently represent an alkyl group having 1 to 10 carbon atoms, an aryl group having 6 or more carbon atoms, or an aralkyl group having 7 or more carbon atoms) are more preferable, and —NHCOOR¹⁸ and —OCONHR²¹ (where R¹⁸ and R²¹ each independently represent an alkyl group having 1 to 10 carbon atoms, an aryl group having 6 or more carbon atoms, or an aralkyl group having 7 or more carbon atoms) are still more preferable.

Examples of the group having a coordinating oxygen atom include an acetylacetonate group and crown ether.

Preferable examples of the hydrocarbon group having 4 or more carbon atoms include an alkyl group having 4 or more carbon atoms, an aryl group having 6 or more carbon atoms, and an aralkyl group having 7 or more carbon atoms. Among them, an alkyl group having 4 to 20 carbon atoms, an aryl group having 6 to 20 carbon atoms, and an aralkyl group having 7 to 20 carbon atoms are more preferable, and an alkyl group having 4 to 15 carbon atoms (for example, an octyl group, a dodecyl group or the like), an aryl group having 6 to 15 carbon atoms (for example, a phenyl group or a naphthyl group) and an aralkyl group having 7 to 15 carbon atoms (for example, a benzyl group) are still more preferable.

Examples of the alkoxysilyl group include a trimethoxysilyl group and a triethoxysilyl group.

As the organic linking group binding to the adsorptive moiety, a single bond and an organic linking group composed of 1 to 100 carbon atoms, 0 to 10 nitrogen atoms, 0 to 50 oxygen atoms, 1 to 200 hydrogen atoms, and 0 to 20 sulfur atoms are preferable. This organic linking group may be unsubstituted or may further have a substituent.

Specific examples of this organic linking group include a group constituted by one of the following structural units or a combination of two or more structural units each of which is selected from the following structural units.

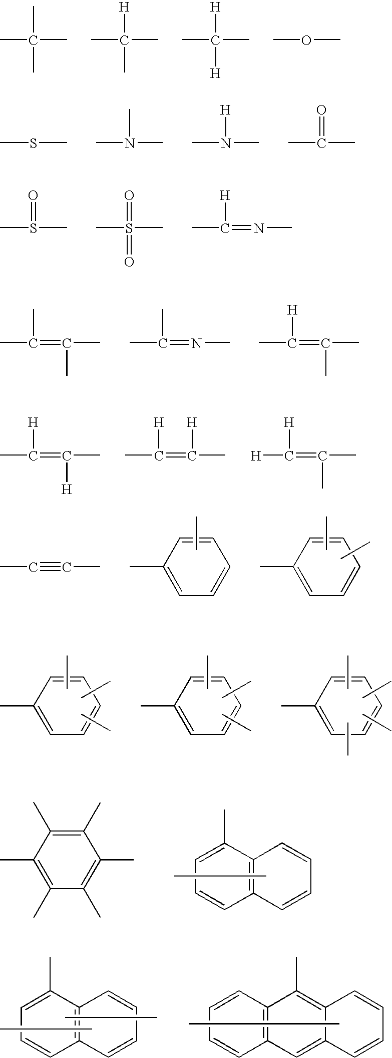

When the organic linking group has a substituent, examples of the substituent include an alkyl group having 1 to 20 carbon atoms, such as a methyl group or an ethyl group; an aryl group having 6 to 16 carbon atoms, such as a phenyl group or a naphthyl group; a hydroxyl group; an amino group; a carboxyl group; a sulfonamide group; an N-sulfonylamide group; an acyloxy group having 1 to 6 carbon atoms, such as an acetoxy group; an alkoxy group having 1 to 6 carbon atoms, such as a methoxy group or an ethoxy group; a halogen atom such as chlorine or bromine; an alkoxycarbonyl group having 2 to 7 carbon atoms, such as a methoxycarbonyl group, an ethoxycarbonyl group or a cyclohexyloxycarbonyl group; a cyano group; and a carbonic acid ester group such as t-butyl carbonate.

Among them, the substituent A¹ is preferably a monovalent organic group containing at least one moiety selected from an organic dye structure, a heterocyclic structure, an acidic group, a group having a basic nitrogen atom, a urea group, or a hydrocarbon group having 4 or more carbon atoms.

The substituent A¹ is more preferably a monovalent organic group represented by the following Formula (b).

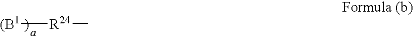

In Formula (b), B¹ represents an adsorptive moiety (that is, a moiety selected from an organic dye structure, a heterocyclic structure, an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group or a hydroxyl group); R²⁴ represents a single bond or an organic linking group having a valency of (a+1); a represents an integer of from 1 to 10; and each B¹, the number of which is a, may be the same as or different from each other.

Examples of the adsorptive moiety represented by B¹ are the same as those of the adsorptive moiety of A¹ in Formula (3), and preferred examples thereof are also the same as those of the adsorptive moiety of A¹.

Among them, a moiety selected from an organic dye structure, a heterocyclic structure, an acidic group, a group having a basic nitrogen atom, a urea group or a hydrocarbon group having 4 or more carbon atoms, is preferable.

R²⁴ represents a single bond or an organic linking group having a valency of (a+1), and a represents an integer of from 1 to 10. Preferably, a represents an integer of from 1 to 7, more preferably from 1 to 5, and still more preferably from 1 to 3.

Examples of the organic linking group having a valency of (a+1) include a group composed of 1 to 100 carbon atoms, 0 to 10 nitrogen atoms, 0 to 50 oxygen atoms, 1 to 200 hydrogen atoms, and 0 to 20 sulfur atoms, and the organic linking group may be unsubstituted or may further have a substituent.

Specific examples of the organic linking group having a valency of (a+1) include a group constituted by one of the following structural units or a combination of two or more structural units each of which is selected from the following structural units (which may form a cyclic structure).

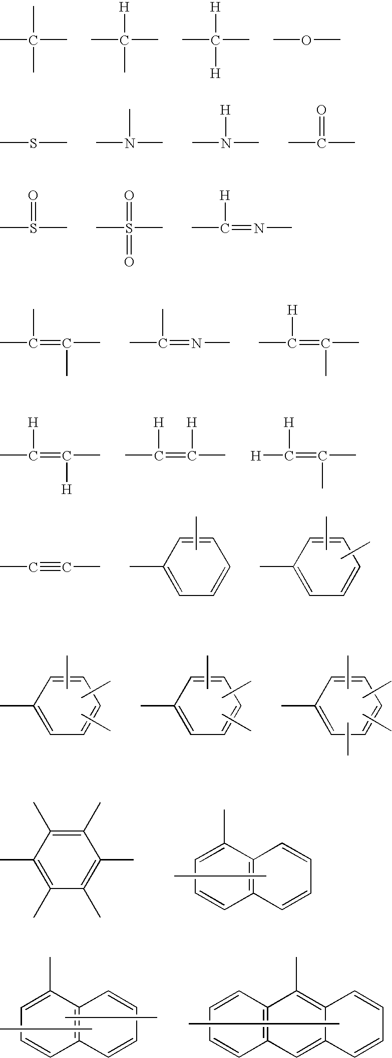

R²⁴ is preferably a single bond, or an organic linking group having a valency of (a+1) that is composed of 1 to 50 carbon atoms, 0 to 8 nitrogen atom, 0 to 25 oxygen atoms, 1 to 100 hydrogen atoms, and 0 to 10 sulfur atoms; more preferably a single bond, or an organic linking group having a valency of (a+1) that is composed of 1 to 30 carbon atoms, 0 to 6 nitrogen atoms, 0 to 15 oxygen atoms, 1 to 50 hydrogen atoms, and 0 to 7 sulfur atoms; and still more preferably a single bond, or an organic linking group having a valency of (a+1) that is composed of 1 to 10 carbon atoms, 0 to 5 nitrogen atoms, 0 to 10 oxygen atoms, 1 to 30 hydrogen atoms, and 0 to 5 sulfur atoms.

When the above organic linking group having a valency of (a+1) has a substituent, examples of the substituent include an alkyl group having 1 to 20 carbon atoms, such as a methyl group or an ethyl group; an aryl group having 6 to 16 carbon atoms, such as a phenyl group or a naphthyl group; a hydroxyl group; an amino group; a carboxyl group; a sulfonamide group; an N-sulfonylamide group; an acyloxy group having 1 to 6 carbon atoms, such as an acetoxy group; an alkoxy group having 1 to 6 carbon atoms, such as a methoxy group or an ethoxy group; a halogen atom such as chlorine or bromine; an alkoxycarbonyl group having 2 to 7 carbon atoms, such as a methoxycarbonyl group, an ethoxycarbonyl group or a cyclohexyloxycarbonyl group; a cyano group; and a carbonic acid ester group such as t-butyl carbonate.

In Formula (3), R² represents a single bond or a divalent organic linking group. Each R², the number of which is n, may be the same as or different from each other.

Examples of the divalent organic linking group include a group composed of 1 to 100 carbon atoms, 0 to 10 nitrogen atoms, 0 to 50 oxygen atoms, 1 to 200 hydrogen atoms, and 0 to 20 sulfur atoms, and the organic linking group may be unsubstituted or may further have a substituent.

Specific examples of the divalent organic linking group include a group constituted by one of the following structural units or a combination of two or more structural units each of which is selected from the following structural units.

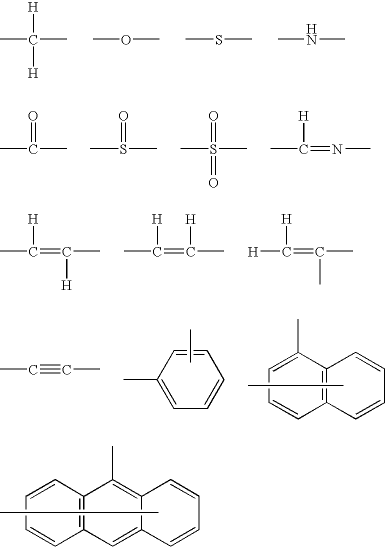

R² is preferably a single bond, or a divalent organic linking group composed of 1 to 50 carbon atoms, 0 to 8 nitrogen atoms, 0 to 25 oxygen atoms, 1 to 100 hydrogen atoms, and 0 to 10 sulfur atoms; more preferably a single bond, or a divalent organic linking group composed of 1 to 30 carbon atoms, 0 to 6 nitrogen atoms, 0 to 15 oxygen atoms, 1 to 50 hydrogen atoms, and 0 to 7 sulfur atoms; and still more preferably a single bond, or a divalent organic linking group composed of 1 to 10 carbon atoms, 0 to 5 nitrogen atoms, 0 to 10 oxygen atoms, 1 to 30 hydrogen atoms, and 0 to 5 sulfur atoms.

When the above divalent organic linking group has a substituent, examples of the substituent include an alkyl group having 1 to 20 carbon atoms, such as a methyl group or an ethyl group; an aryl group having 6 to 16 carbon atoms, such as a phenyl group or a naphthyl group; a hydroxyl group; an amino group; a carboxyl group; a sulfonamide group; an N-sulfonylamide group; an acyloxy group having 1 to 6 carbon atoms, such as an acetoxy group; an alkoxy group having 1 to 6 carbon atoms, such as a methoxy group or an ethoxy group; a halogen atom such as chlorine or bromine; an alkoxycarbonyl group having 2 to 7 carbon atoms, such as a methoxycarbonyl group, an ethoxycarbonyl group or a cyclohexyloxycarbonyl group; a cyano group; and a carbonic acid ester group such as t-butyl carbonate.

In Formula (3), R¹ represents an organic linking group having a valency of (m+n), where m+n is an integer of from 3 to 10.

Examples of the organic linking group having a valency of (m+n) represented by R¹ include a group composed of 1 to 100 carbon atoms, 0 to 10 nitrogen atoms, 0 to 50 oxygen atoms, 1 to 200 hydrogen atoms, and 0 to 20 sulfur atoms, and the organic linking group may be unsubstituted or may further have a substituent.

Specific examples of the organic linking group having a valency of (m+n) include a group constituted of one of the following structural units or a combination of two or more structural units each of which is selected from the following structural units (which may form a cyclic structure).

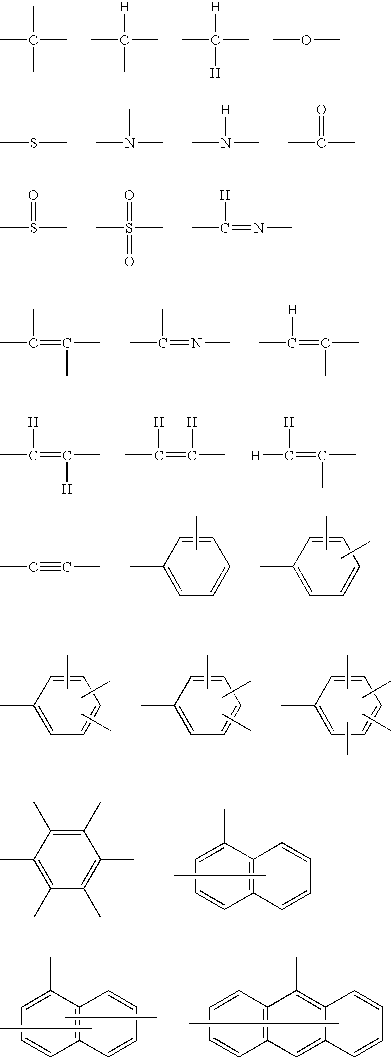

The organic linking group having a valency of (m+n) is preferably a group composed of 1 to 60 carbon atoms, 0 to 10 nitrogen atoms, 0 to 40 oxygen atoms, 1 to 120 hydrogen atoms, and 0 to 10 sulfur atoms; more preferably a group composed of 1 to 50 carbon atoms, 0 to 10 nitrogen atoms, 0 to 30 oxygen atoms, 1 to 100 hydrogen atoms, and 0 to 7 sulfur atoms; and still more preferably a group composed of 1 to 40 carbon atoms, 0 to 8 nitrogen atoms, 0 to 20 oxygen atoms, 1 to 80 hydrogen atoms, and 0 to 5 sulfur atoms.

When the above organic linking group having a valency of (m+n) has a substituent, examples of the substituent include an alkyl group having 1 to 20 carbon atoms, such as a methyl group or an ethyl group; an aryl group having 6 to 16 carbon atoms, such as a phenyl group or a naphthyl group; a hydroxyl group; an amino group; a carboxyl group; a sulfonamide group; an N-sulfonylamide group; an acyloxy group having 1 to 6 carbon atoms, such as an acetoxy group; an alkoxy group having 1 to 6 carbon atoms, such as a methoxy group or an ethoxy group; a halogen atom such as chlorine or bromine; an alkoxycarbonyl group having 2 to 7 carbon atoms, such as a methoxycarbonyl group, an ethoxycarbonyl group or a cyclohexyloxycarbonyl group; a cyano group; and a carbonic acid ester group such as t-butyl carbonate.

Specific examples of the organic linking group having a valency of (m+n) represented by R¹ include, but are not limited to, those shown below (specific examples (1) to (17)).

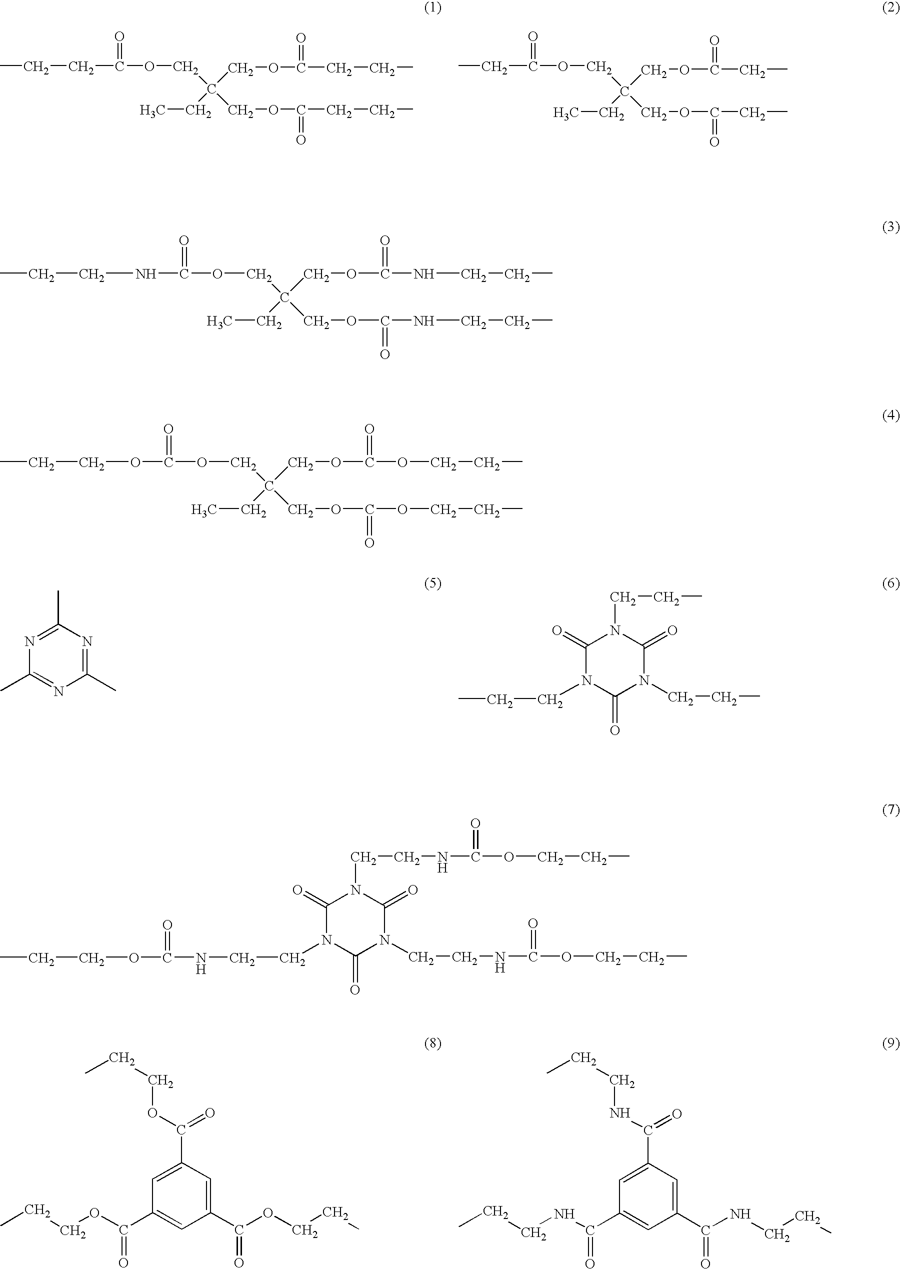

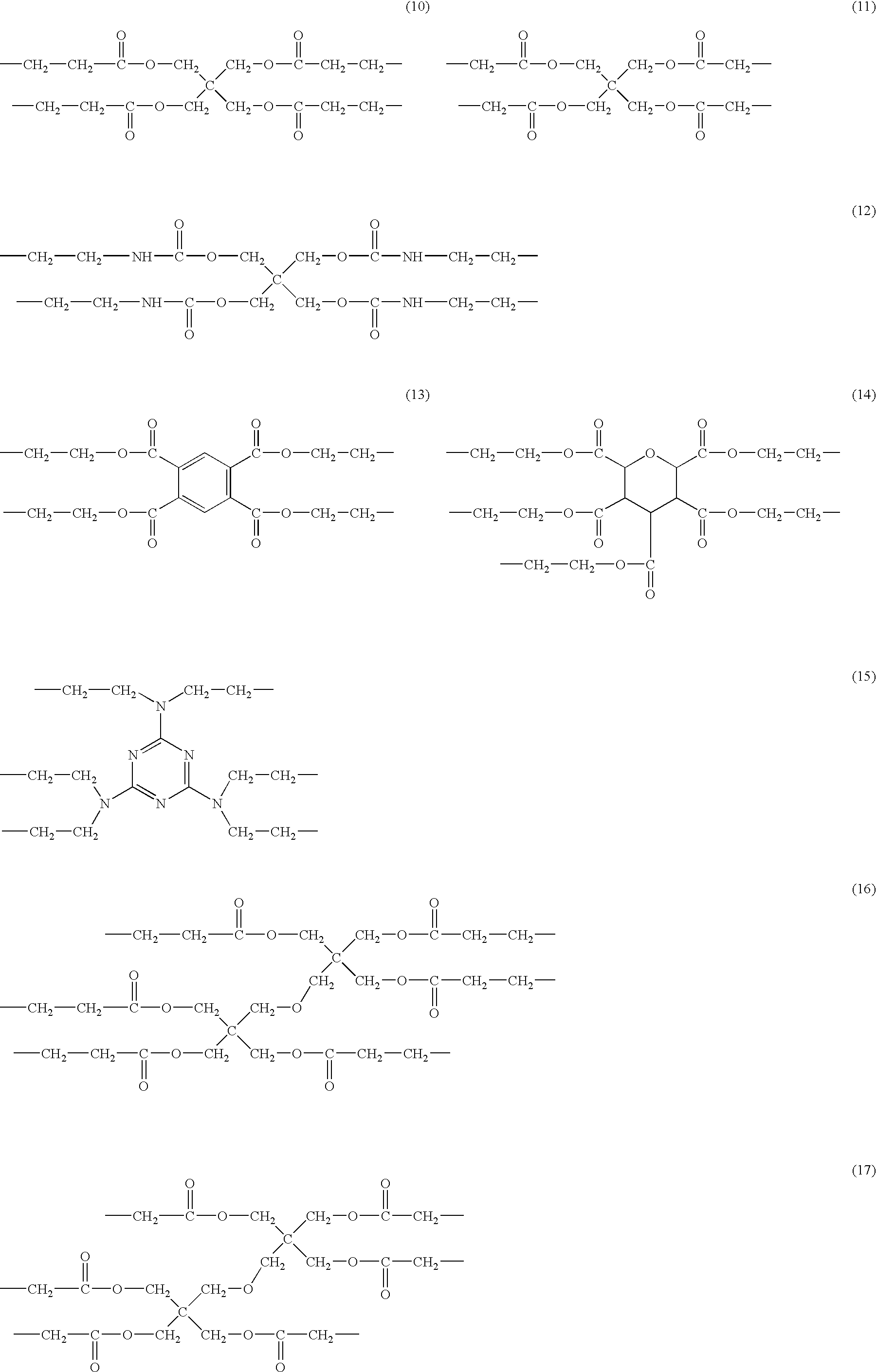

Among the above specific examples, the following organic linking groups having a valency of (m+n) are preferable from the viewpoints of availability of raw materials, ease of synthesis, and solubility in various solvents.

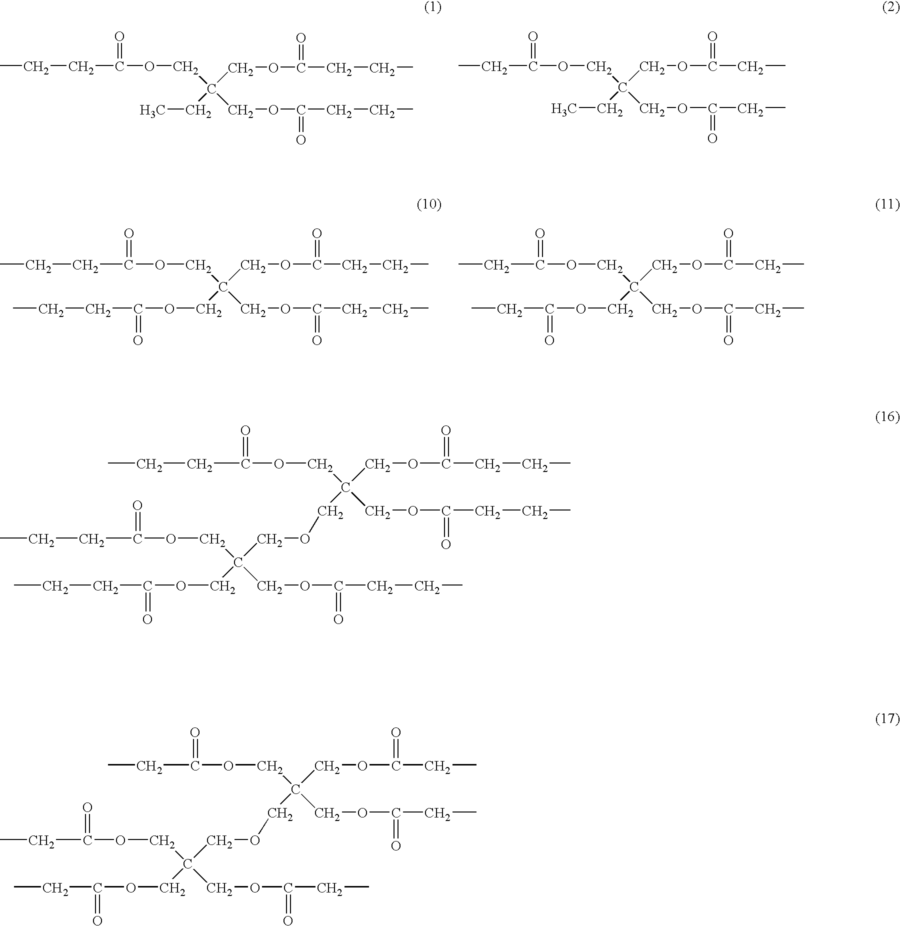

In Formula (3), m represents the integer of from 1 to 8. m preferably represents an integer of from 1 to 5, more preferably from 1 to 4, and still more preferably from 1 to 3.

In Formula (3), n represents an integer of from 2 to 9. n preferably represents an integer of from 2 to 8, more preferably from 2 to 7, and still more preferably from 3 to 6.

In Formula (3), P¹ represents a polymer skeleton, and may be selected from known polymers depending on the purposes. Each P¹, the number of which is m, may be the same as or different from each other.

The polymer for constituting the polymer skeleton is preferably at least one selected from the group consisting of a polymer or copolymer of a vinyl monomer; an ester polymer; an ether polymer; a urethane polymer; an amide polymer; an epoxy polymer; a silicone polymer; and a modified product or copolymer thereof (example thereof including a copolymer of polyether/polyurethane and a copolymer of polyether/polymer of a vinyl monomer, where the copolymer may be any of a random copolymer, a block copolymer and a graft copolymer); more preferably at least one selected from the group consisting of a polymer or copolymer of a vinyl monomer, an ester polymer, an ether polymer, a urethane polymer, and a modified product or copolymer thereof; and still more preferably a polymer or copolymer of a vinyl monomer.

Moreover, the polymer is preferably soluble in an organic solvent. When a polymer having low affinity with an organic solvent is used, for example, as a pigment dispersant, the affinity with the dispersion medium is weakened, and thus an adsorption layer sufficient for dispersion stabilization may not be secured.

The vinyl monomer is not particularly limited, but preferably (meth)acrylic acid esters, crotonic acid esters, vinyl esters, maleic acid diesters, fumaric acid diesters, itaconic acid diesters, (meth)acrylamides, styrenes, vinyl ethers, vinyl ketones, olefins, maleimides, (meth)acrylonitrile, or vinyl monomers having an acidic group.

Hereinafter, preferable examples of these vinyl monomers will be described.

Examples of the (meth)acrylic acid esters include methyl(meth)acrylate, ethyl(meth)acrylate, n-propyl(meth)acrylate, isopropyl(meth)acrylate, n-butyl(meth)acrylate, isobutyl(meth)acrylate, t-butyl(meth)acrylate, amyl(meth)acrylate, n-hexyl(meth)acrylate, cyclohexyl(meth)acrylate, t-butylcyclohexyl(meth)acrylate, 2-ethylhexyl(meth)acrylate, t-octyl(meth)acrylate, dodecyl(meth)acrylate, octadecyl(meth)acrylate, acetoxyethyl(meth)acrylate, phenyl(meth)acrylate, 2-hydroxyethyl(meth)acrylate, 2-hydroxypropyl(meth)acrylate, 3-hydroxypropyl(meth)acrylate, 4-hydroxybutyl(meth)acrylate, 2-methoxyethyl(meth)acrylate, 2-ethoxyethyl(meth)acrylate, 2-(2-methoxyethoxy)ethyl(meth)acrylate, 3-phenoxy-2-hydroxypropyl(meth)acrylate, 2-chloroethyl(meth)acrylate, glycidyl(meth)acrylate, 3,4-epoxycyclohexylmethyl(meth)acrylate, vinyl(meth)acrylate, 2-phenylvinyl(meth)acrylate, 1-propenyl(meth)acrylate, allyl(meth)acrylate, 2-allyloxyethyl(meth)acrylate, propargyl(meth)acrylate, benzyl(meth)acrylate, (meth)acrylic acid diethylene glycol monomethyl ether, (meth)acrylic acid diethylene glycol monoethyl ether, (meth)acrylic acid triethylene glycol monomethyl ether, (meth)acrylic acid triethylene glycol monoethyl ether, (meth)acrylic acid polyethylene glycol monomethyl ether, (meth)acrylic acid polyethylene glycol monoethyl ether, β-phenoxyethoxyethyl(meth)acrylate, nonylphenoxypolyethylene glycol(meth)acrylate, dicyclopentenyl(meth)acrylate, dicyclopentenyloxyethyl(meth)acrylate, trifluoroethyl(meth)acrylate, octafluoropentyl(meth)acrylate, perfluorooctylethyl(meth)acrylate, dicyclopentanyl(meth)acrylate, tribromophenyl(meth)acrylate, tribromophenyloxyethyl(meth)acrylate, and (meth)acrylic acid-γ-butyrolactone.

Examples of the crotonic acid esters include butyl crotonate and hexyl crotonate.

Examples of the vinyl esters include vinyl acetate, vinyl chloroacetate, vinyl propionate, vinyl butyrate, vinyl methoxyacetate, and vinyl benzoate.

Examples of the maleic acid diesters include dimethyl maleate, diethyl maleate, and dibutyl maleate.

Examples of the fumaric acid diesters include dimethyl fumarate, diethyl fumarate, and dibutyl fumarate.

Examples of the itaconic acid diesters include dimethyl itaconate, diethyl itaconate, and dibutyl itaconate.

Examples of the (meth)acrylamides include (meth)acrylamide, N-methyl(meth)acrylamide, N-ethyl(meth)acrylamide, N-propyl(meth)acrylamide, N-isopropyl(meth)acrylamide, N-n-butylacryl(meth)amide, N-t-butyl(meth)acrylamide, N-cyclohexyl(meth)acrylamide, N-(2-methoxyethyl)(meth)acrylamide, N,N-dimethyl(meth)acrylamide, N,N-diethyl(meth)acrylamide, N-phenyl(meth)acrylamide, N-nitrophenylacrylamide, N-ethyl-N-phenylacrylamide, N-benzyl(meth)acrylamide, (meth)acryloylmorpholine, diacetone acrylamide, N-methylolacrylamide, N-hydroxyethylacrylamide, vinyl(meth)acrylamide, N,N-diallyl(meth)acrylamide, and N-allyl(meth)acrylamide.

Examples of the styrenes include styrene, methylstyrene, dimethylstyrene, trimethylstyrene, ethylstyrene, isopropylstyrene, butylstyrene, hydroxystyrene, methoxystyrene, butoxystyrene, acetoxystyrene, chlorostyrene, dichlorostyrene, bromostyrene, chloromethylstyrene, hydroxystyrene protected with a group (for example, t-Boc or the like) that allows deprotection by an acidic substance, methyl vinylbenzoate, and α-methylstyrene.

Examples of the vinyl ethers include methyl vinyl ether, ethyl vinyl ether, 2-chloroethyl vinyl ether, hydroxyethyl vinyl ether, propyl vinyl ether, butyl vinyl ether, hexyl vinyl ether, octyl vinyl ether, methoxyethyl vinyl ether, and phenyl vinyl ether.

Examples of the vinyl ketones include methyl vinyl ketone, ethyl vinyl ketone, propyl vinyl ketone, and phenyl vinyl ketone.

Examples of the olefins include ethylene, propylene, isobutylene, butadiene, and isoprene.

Examples of the maleimides include maleimide, butylmaleimide, cyclohexylmaleimide, and phenylmaleimide.

Further, a (meth)acrylonitrile, a heterocyclic group substituted by a vinyl group (for example, vinylpyridine, N-vinylpyrrolidone, or vinylcarbazole), N-vinylformamide, N-vinylacetamide, N-vinylimidazole, vinylcaprolactone, and the like may be used.

Other than the above-mentioned compounds, for example, a vinyl monomer having a functional group such as a urethane group, a urea group, a sulfonamide group, a phenol group or an imide group may also be used. The monomer having such urethane group or urea group may be appropriately synthesized, for example, by using an addition reaction of an isocyanate group with a hydroxyl group or an addition reaction of an isocyanate group with an amino group. Specifically, the monomer may be appropriately synthesized by an addition reaction of an isocyanate group-containing monomer with a compound containing one hydroxyl group or with a compound containing one primary or secondary amino group, or an addition reaction of a hydroxyl group-containing monomer or primary or secondary amino group-containing monomer with monoisocyanate.

Examples of the vinyl monomer having an acidic group include a vinyl monomer having a carboxyl group and a vinyl monomer having a sulfonic acid group.

Examples of the vinyl monomer having a carboxyl group include (meth)acrylic acid, vinylbenzoic acid, maleic acid, maleic acid monoalkyl ester, fumaric acid, itaconic acid, crotonic acid, cinnamic acid, and acrylic acid dimer. Furthermore, an addition product of a monomer having a hydroxyl group, such as 2-hydroxyethyl(meth)acrylate, and a cyclic anhydride, such as maleic anhydride, phthalic anhydride or cyclohexanedicarboxylic anhydride; and ω-carboxypolycaprolactone mono(meth)acrylate can also be used. As a precursor of the carboxyl group, it is possible to use a monomer containing an anhydride such as maleic anhydride, itaconic anhydride or citraconic anhydride. Among them, (meth)acrylic acid is preferable in consideration of copolymerizability, costs, solubility and the like.

Examples of the vinyl monomer having a sulfonic acid group include 2-acrylamide-2-methylpropanesulfonic acid. Examples of the vinyl monomer having a phosphoric acid group include phosphoric acid mono(2-acryloyloxyethyl ester), and phosphoric acid mono(1-methyl-2-acryloyloxyethyl ester).

Furthermore, as the vinyl monomer having an acidic group, it is also possible to use a vinyl monomer containing a phenolic hydroxyl group, a vinyl monomer containing a sulfonamide group, or the like.

Among the polymer compounds represented by Formula (3), a polymer compound represented by the following Formula (3-2) is preferable.

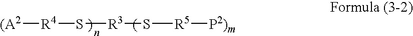

In Formula (3-2), A² represents a monovalent organic group containing at least one moiety selected from an organic dye structure, a heterocyclic structure, an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group and a hydroxyl group. Each A², the number of which is n, may be the same as or different from each other.

A² has the same definition as A¹ in Formula (3), and preferable embodiments thereof are the same as those of A¹ in Formula (3).

In Formula (3-2), R⁴ and R⁵ each independently represent a single bond or a divalent organic linking group. Each R⁴, the number of which is n, may be the same as or different from each other. Furthermore, each R⁵, the number of which is m, may be the same as or different from each other.

Examples of the divalent organic linking group represented by R⁴ or R⁵ are the same as those described above as examples of the divalent organic linking group represented by R² in Formula (3), and preferable embodiments thereof are also the same as those of the divalent organic linking group represented by R² in Formula (3).

In Formula (3-2), R³ represents an organic linking group having a valency of (m+n), where m+n is from 3 to 10.

The organic linking group having a valency of (m+n) represented by R³ may be a group composed of 1 to 60 carbon atoms, 0 to 10 nitrogen atom, 0 to 50 oxygen atoms, 1 to 100 hydrogen atoms, and 0 to 20 sulfur atoms, and the organic linking group may be unsubstituted or may further have a substituent.

Specific examples of the organic linking group having a valency of (m+n) represented by R³ include the same groups as those described above as examples of the organic linking group having a valency of (m+n) represented by R¹ in Formula (3), and preferable embodiments thereof are also the same as those of the organic linking group having a valency of (m+n) represented by R¹ in Formula (3).

In Formula (3-2), m represents from 1 to 8, preferably from 1 to 5, more preferably from 1 to 4, and still more preferably from 1 to 3.

Furthermore, in Formula (3-2), n is from 2 to 9, preferably from 2 to 8, more preferably from 2 to 7, and still more preferably from 3 to 6.

In Formula (3-2), P² represents a polymer skeleton, and may be selected from known polymers in accordance with the purpose. Each P², the number of which is m, may be the same as or different from each other. Preferable embodiments of the polymer are the same as those of P¹ in Formula (3).

Among the polymer compounds represented by Formula (3-2), a polymer compound which satisfies all of the conditions for R³, R⁴, R⁵, P², m and n shown below is most preferable.

R³: Specific examples (1), (2), (10), (11), (16) or (17), described above as specific examples of the organic linking group represented by R¹ in Formula (3)

R⁴: A single bond, or a divalent organic linking group composed of “1 to 10 carbon atoms, 0 to 5 nitrogen atoms, 0 to 10 oxygen atoms, 1 to 30 hydrogen atoms, and 0 to 5 sulfur atoms” and constituted by one of the following structural units or a combination of two or more structural units each of which is selected from the following structural units, where the divalent organic linking group may have a substituent, and examples of the substituent include an alkyl group having 1 to 20 carbon atoms, such as a methyl group or an ethyl group; an aryl group having 6 to 16 carbon atoms, such as a phenyl group or a naphthyl group; a hydroxyl group; an amino group; a carboxyl group; a sulfonamide group; an N-sulfonylamide group; an acyloxy group having 1 to 6 carbon atoms, such as an acetoxy group; an alkoxy group having 1 to 6 carbon atoms, such as a methoxy group or an ethoxy group; a halogen atom such as chlorine or bromine; an alkoxycarbonyl group having 2 to 7 carbon atoms, such as a methoxycarbonyl group, an ethoxycarbonyl group or a cyclohexyloxycarbonyl group; a cyano group; and a carbonic acid ester group such as t-butyl carbonate.

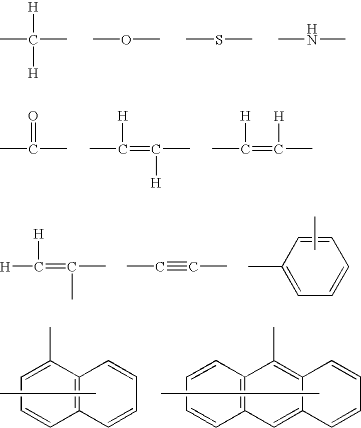

R⁵: A single bond, an ethylene group, a propylene group, the following group (a), or the following group (b)

In the following groups, R²⁵ represents a hydrogen atom or a methyl group; and l represents 1 or 2.

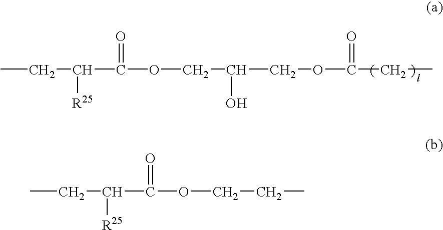

P²: A polymer or copolymer of a vinyl monomer, an ester polymer, an ether polymer, a urethane polymer, or a modified product thereof

m: 1 to 3

n: 3 to 6

The acid value of the polymer compound is not particularly limited. When the polymer compound is used as a pigment dispersant, the acid value is preferably 200 mg KOH/g or less, more preferably 160 mg KOH/g or less, and particularly preferably 120 mg KOH/g or less. When the acid value exceeds 200 mg KOH/g, the pigment dispersibility and dispersion stability may be deteriorated.

When the polymer compound together with a pigment is used in a photosensitive composition requiring an alkali development treatment, the acid value of the polymer compound is preferably from 30 mg KOH/g to 200 mg KOH/g, more preferably from 40 mg KOH/g to 160 mg KOH/g, and still more preferably from 50 mg KOH/g to 120 mg KOH/g. When the acid value is less than 30 mg KOH/g, the alkali developability of the photosensitive composition may be insufficient, whereas when the acid value exceeds 200 mg KOH/g, the pigment dispersibility and dispersion stability may be deteriorated.

The molecular weight of the polymer compound is, in terms of the weight average molecular weight, preferably from 3,000 to 100,000, more preferably from 5,000 to 80,000, and particularly preferably from 7,000 to 60,000. When the weight average molecular weight is within the above range, the effects produced by the plural adsorptive moieties introduced at a terminal of the polymer are sufficient, and the polymer compound shows excellent performance in adsorbability to solid surfaces, micelle forming capability and surface-active properties. In particular, when the polymer compound according to the invention is used as a pigment dispersant, good dispersibility and dispersion stability may be achieved.

Synthesis Method

The method for synthesizing the polymer compound represented by Formula (3) (encompassing the compound represented by Formula (3-2)) is not particularly limited, and the polymer compound represented by Formula (3) may be synthesized by the following methods and the like.

1. A method of performing a polymer reaction of a polymer having a functional group selected from a carboxyl group, a hydroxyl group, an amino group and the like introduced at a terminal thereof, with an acid halide having a plurality of aforementioned adsorptive moieties, alkyl halide having a plurality of aforementioned adsorptive moieties, or isocyanate having a plurality of aforementioned adsorptive moieties.

2. A method of performing a Michael addition reaction of a polymer having a carbon-carbon double bond introduced at a terminal thereof, with a mercaptan having a plurality of aforementioned adsorptive moieties.

3. A method of reacting a polymer in which a carbon-carbon double bond has been introduced to a terminal, with a mercaptan having an aforementioned adsorptive moiety, in the presence of a radical generator.

4. A method of reacting a polymer in which plural mercaptan groups have been introduced to at least one terminal, with a compound having a carbon-carbon double bond and an aforementioned adsorptive moiety, in the presence of a radical generator.

5. A method of radical polymerizing a vinyl monomer in the presence of a mercaptan compound having a plurality of aforementioned adsorptive moieties.

Among these methods, the polymer compound that can be used as a pigment dispersant of the invention is preferably synthesized by the synthesis method of item 2, 3, 4 or 5, and more preferably by the synthesis method of item 3, 4 or 5, from the viewpoint of the ease of synthesis. In particular, when the polymer compound has a structure represented by Formula (3-2), it is most preferable to synthesize the polymer compound by the synthesis method of item 5, from the viewpoint of the ease of synthesis.

As the synthesis method of item 5, more specifically, a method of radical polymerizing a vinyl monomer in the presence of a compound represented by the following Formula (3-3) is preferable.

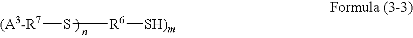

In Formula (3-3), R⁶, R⁷, A³, m and n have the same definitions as R³, R⁴, A², m and n in Formula (3-2), respectively, and have the same preferable embodiments as R³, R⁴, A², m and n in Formula (3-2), respectively.

The compound represented by Formula (3-3) can be synthesized by the following methods. From the viewpoint of ease in synthesis, the following method of item 7 is more preferable.

6. A method including converting a halide compound having a plurality of aforementioned adsorptive moieties into a mercaptan compound (such as a method including reacting with thiourea and then hydrolyzing the product, a method including reacting directly with NaSH, or a method including reacting with CH₃COSNa and then hydrolyzing the product).

7. A method including subjecting a compound having 3 to 10 mercapto groups in one molecule, and a compound having an aforementioned adsorptive moiety and a functional group capable of reacting with a mercapto group, to an addition reaction.

In the synthesis method of item 7, suitable examples of the “functional group capable of reacting with a mercapto group” include an acid halide, an alkyl halide, an isocyanate, and a carbon-carbon double bond.

It is particularly preferable that the “functional group capable of reacting with a mercapto group” is a carbon-carbon double bond and the addition reaction is a radical addition reaction. In addition, the carbon-carbon double bond is more preferably a monosubstituted or disubstituted vinyl group from the viewpoint of the reactivity with a mercapto group.

Specific examples of the compound having 3 to 10 mercapto groups in one molecule (specific examples (18) to (34)) include the following compounds.

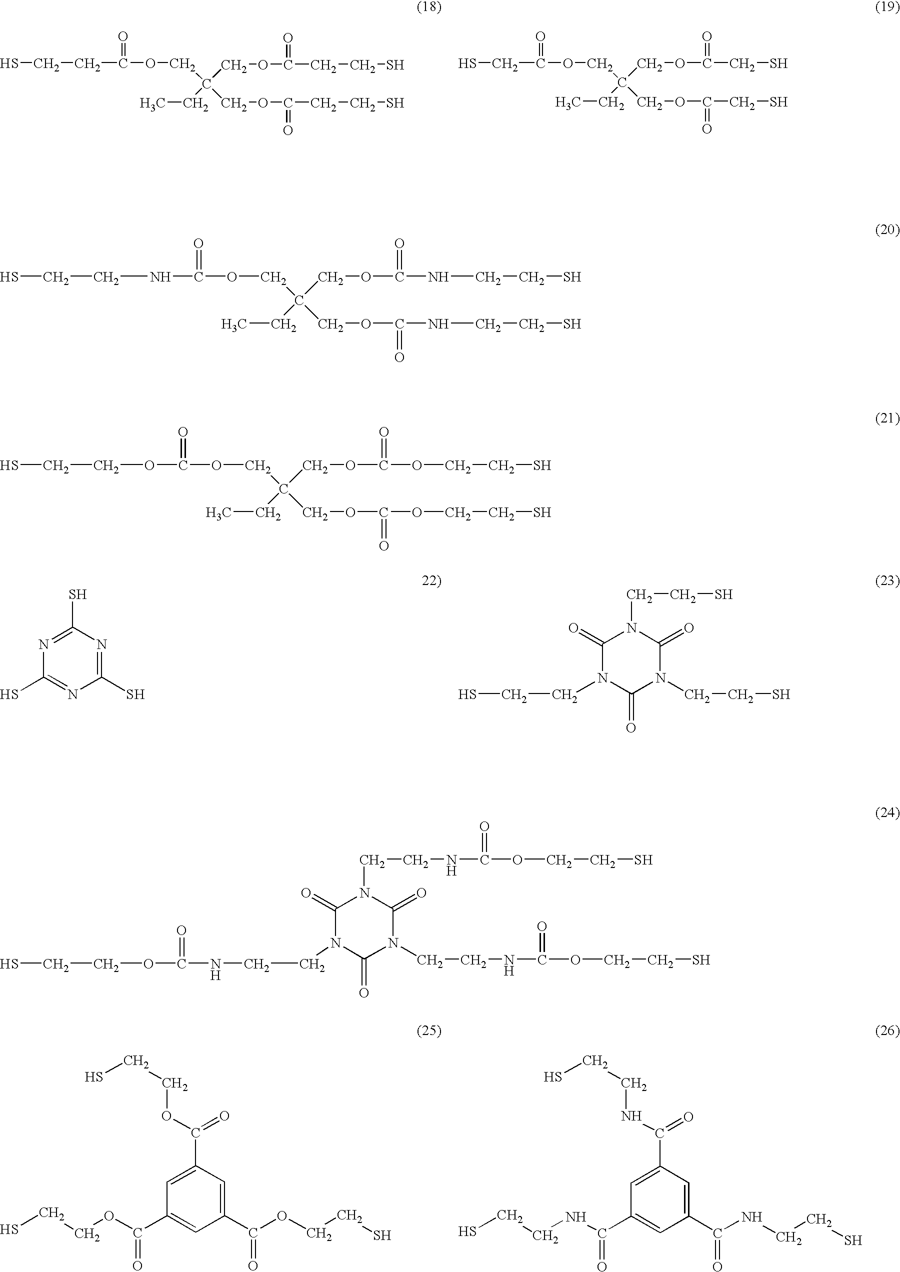

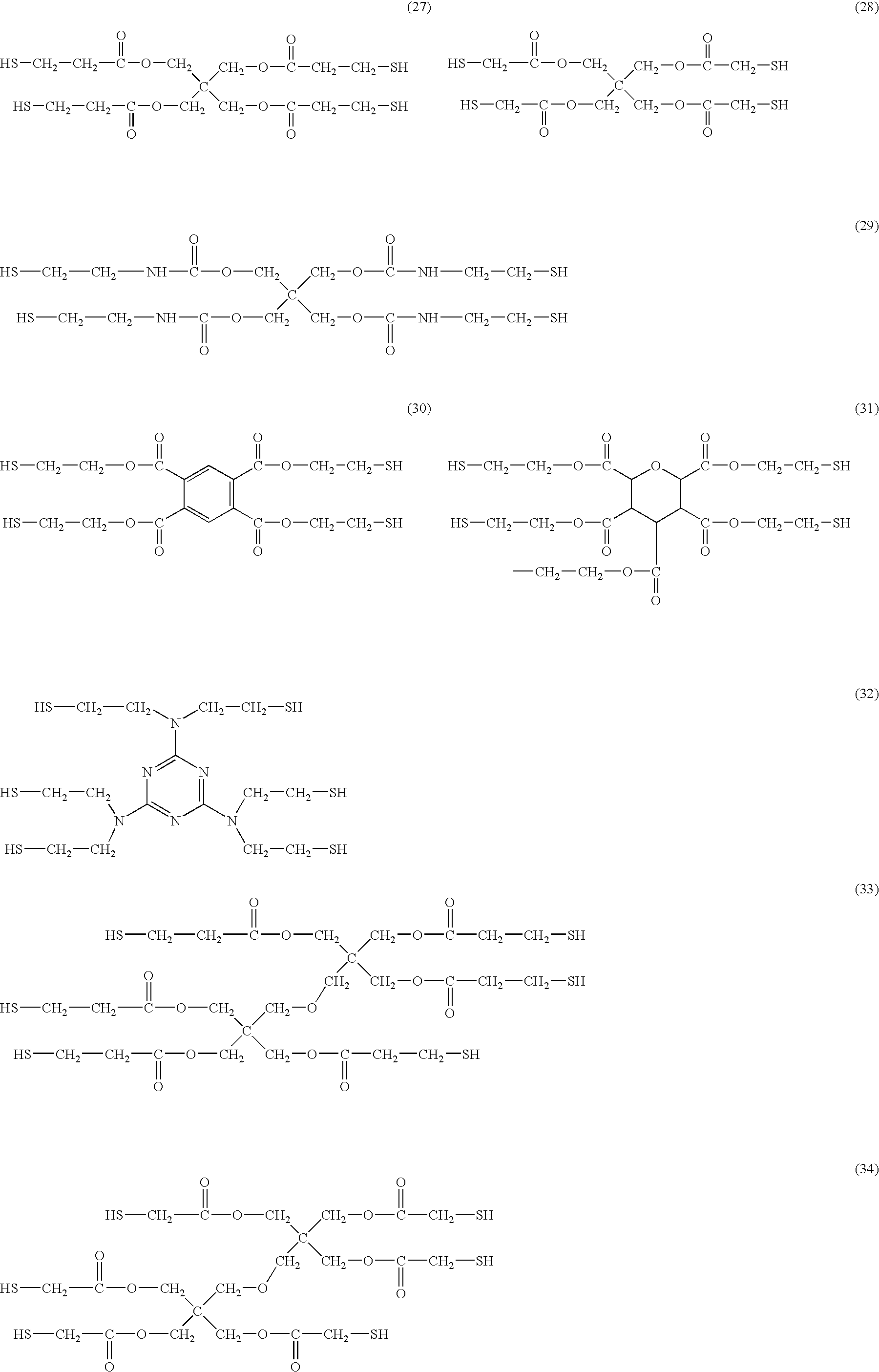

Among the above compounds, the following compounds are particularly preferable from the viewpoints of the availability of raw materials, ease in synthesis, and solubility in various solvents.

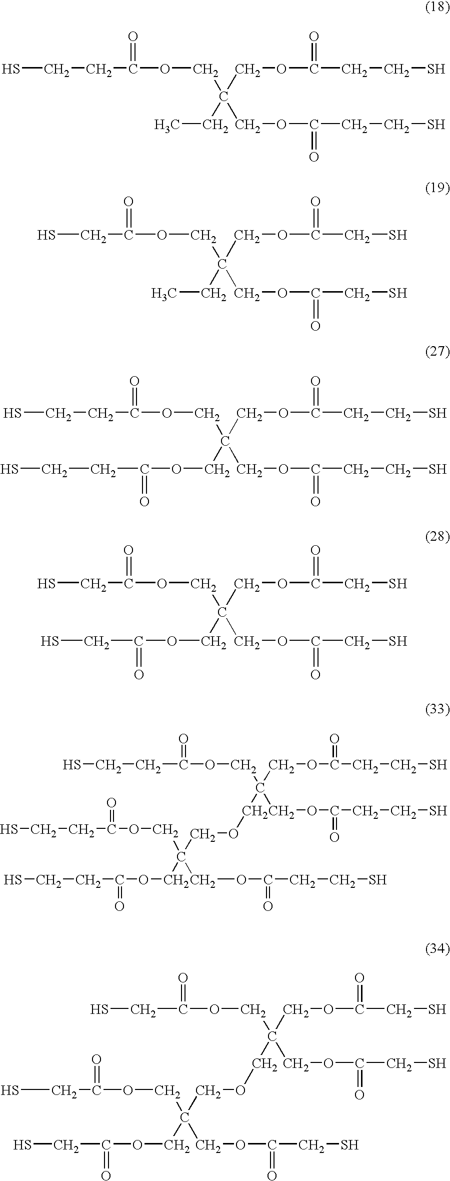

The compound having an aforementioned adsorptive moiety and a carbon-carbon double bond (specifically, a compound having a carbon-carbon double bond and at least one moiety selected from an organic dye structure, a heterocyclic structure, an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group and a hydroxyl group) is not particularly limited, and examples thereof include the following.

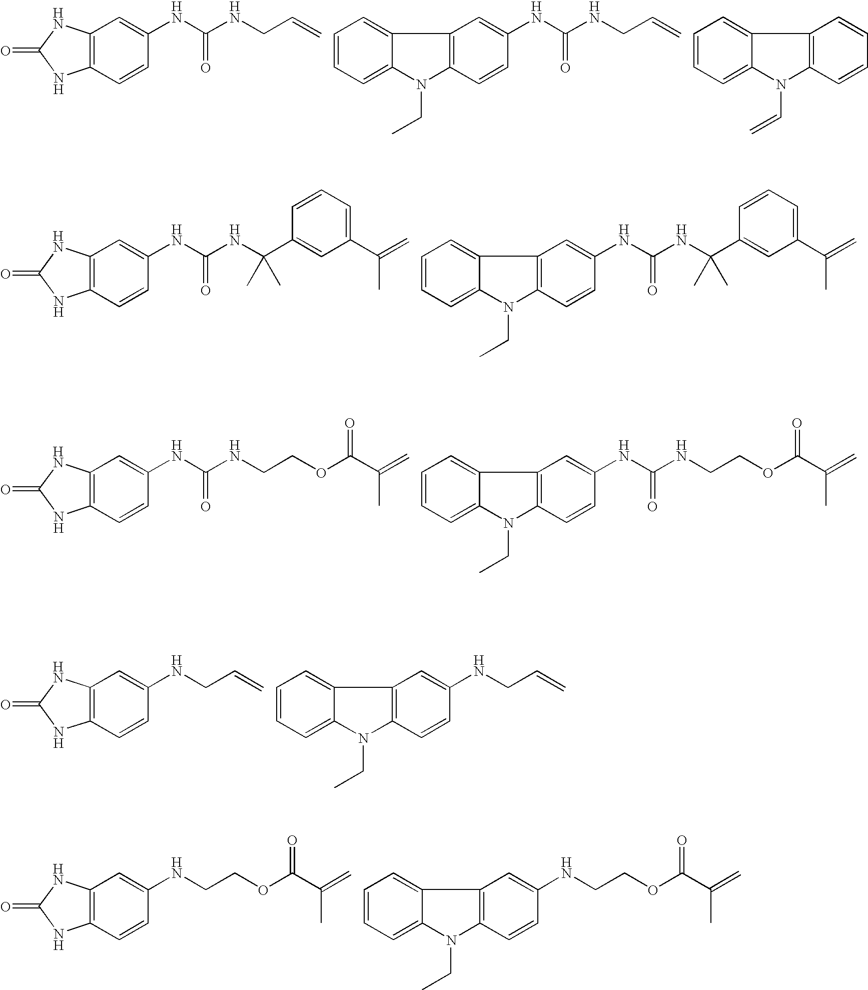

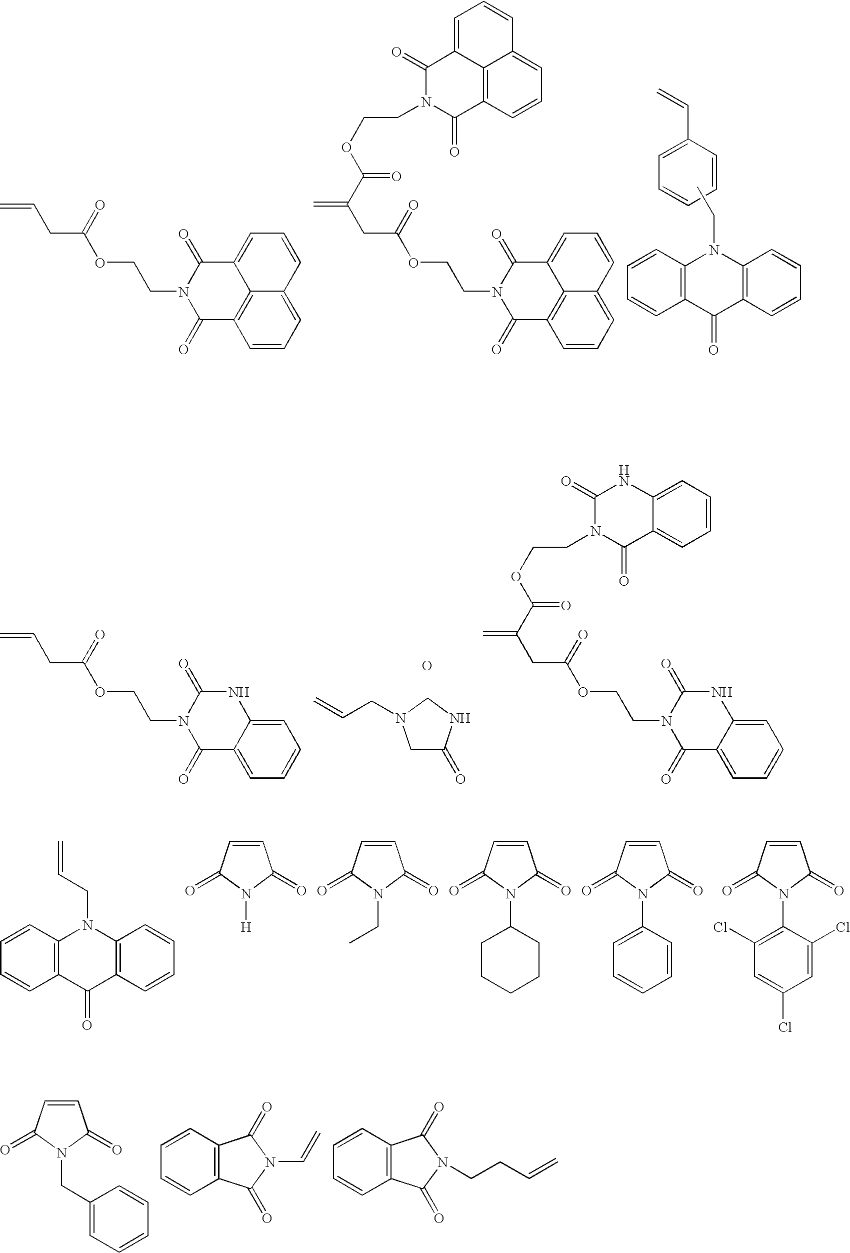

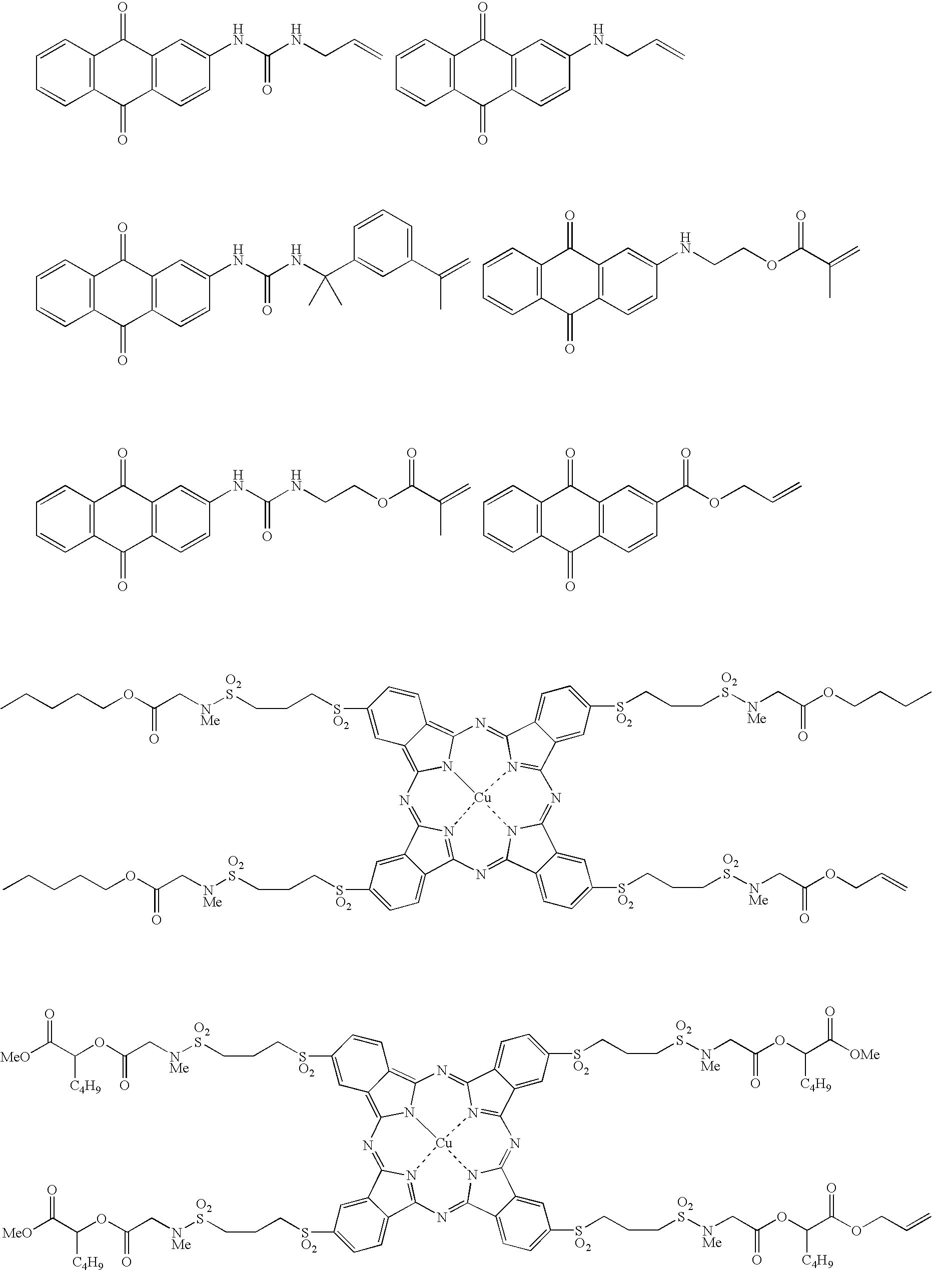

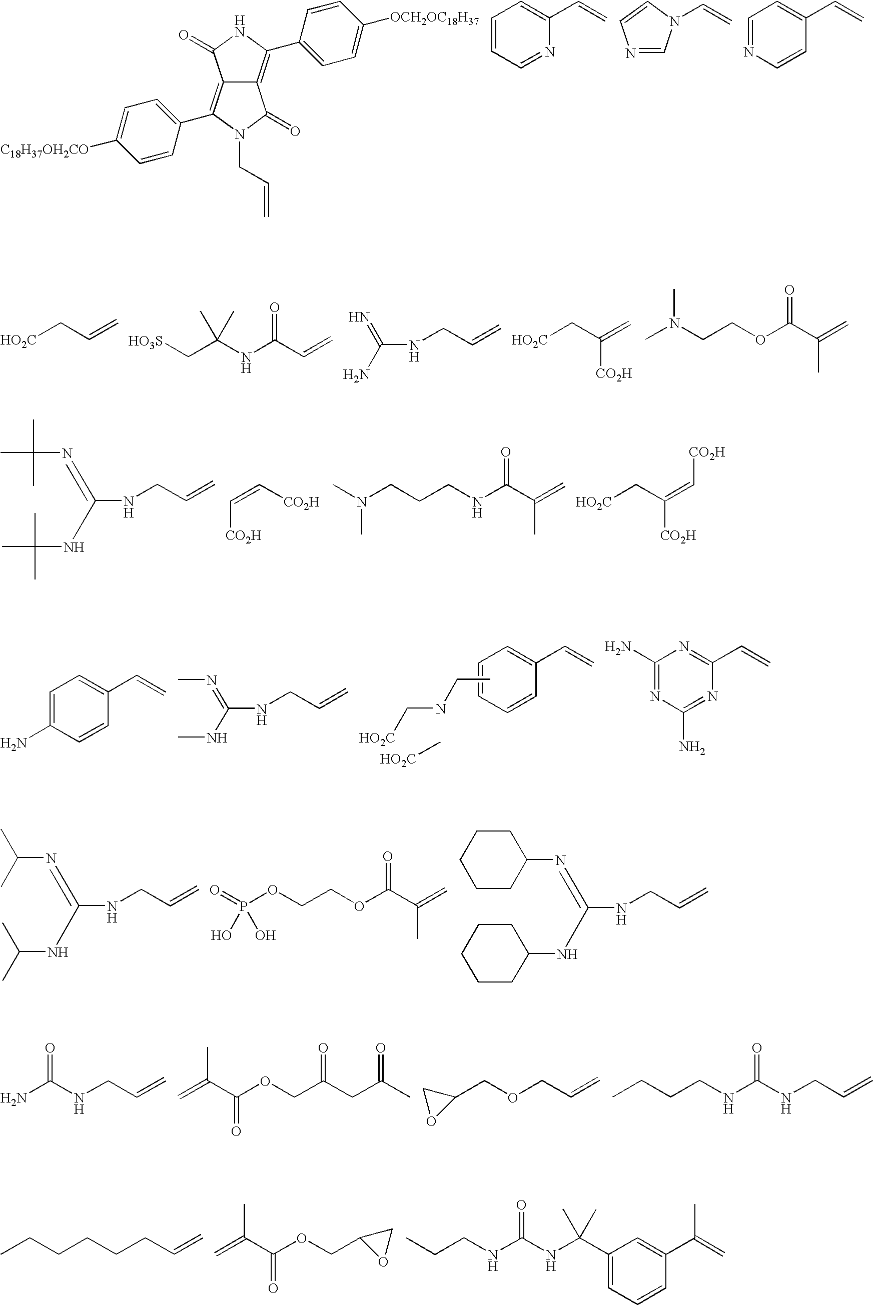

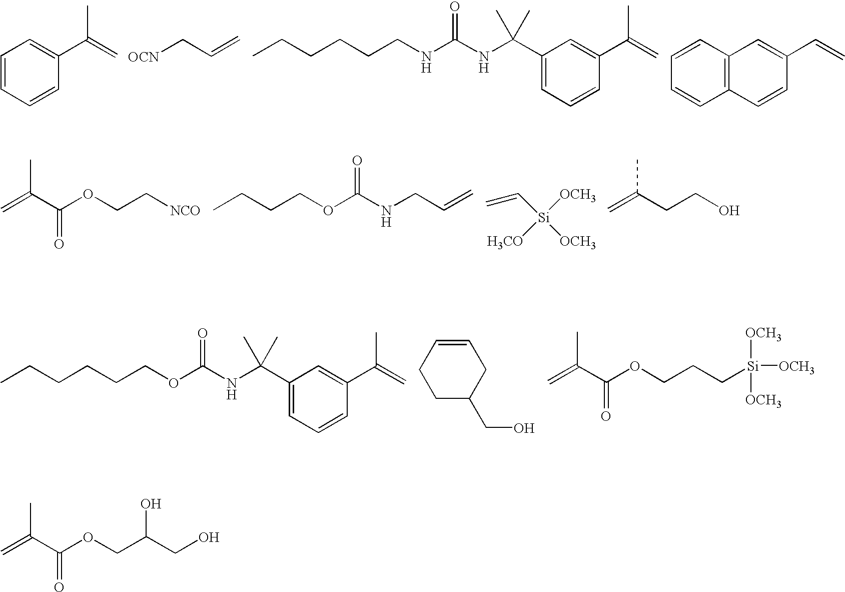

The radical addition reaction product of the “compound having 3 to 10 mercapto groups in one molecule” and the “compound having the adsorptive moiety and a carbon-carbon double bond,” is obtained using, for example, a method including dissolving the “compound having 3 to 10 mercapto groups in one molecule” and the “compound having the adsorptive moiety and a carbon-carbon double bond” in a suitable solvent, adding a radical generator thereto, and allowing the addition to proceed at about 50° C. to 100° C. (thiol-ene reaction method).

Examples of the suitable solvent used in the thiol-ene reaction method may be arbitrarily selected in accordance with the solubility of the “compound having 3 to 10 mercapto groups in one molecule” and the “compound having the adsorptive moiety and a carbon-carbon double bond” to be used, and the solubility of the “generated radical addition reaction product.”

For example, examples of the suitable solvent include methanol, ethanol, propanol, isopropanol, 1-methoxy-2-propanol, 1-methoxy-2-propyl acetate, acetone, methyl ethyl ketone, methyl isobutyl ketone, methoxypropyl acetate, ethyl lactate, ethyl acetate, acetonitrile, tetrahydrofuran, dimethylformamide, chloroform, and toluene. In an embodiment, a mixture of two or more kinds thereof is used.

As the radical generator, an azo compound such as 2,2′-azobis(isobutyronitrile) (AIBN), 2,2′-azobis-(2,4′-dimethylvaleronitrile) or dimethyl 2,2′-azobisisobutyrate; a peroxide such as benzoyl peroxide; or a persulfuric acid salt such as potassium persulfate or ammonium persulfate; or the like may be used.

The vinyl monomer used in the synthesis method of item 5 is not particularly limited. For example, the above-mentioned vinyl monomers that can be used for obtaining the polymer skeleton represented by P¹ in Formula (3) may be used.

The polymerization may be conducted with only one kind of vinyl monomer, or two or more kinds of vinyl monomers may be used in combination to perform copolymerization.

When the polymer compound is applied to a photosensitive composition requiring alkali development treatment, it is more preferable to copolymerize one or more vinyl monomers having an acidic group and one or more vinyl monomers having no acidic group.

The polymer compound is preferably a polymer compound obtained by performing polymerization using the vinyl monomer(s) and a compound represented by Formula (3-3) by a known method according to a conventional procedure. In addition, the compound represented by Formula (3-3) in the invention is a compound functioning as a chain transfer agent, and thus the compound is also simply referred to as “chain transfer agent” hereinafter in some cases.

The polymer compound is obtained, for example, using a method including dissolving such a vinyl monomer and the chain transfer agent in an appropriate solvent, adding a radical polymerization initiator thereto, and performing polymerization at about 50° C. to 220° C. in a solution (solution polymerization method).

Examples of the appropriate solvent used in the solution polymerization method may be arbitrarily selected in accordance with the solubility of the monomer used and the copolymer generated. Examples thereof include methanol, ethanol, propanol, isopropanol, 1-methoxy-2-propanol, 1-methoxy-2-propyl acetate, acetone, methyl ethyl ketone, methyl isobutyl ketone, methoxypropyl acetate, ethyl lactate, ethyl acetate, acetonitrile, tetrahydrofuran, dimethylformamide, chloroform, and toluene. In an embodiment, a mixture of two or more of these solvents is used.

As the radical polymerization initiator, an azo compound such as 2,2′-azobis(isobutyronitrile) (AIBN), 2,2′-azobis-(2,4′-dimethylvaleronitrile) or dimethyl 2,2′-azobisisobutyrate; a peroxide such as benzoyl peroxide; a persulfuric acid salt such as potassium persulfate or ammonium persulfate; or the like may be used.

The pigment-dispersed composition of the invention is prepared to include the aforementioned polymer compound as a pigment dispersant for dispersing a pigment, and in addition to the polymer compound, dispersants such as conventional known pigment dispersants or surfactants, and other components may also be added for the purpose of further enhancing the dispersibility of pigment.

As to known dispersants (pigment dispersants), examples thereof include polymeric dispersants (for example, polyamideamines and salts thereof, polycarboxylic acids and salts thereof, high-molecular-weight unsaturated acid esters, modified polyurethanes, modified polyesters, modified poly(meth)acrylates, (meth)acrylic copolymers, naphthalenesulfonic acid-formalin condensates), polyoxyethylene alkylphosphoric acid esters, polyoxyethylene alkylamines, alkanolamines, and pigment derivatives.

The polymeric dispersants may be further classified, on the basis of the structure, into straight-chained polymers, terminal-modified polymers, graft polymers, and block polymers.

The polymeric dispersant is adsorbed on the surface of a pigment, and acts to prevent re-aggregation. For that reason, preferable examples of the polymeric dispersant include a terminal-modified polymer having an anchor moiety for the pigment surface, a graft polymer, and a block polymer. On the other hand, a pigment derivative has an effect of promoting the adsorption of the polymeric dispersant by modifying the pigment surface.

Specific examples of the known dispersants (pigment dispersants) that may be used in the invention, include DISPERBYK-101 (polyamidoamine phosphate), -107 (carboxylic acid ester), -110 (copolymer containing an acid group), -130 (polyamide), -161, -62, -163, -164, -165, -166, -170 (high-molecular-weight copolymers), and BYK-P104, P105 (high-molecular-weight unsaturated polycarboxylic acids) (trade names, all manufactured by BYK Chemie GmbH); EFKA4047, 4050, 4010,4165 (polyurethane-based), EFKA 4330, 4340 (block copolymers), 4400, 4402 (modified polyacrylates), 5010 (polyester amide), 5765 (high-molecular-weight polycarboxylic acid salt), 6220 (fatty acid polyester), 6745 (phthalocyanine derivative), and 6750 (azo pigment derivative) (trade names, all manufactured by EFKA GmbH & Co. KG); AJISPER PB821, and PB822 (trade names, manufactured by Ajinomoto Fine Techno Co., Inc.); FLOWLEN TG-710 (urethane oligomer), and POLYFLOW No. 50E, No. 300 (acrylic copolymers) (trade names, all manufactured by Kyoeisha Chemical Co., Ltd).; DISPARLON KS-860, 873SN, 874, #2150 (aliphatic polyvalent carboxylic acids), #7004 (polyether ester), and DA-703-50, DA-705, DA-725 (trade names, all manufactured by Kusumoto Chemicals, Ltd.); DEMOL RN, N (naphthalenesulfonic acid-formalin polycondensates), MS, C, SN-B (aromatic sulfonic acid-formalin polycondensates), HOMOGENOL L-18 (high-molecular-weight polycarboxylic acid), EMULGEN 920, 930, 935, 985 (polyoxyethylene nonyl phenyl ethers), and ACETAMIN 86 (stearylamine acetate) (trade names, all manufactured by Kao Corporation); SOLSPERSE 5000 (phthalocyanine derivative) 22000 (azo pigment derivative), 13240 (polyesteramine), 3000, 17000, 27000 (polymers having functional moieties at terminal portions), and 24000, 28000, 32000, 38500 (graft type polymers) (trade names, all manufactured by The Lubrizol Corporation); and NIKKOL T106 (polyoxyethylene sorbitan monooleate), and MYS-IEX (polyoxyethylene monostearate) (trade names, manufactured by Nikko Chemicals Co., Ltd.)

Other Components

The pigment-dispersed composition may further contain other components selected appropriately depending on purpose in addition to the aforementioned pigment derivative and the dispersant. Examples of other components include the known dispersants described above.

The pigment-dispersed composition may further contain an amine compound represented by Formula (4) or Formula (5):

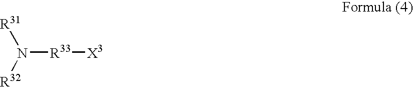

In Formula (4), R³¹ and R³² each independently represent a hydrogen atom, or an alkyl or aralkyl group which may be unsubstituted or may further have a substituent. R³¹ and R³² may be bound to each other to form a saturated 5- to 6-membered ring containing a nitrogen atom. This saturated ring may further contain 1 to 3 atoms each of which is selected from an oxygen atom, a sulfur atom and a nitrogen atom. R³³ represents an alkylene group or an alkylene group containing an ether bond. X³ represents —CON(Y³¹)(Y³²), —OCON(Y³¹)(Y³²), —N(Y³³)CO(Y³⁴), or —N(Y³³)CON(Y³¹)(Y³²). Y³¹, Y³²,Y³³ and Y³⁴ each independently represent a hydrogen atom, or an alkyl group, an aralkyl or an aryl group, each of which may be unsubstituted or substituted.

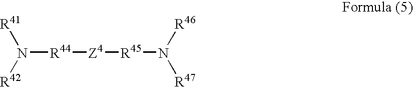

In Formula (5), R⁴¹, R⁴², R⁴⁶ and R⁴⁷ each independently represent a hydrogen atom, or an alkyl or aralkyl group which may further have a substituent. Any two of R⁴¹, R⁴², R⁴⁶ and R⁴⁷ may be bound to each other to form a saturated 5- to 6-membered ring containing a nitrogen atom. This saturated ring may further contain 1 to 3 atoms each of which is selected from an oxygen atom, a sulfur atom and a nitrogen atom. R⁴⁴ and R⁴⁵ each independently represent an alkylene group or an alkylene group containing an ether bond. Z⁴ represents —CON(Y⁴¹)—, —OCON(Y⁴¹)— or —N(Y⁴²)CON(Y⁴³)—. Y⁴¹, Y⁴² and Y⁴³ have the same definitions as Y³¹, Y³² and Y³³ in Formula (4), respectively.

Preferable examples of the amine compounds represented by Formula (4) or Formula (5) include bis(2-(1-morpholino)ethyl)terephthalamide.

The pigment-dispersed composition may contain various surfactants, and when the surfactants are contained, dispersion stability is effectively improved. Examples of the surfactants include anionic surfactants such as alkylnaphthalene sulfonates and phosphates, cationic surfactants such as amine salts, and amphoteric surfactants such as aminocarboxylic acids and betaine type surfactants.

The pigment-dispersed composition used for preparing a color filter layer in the invention is configured to include at least one pigment and the aforementioned pigment dispersant of the invention in an organic solvent, and if necessary, other components such as resin components may be used in the pigment-dispersed composition. Since this pigment-dispersed composition includes at least one polymer compound of the invention described above as a pigment dispersant, the dispersed state of the pigment in the organic solvent can improve, and thus excellent color properties can be obtained. In particular, an excellent dispersing effect is exerted on organic pigments.

<Colored Photosensitive Composition>

A colored photosensitive composition containing the pigment-dispersed composition is used in forming a color filter layer in the display device of the invention.

The colored photosensitive composition contains the pigment-dispersed composition containing the pigment as a colorant, and also contains a polymerizable compound, a photopolymerization initiator, and, optionally, various other compounds.

The amount of the pigment-dispersed composition added to the colored photosensitive composition is established in such a range that the concentration of the pigment in the photosensitive composition is in the range of from 10% by mass to 60% by mass, more preferably in the range of from 15% by mass to 50% by mass. When the pigment concentration is in this range, an effect of eliminating residues can be exerted.

Photopolymerizable Compound

The colored photosensitive composition used for preparing a color filter layer of the invention includes at least one photopolymerizable compound in addition to the pigment-dispersed composition. The photopolymerizable compound that can be used in the invention is an addition-polymerizable compound having at least one ethylenic unsaturated double bond, and is selected from compounds having at least one, and preferably two or more, terminal ethylenic unsaturated bonds. Such compounds are widely known in the art, and may be used in the invention without particularly restrictions. These compounds may be in a form of, for example, monomer, prepolymer (i.e., dimer, trimer and oligomer), or a mixture thereof, or a copolymer thereof.

Examples of the monomer and copolymers thereof include unsaturated carboxylic acids (for example, acrylic acid, methacrylic acid, itaconic acid, crotonic acid, isocrotonic acid, and maleic acid), and esters and amides thereof. It is preferable to use an ester of an unsaturated carboxylic acid and an aliphatic polyhydric alcohol compound or an amide of an unsaturated carboxylic acid and an aliphatic polyvalent amine compound. It is also preferable to use an adduct of an unsaturated carboxylic acid ester or amide having a nucleophilic substituent such as a hydroxyl group, an amino group or a mercapto group, with a monofunctional or polyfunctional isocyanate or epoxy; or a dehydration condensation product of the unsaturated carboxylic acid ester or amide having a nucleophilic substituent such as a hydroxyl group, an amino group or a mercapto group, with a monofunctional or polyfunctional carboxylic acid. Furthermore, an adduct of an unsaturated carboxylic acid ester or amide having an electrophilic substituent such as an isocyanate group or an epoxy group, with a monofunctional or polyfunctional alcohol, amine or thiol; and a substitution product of an unsaturated carboxylic acid ester or amide having a leaving substituent such as a halogen group or a tosyloxy group, with a monofunctional or polyfunctional alcohol, amine or thiol, are also preferable. It is also possible to use compounds in which the unsaturated carboxylic acid is replaced by an unsaturated phosphonic acid, styrene, vinyl ether or the like.

Specific examples of the monomer of the ester of an aliphatic polyhydric alcohol compound and an unsaturated carboxylic acid include acrylic acid esters, such as ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, polyester acrylate oligomer, or isocyanuric acid EO-modified triacrylate;

methacrylic acid esters, such as tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, or bis[p-(methacryloxyethoxy)phenyl]dimethylmethane;

itaconic acid esters, such as ethylene glycol diitaconate, propylene glycol diitaconate, 1,3-butanediol diitaconate, 1,4-butanediol diitaconate, tetramethylene glycol diitaconate, pentaerythritol diitaconate, or sorbitol tetraitaconate;

crotonic acid esters, such as ethylene glycol dicrotonate, tetramethylene glycol dicrotonate, pentaerythritol dicrotonate, or sorbitol tetracrotonate;

isocrotonic acid esters, such as ethylene glycol diisocrotonate, pentaerythritol diisocrotonate, or sorbitol tetraisocrotonate; and

maleic acid esters, such as ethylene glycol dimaleate, triethylene glycol dimaleate, pentaerythritol dimaleate, or sorbitol tetramaleate.

As other esters, for example, it is also preferable to use aliphatic alcohol-based esters such as those described in JP-B No. 51-47334 and JP-A No. 57-196231; esters having an aromatic skeleton such as those described in JP-A Nos. 59-5240, 59-5241 and 2-226149; esters containing an amino group such as those described in JP-A No. 1-165613; and the like. Furthermore, the above-mentioned ester monomer may be used as a mixture.

Specific examples of the monomer of the amide of an aliphatic polyvalent amine compound and an unsaturated carboxylic acid include methylenebisacrylamide, methylenebismethacrylamide, 1,6-hexamethylenebisacrylamide, 1,6-hexamethylenebismethacrylamide, diethylenetriaminetrisacrylamide, xylylenebisacrylamide, and xylylenebismethacrylamide. Other examples of preferable monomer of the amide include those having a cyclohexylene structure such as those described in JP-B No. 54-21726.

Furthermore, urethane addition-polymerizable compounds produced by an addition reaction of an isocyanate with a hydroxyl group are also suitable for the photopolymerizable compound, and specific examples thereof include the vinylurethane compound containing two or more polymerizable vinyl groups in one molecule, which is produced by addition of a vinyl monomer containing a hydroxyl group represented by the following Formula (a) to a polyisocyanate compound having two or more isocyanate groups in one molecule, such as those described in JP-B No. 48-41708.

CH₂═C(R)COOCH₂CH(R′)OH Formula (a)

where R and R′ each independently represent H or CH₃.

Urethane acrylates such as those described in JP-A No. 51-37193, JP-B Nos. 2-32293 and 2-16765, or the urethane compounds having an ethylene oxide skeleton such as those described in JP-B Nos. 58-49860, 56-17654, 62-39417 and 62-39418, are also suitable for the photopolymerizable compound. When the addition-polymerizable compounds having an amino structure or sulfide structure in the molecule, such as those described in JP-A Nos. 63-277653, 63-260909, and 1-105238 are used, a photopolymerizable composition with an excellent photosensitive speed may be obtained.

Other examples of the photopolymerizable compound include polyfunctional acrylates and methacrylates, such as polyester acrylates and epoxy acrylates obtained by a reaction of epoxy resins with (meth)acrylic acid such as those described in JP-A No. 48-64183, JP-B Nos. 49-43191 and 52-30490; the specific unsaturated compounds such as those described in JP-B Nos. 46-43946, 1-40337 and 1-40336; and the vinylphosphonic acid compounds such as those described in JP-A No. 2-25493. In some cases, the structure containing a perfluoroalkyl group such as those described in JP-A No. 6122048 can be suitably used. Photocurable monomers and oligomers as described in Journal of the Adhesion Society of Japan (Nippon Setchaku Kyoukaishi), Vol. 20, No. 7, pp. 300-308 (1984) can also be used.

With regard to these addition-polymerizable compounds, the structure thereof, and details of the usage thereof such as whether the compound is used alone or in combination and the addition amount thereof, and the like, may be arbitrarily set in accordance with the design of the performance of a final photosensitive material.

For example, the conditions may be selected based on the following considerations. In consideration of sensitivity, a structure having a large content of unsaturated groups per one molecule is preferable, and in many cases, a bi- or higher-functional compound is preferable. In order to increase the strength of a cured film, a tri- or higher-functional compound is favorable. Further, a method in which compounds having different functionalities and/or different polymerizable groups (for example, an acrylic acid ester, a methacrylic acid ester, a styrene compound, or a vinyl ether compound) are used in combination to control both sensitivity and strength, may also be effectively employed.

Selection and usage of the addition-polymerizable compound are important factors for dispersibility and compatibility with other components in the colored photosensitive composition (for example, a binder polymer such as an alkali-soluble resin, a photopolymerization initiator, and a colorant (pigment)). For example, the compatibility may be improved by using either a low-purity addition-polymerizable compound or two or more addition-polymerizable compounds.

For the purpose of improving adhesion to a substrate or the like, a specific structure may be selected. The addition-polymerizable compound can be used preferably in the range of from 5% by mass to 70% by mass, more preferably from 10% by mass to 60% by mass, with respect to nonvolatile components in the colored photosensitive composition. The addition-polymerizable compound may be used singly or in combination of two or more kinds thereof. For usage of the addition-polymerizable compound, a suitable structure, composition and amount of the addition-polymerizable compound may be arbitrarily selected from the viewpoints of the degree of polymerization inhibition by oxygen, resolution, fogging, refractive index change, surface stickiness, and the like.

Photopolymerization Initiator

It is preferable to use a photopolymerization initiator in the colored photosensitive composition of the invention.

Examples of the photopolymerization initiator that can be used in the invention include a halomethyl oxadiazole such as those described in JP-A No. 60-3626; activated halogenated compounds such as halomethyl-s-triazine such as those described in JP-B No. 59-1281, JP-A No. 53-133428; aromatic carbonyl compounds such as ketal, acetal or benzoin alkyl ethers such as those described in U.S. Pat. No. 4,318,791 and European Patent Application Laid-Open No. 88050; aromatic ketone compounds such as benzophenones such as those described in U.S. Pat. No. 4,199,420; (thio)xanthone compounds and acridine compounds such as those described in French Patent No. 2456741; coumarin compounds and Iophine dimer compounds such as those described in JP-A No. 10-62986; and sulfonium organoboron complexes such as those described in JP-A No. 8-015521.

Preferable examples of the photopolymerization initiator include acetophenones, ketals, benzophenones, benzoins, benzoyls, xanthones, activated halogenated compounds (triazines, halomethyl oxadiazoles, coumarins), acridines, biimidazoles, and oxime esters.

Preferable examples of the acetophenone photopolymerization initiators include 2,2-diethoxyacetophenone, p-dimethylamino acetophenone, 2-hydroxy-2-methyl-1-phenyl-propan-1-one, p-dimethylamino acetophenone, 4′-isopropyl-2-hydroxy-2-methyl-propiophenone, 1-hydroxy-cyclohexyl phenyl ketone, 2-benzyl-2-dimethylamino-1-(4-morpholinophenyl)-butan-1-one, 2-tolyl-2-dimethylamino-1-(4-morpholinophenyl)-butan-1-one, and 2-methyl-1-[4-(methylthio)phenyl]-2-morpholino-propan-1-one.

Preferable examples of the ketal photopolymerization initiators include benzyl dimethyl ketal, and benzyl-β-methoxy ethyl acetal.

Preferable examples of the benzophenone photopolymerization initiators include benzophenone, 4,4′,-(bisdimethylamino)benzophenone, 4,4′-(bisdiethylamino)benzophenone, and 4,4′-dichloro benzophenone.

Preferable examples of the benzoin or benzoyl photopolymerization initiators include benzoin isopropyl ether, benzoin isobutyl ether, benzoin methyl ether, and methyl-o-benzoylbenzoate.

Preferable examples of the xanthone photopolymerization initiators include diethylthioxanthone, diisopropylthioxantone, monoisopropylthioxantone, and chlorothioxantone.

Preferable examples of the activated halogen compounds (triazines, oxadiazoles, coumarins) include 2,4-bis(trichloromethyl)-6-p-methoxyphenyl-s-triazine, 2,4-bis(trichloromethyl)-6-p-methoxystyryl-s-triazine, 2,4-bis(trichloromethyl)-6-(1-p-dimethylaminophenyl)-1,3-butadienyl-s-triazine, 2,4-bis(trichloromethyl)-6-biphenyl-s-triazine, 2,4-bis(trichloromethyl)-6-(p-methylbiphenyl)-s-triazine, p-hydroxyethoxystyryl-2,6-di(trichloromethyl)-s-triazine, methoxystyryl-2,6-di(trichloromethyl)-s-triazine, 3,4-dimethoxystyryl-2,6-di(trichloromethyl)-s-triazine, 4-benzoxolane-2,6-di(trichloromethyl)-s-triazine, 4-(o-bromo-p-N,N-di(ethoxycarbonylamino)-phenyl)-2,6-di(chloromethyl)-s-triazine, 4-(p-N,N-di(ethoxycarbonylamino)-phenyl)-2,6-di(chloromethyl)-s-triazine, 2-trichloromethyl-5-styryl-1,3,4-oxodiazole, 2-trichloromethyl-5-(cyanostyryl)-1,3,4-oxodiazole, 2-trichloromethyl-5-(naphth-1-yl)-1,3,4-oxodiazole, 2-trichloromethyl-5-(4-styryl)styryl-1,3,4-oxodiazole, 3-methyl-5-amino-((s-triazine-2-yl)amino)-3-phenylcoumarin, 3-chloro-5-diethylamino-((s-triazine-2-yl)amino)-3-phenylcoumarin, and 3-butyl-5-dimethylamino-((s-triazine-2-yl)amino)-3-phenylcoumarin.

Preferable examples of the acridine include 9-phenylacridine, and 1,7-bis(9-acridinyl)heptane.

Preferable examples of the biimidazole photopolymerization initiators include 2-(o-chlorophenyl)-4,5-diphenyl-imidazolyl dimer, 2-(o-methoxyphenyl)-4,5-diphenyl-imidazolyl dimer, and 2-(2,4-dimethoxyphenyl)-4,5-diphenyl-imidazolyl dimer.

Other examples of the photopolymerization initiators include 1-phenyl-1,2-propanedione-2-(o-ethoxycarbonyl)oxime, o-benzoyl-4′-(benzmercapto)benzoyl-hexyl-ketoxime, 2,4,6-trimethylphenylcarbonyl-diphenylphosphonyl oxide, and salts of hexafluoro-phosphoro-trialkylphenylphosphonium.

The photopolymerization initiator of the present invention is not limited to the above photopolymerization initiators, and other known photopolymerization initiators can also be used. Examples thereof include vicinal polyketaldonyl compounds such as those described in the specification of U.S. Pat. No. 2,367,660; α-carbonyl compounds such as those described in the specifications of U.S. Pat. Nos. 2,367,661 and 2,367,670; acyloin ethers such as those described in the specification of U.S. Pat. No. 2,448,828; aromatic acyloin compounds substituted with an α-hydrocarbon such as those described in the specification of U.S. Pat. No. 2,722,512; polynuclear quinone compounds such as those described in the specifications of U.S. Pat. Nos. 3,046,127 and 2,951,758; a combination of triarylimidazolyl dimer and p-aminophenyl ketone such as those described in the specification of U.S. Pat. No. 3,549,367; a benzothiazole compound/trihalomethyl-s-triazine compound such as those described in JP-B No. 51-48516; and oxime ester compounds such as those described in J. C. S. Perkin II (1979) 1653-1660, J. C. S. Perkin II (1979) 156-162, Journal of Photopolymer Science and Technology (1995) 202-232, and in JP-A No. 2000-66385.

These photopolymerization initiators may be used in combination.

The content of photopolymerization initiator in the colored photosensitive composition is preferably from 0.1% by mass to 10.0% by mass, and is more preferably from 0.5% by mass to 5.0% by mass, with respect to the total solid content of the composition. When the content of the photopolymerization initiator is within the above range, a polymerization reaction proceeds well and a film with sufficient strength can be formed.

Alkali-Soluble Resin

The colored photosensitive composition used in forming the color filter layer in the invention preferably contains an alkali-soluble resin. Inclusion of an alkali-soluble resin in the colored photosensitive composition improves pattern formability when the colored photosensitive composition is applied to photolithographic pattern formation.

The alkali-soluble resin is a linear organic polymer, and may be suitably selected from alkali-soluble resins having at least one alkali-solubility promoting group (for example, a carboxyl group, a phosphoric acid group, or a sulfonic acid group) in a molecule thereof (preferably a molecule containing an acrylic copolymer or a styrene copolymer as a main chain thereof). Among these, resins which are soluble in an organic solvent and developable by a weak-alkaline aqueous solution are preferable.

The alkali-soluble resin can be produced by, for example, a known radical polymerization method. For producing the alkali-soluble resin using a radical polymerization method, polymerization conditions such as the temperature, pressure, type and amount of radical initiator, type of solvent, and the like can be easily determined by those skilled in the art, and the conditions may also be determined experimentally.

The linear organic polymer is preferably a polymer having a carboxylic acid group in a side chain thereof. Preferable examples thereof include a methacrylic acid copolymer, an acrylic acid copolymer, an itaconic acid copolymer, a crotonic acid copolymer, a maleic acid copolymer, and a partially-esterified maleic acid copolymer such as those described in JP-A No. 59-44615, JP-B Nos. 54-34327, 58-12577, and 54-25957, JP-A Nos. 59-53836, and 59-71048; an acidic cellulose derivative having carboxylic acid in a side chain thereof; a polymer having a hydroxyl group to which an acid anhydride has been added; and a polymer which has a (meth)acryloyl group in a side chain thereof

Among them, a copolymer of benzyl(meth)acrylate/(meth)acrylic acid, and a multi-component copolymer configured from benzyl(meth)acrylate/(meth)acrylic acid/another monomer are preferable. In addition, products obtained by copolymerization of 2-hydroxyethyl methacrylate can also be effectively used.

In addition, examples of the linear organic polymer include a copolymer of 2-hydroxypropyl(meta)acrylate/polystyrene macromonomer/benzyl methacrylate/methacrylic acid; a copolymer of 2-hydroxy-3-phenoxypropylacrylate/poly(methyl methacrylate)macromonomer/benzyl methacrylate/methacrylic acid; a copolymer of 2-hydroxyethyl methacrylate/polystyrene macromonomer/methyl methacrylate/methacrylic acid; and a copolymer of 2-hydroxyethyl methacrylate/polystyrene macromonomer/benzyl methacrylate/methacrylic acid such as those described in JP-A No. 7-140654.

Preferable examples of the alkali-soluble resin in the present invention include a copolymer of (meth)acrylic acid with other monomers copolymerizable therewith. Here, (meth)acrylic acid means either acrylic acid or methacrylic acid or both, and in a similar manner, (meth)acrylate is used as a term that means either acrylate or methacrylate or both.

Examples of other monomers copolymerizable with (meth)acrylic acid include alkyl(meth)acrylates, aryl(meth)acrylates, and vinyl compounds. Here, hydrogen atoms of the alkyl group and the aryl group each may independently be replaced by a substituent.

Specific examples of the alkyl(meth)acrylates and aryl(meth)acrylates include methyl(meth)acrylate, ethyl(meth)acrylate, propyl(meth)acrylate, butyl(meth)acrylate, isobutyl(meth)acrylate, pentyl(meth)acrylate, hexyl(meth)acrylate, octyl(meth)acrylate, phenyl(meth)acrylate, benzyl(meth)acrylate, tolyl(meth)acrylate, naphthyl(meth)acrylate, and cyclohexyl(meth)acrylate.

Examples of the vinyl compounds include styrene, α-methylstyrene, vinyltoluene, glycidyl methacrylate, acrylonitrile, vinyl acetate, N-vinyl pyrrolidone, tetrahydrofurfuryl methacrylate, a polystyrene macromonomer, a polymethyl methacrylate macromonomer, CH₂═CR¹R², and CH₂═C(R¹)(COOR³) (where R¹ represents a hydrogen atom or an alkyl group having 1 to 5 carbon atoms, R² represents an aromatic hydrocarbon ring having 6 to 10 carbon atoms, and R³ represents an alkyl group having 1 to 8 carbon atoms or an aralkyl group having 6 to 12 carbon atoms).

Any of these other copolymerizable monomers may be used singly or in combination of two or more kinds thereof.

Preferable examples of other copolymerizable monomers include at least one monomer selected from CH₂═CR¹R², CH₂═C(R′)(COOR³), phenyl(meth)acrylate, benzyl(meth)acrylate, and styrene, and more preferable examples include at least one monomer selected from CH₂═CR¹R² and CH₂═C(R¹)(COOR³).

The content of alkali-soluble resin in the colored photosensitive composition is preferably from 1% by mass to 20% by mass, more preferably from 2% by mass to 15% by mass, and still more preferably from 3% by mass to 12% by mass, with respect to the total solid contents of the composition.

Solvent

In general, the colored photosensitive composition for forming a color filter of the invention may be suitably prepared using a solvent, together with the above-described components.

Examples of the solvent include esters, for example, amyl formate, alkyl acetate esters (for example, ethyl acetate, n-butyl acetate, isobutyl acetate, isoamyl acetate, isobutyl acetate), butyl propionate, isopropyl butyrate, ethyl butyrate, butyl butyrate, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate and ethyl ethoxyacetate; 3-oxypropionic acid alkyl esters such as methyl 3-oxypropionate and ethyl 3-oxypropionate (for example, methyl 3-methoxypropionate, ethyl 3-methoxypropionate, methyl 3-ethoxypropionate, ethyl 3-ethoxypropionate); 2-oxypropionic acid alkyl esters such as methyl 2-oxypropionate, ethyl 2-oxypropionate and propyl 2-oxypropionate (for example, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, ethyl 2-ethoxy-2-methylpropionate); and methyl pyruvate, ethyl pyruvate, propyl pyruvate, methyl acetoacetate, ethyl acetoacetate, methyl 2-oxobutanoate, and ethyl 2-oxobutanoate;

ethers, for example, diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, ethyl carbitol acetate, butyl carbitol acetate, propylene glycol methyl ether acetate, propylene glycol ethyl ether acetate, and propylene glycol propyl ether acetate;

ketones, for example, methyl ethyl ketone, cyclohexanone, 2-heptanone, and 3-heptanone; and

aromatic hydrocarbons, for example, toluene and xylene.

Among them, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether acetate, and the like are suitable.

Any of these solvents may be used singly or in combination of two or more kinds thereof.

Other Components

The colored photosensitive composition of the invention may include, as necessary, various additives such as a sensitizing dye, an epoxy resin, a fluorine-containing organic compound, a thermal-polymerization initiator, a thermal-polymerization component, a thermal-polymerization inhibitor, a filler, a polymer compound other than the above alkali-soluble resins, a surfactant, an adhesion promoting agent, an antioxidant, an ultraviolet absorbent, and an aggregation inhibitor.

Sensitizing Dye

The colored photosensitive composition of the invention may include a sensitizing dye as needed. Exposure of the sensitizing dye to light having a wavelength which can be absorbed by this sensitizing dye promotes a radical generating reaction of the photopolymerization initiator and thus promotes a polymerization reaction of the photopolymerizable compound.

Examples of such a sensitizing dye include a known spectral sensitizing dye or colorant, and a dye or pigment which absorbs light and interacts with a photopolymerization initiator.

—Spectral Sensitizing Dye or Colorant—

Preferable examples of the spectral sensitizing dye or colorant used for the sensitizing dye that can be used in the invention include polynuclear aromatics (for example, pyrene, perylene, triphenylene); xanthenes (for example, fluorescein, eosin, erythrosine, Rhodamine B, Rose Bengal); cyanines (for example, thiacarbocyanine, oxacarbocyanine); merocyanines (for example, merocyanine, carbomerocyanine); thiazines (for example, thionine, Methylene Blue, Toluidine Blue); acridines (for example, Acridine Orange, chloroflavin, acriflavine); phthalocyanines (for example, phthalocyanine, metal phthalocyanines); porphyrins (for example, tetraphenylporphyrin, central metal-substituted porphyrins); chlorophylls (for example, chlorophyll, chlorophyllin, central metal-substituted chlorophyll); metal complexes (for example, the following compounds); anthraquinones (for example, anthraquinone); and squaryliums (for example, squarylium).

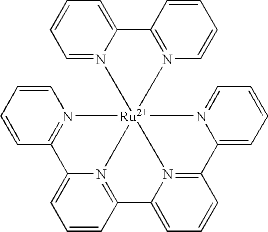

More preferable examples of the spectral sensitizing dye include cation dyes such as those described in JP-A No. 62-143044; quinoxalinium salts such as those described in JP-B No. 59-24147; novel Methylene Blue compounds such as those described in JP-A No. 64-33104; anthraquinones such as those described in JP-A No. 64-56767; benzoxanthene dyes such as those described in JP-A No. 2-1714; acridines such as those described in JP-A Nos. 2-226148 and 2-226149; pyrylium salts such as those described in JP-B No. 40-28499; cyanines such as those described in JP-B No. 46-42363; benzofuran dyes such as those described in JP-A No. 2-63053; conjugate ketone dyes such as those described in JP-A Nos. 2-85858 and 2-216154; dyes described in JP-A No. 57-10605; azocinnamylidene derivatives such as those described in JP-B No. 2-30321; cyanine-based dyes such as those described in JP-A No. 1-287105; xanthene-based dyes such as those described in JP-A Nos. 62-31844, 62-31848, and 62-143043; aminostyryl ketones such as those described in JP-B No. 59-28325; dyes such as those described in JP-A No. 2-179643; merocyanine dyes such as those described in JP-A No. 2-244050; merocyanine dyes such as those described in JP-B No. 59-28326; merocyanine dyes such as those described in JP-A No. 59-89303; merocyanine dyes such as those described in JP-A No. 8-129257; and benzopyran-based dyes such as those described in JP-A No. 8-334897.

Dye Having Absorption Maximum Wavelength in the Region of 350 nm to 450 nm

Preferable examples of the sensitizing dye include those which belong to the following classes of compounds and which have an absorption maximum wavelength in the wavelength region of 330 nm to 450 nm.

Examples thereof include polynuclear aromatics (for example, pyrene, perylene, triphenylene), xanthenes (for example, fluorescein, eosin, erythrosine, rhodamine B, Rose Bengal), cyanines (for example, thiacarbocyanine, oxacarbocyanine), merocyanines (for example, merocyanine, carbomerocyanine), thiazines (for example, thionine, Methylene Blue, Toluidine Blue), acridines (for example, Acridine Orange, chloroflavin, acriflavine), anthraquinones (for example, anthraquinone), and squaryliums (for example, squarylium).

More preferable examples of the sensitizing dye include the compounds represented by the following Formulae (i) to (v).

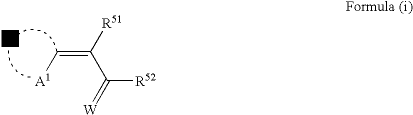

In Formula (i), A¹ represents a sulfur atom or NR⁵⁰ (where R⁵⁰ represents an alkyl group or an aryl group); L² represents a non-metal atomic group which, together with the adjacent A¹ and the adjacent carbon atom, forms a basic nucleus of a dye; R⁵¹ and R⁵² each independently represent a hydrogen atom or a monovalent non-metal atomic group; R⁵¹ and R⁵² may be bound to each other to form an acidic nucleus of a dye; and W represents an oxygen atom or a sulfur atom.

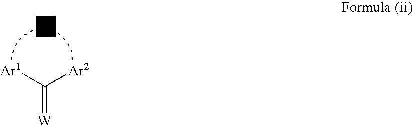

In Formula (ii), Ar¹ and Ar² each independently represent an aryl group, and are linked through a linkage formed by -L³- (where L³ represents —O— or —S—); and W has the same definition as W of Formula (i).

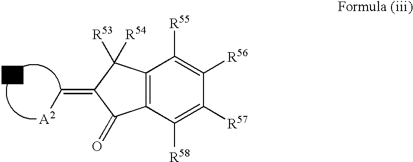

In Formula (iii), A² represents a sulfur atom or NR⁵⁹ (where R⁵⁹ represents an alkyl group or an aryl group); L⁴ represents a non-metal atomic group which, together with the adjacent A² and the carbon atom, forms a basic nucleus of a dye; and R⁵³, R⁵⁴, R⁵⁵, R⁵⁶, R⁵⁷ and R⁵⁸ each independently represent a monovalent non-metal atomic group.

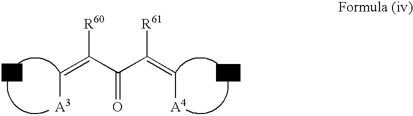

In Formula (iv), A³ and A⁴ each independently represent —S— —NR⁶²— or —NR⁶³— (where R⁶² and R⁶³ each independently represent a substituted or unsubstituted alkyl group, or a substituted or unsubstituted aryl group); L⁵ and L⁶ each independently represent a non-metal atomic group which, together with the adjacent A³ or A⁴ and the adjacent carbon atom, forms a basic nucleus of a dye; R⁶⁰ and R⁶¹ each independently represent a monovalent non-metal atomic group, or.

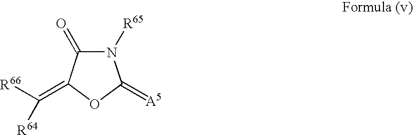

In Formula (v), R⁶⁵ represents an aromatic ring or a heterocyclic group, each of which may further have a substituent; A⁵ represents an oxygen atom, a sulfur atom, or ═NR⁶⁷; R⁶⁴, R⁶⁵, and R⁶⁷ each independently represent a hydrogen atom or a monovalent non-metal atomic group; R⁶⁷ and R⁶⁴ may be bound to each other to form an aliphatic or aromatic ring; and R⁶⁵ and R⁶⁷ may be bound to each other to form an aliphatic or aromatic ring.

Preferable specific examples of the compounds represented by Formulae (i) to (v) include the following compounds.

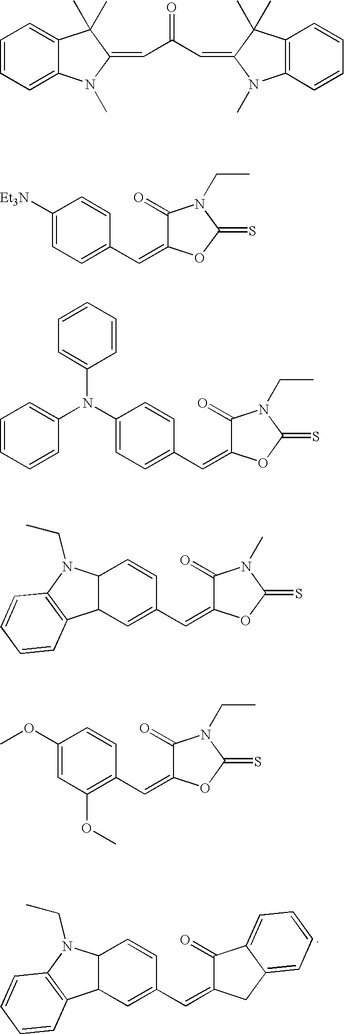

The sensitizing dyes may be modified by various chemical modifications in order to improve the properties of the colored photosensitive composition of the invention. For example, the sensitizing dye may be combined with an addition polymerizable compound structure (for example, an acryloyl group or a methacryloyl group) by a covalent bond, an ionic bond, or a hydrogen bond to improve the strength of a cross-linked curing layer and to obtain the improved effect of suppressing unwanted precipitation of the dye from the cross-linked curing layer.

The content of the sensitizing dye is preferably from 0.01% by mass to 20% by mass, more preferably from 0.01% by mass to 10% by mass, and still more preferably from 0.1% by mass to 5% by mass, with respect to the total solid content of the colored photosensitive composition.

A sensitizing dye content within the above range is preferable since it imparts high sensitivity at the exposure wavelengths of an ultrahigh pressure mercury lamp and curability of deep portions of a layer, and is also preferable with respect to development latitude and pattern formability.

Epoxy Resin

For the purpose of increasing the strength of a coated layer formed with the colored photosensitive composition of the invention, the colored photosensitive composition may include an epoxy resin as a thermal-polymerization component.

Examples of the epoxy resin include a compound having two or more epoxy rings in one molecule, such as bisphenol-A epoxy compounds, cresol novolak type epoxy compounds, biphenyl type epoxy compounds, or alicyclic epoxy compounds.

Examples of the bisphenol-A epoxy compounds include EPOTOHTO YD-115, YD-118T, YD-127, YD-128, YD-134, YD-8125, YD-7011 R, ZX-1059, YDF-8170, and YDF-170 (trade names, manufactured by Tohto Kasei Co., Ltd.); DENACOL EX-1101, EX-1102, and EX-1103 (trade name, manufactured by Nagase Chemtex Corporation); PLACCEL GL-61, GL-62, G101, and G102 (trade names, manufactured by Daicel Chemical Industries, Ltd.); and bisphenol-F epoxy compounds and bisphenol-S epoxy compounds analogous to the above bisphenol-A epoxy compounds. Epoxy acrylates, such as EBECRYL 3700, 3701, and 600 (trade names, manufactured by Daicel-Cytec Co. Ltd.) can also be used.

Examples of the cresol novolak type epoxy compounds include EPOTOHTO YDPN-638, YDPN-701, YDPN-702, YDPN-703, and YDPN-704 (trade names, manufactured by Tohto Kasei Co., Ltd.), and DENACOL EM-125 (trade name, manufactured by Nagase Chemtex Corporation).

Examples of the biphenyl type epoxy compounds include 3,5,3′,5′-tetramethyl-4,4′-diglycidyl biphenyl.

Examples of the alicyclic epoxy compounds include CELLOXIDE 2021, 2081, 2083, and 2085, EPOLEAD GT-301, GT-302, GT-401, and GT-403, and EHPE-3150 (trade names, manufactured by Daicel Chemical Industries, Ltd.); SUNTOHTO ST-3000, ST-4000, ST-5080, and ST-5100 (trade names, manufactured by Tohto Kasei Co., Ltd.); and EPICLON 430, 673, 695, 850S, 4032 (trade names, manufactured by DIC Corporation).

Other examples of epoxy compounds that can be used in the invention include 1,1,2,2-tetrakis(p-glycidyloxyphenyl)ethane, tris(p-glycidyloxyphenyl)methane, triglycidyl tris(hydroxyethyl)isocyanurate, diglycidyl o-phthalate, diglycidyl terephthalate, amine type epoxy resins such as EPOTOHTO YH-434 and YH-434L (trade names, manufactured by Tohto Kasei Co., Ltd.), and a glycidyl ester in which a bisphenol-A epoxy resin has been modified by introducing a dimer acid.

Among these resins, resins having a ratio of “molecular weight/number of epoxy rings” of 100 or more are preferable, and the ratio is more preferably from 130 to 500. When the ratio of “molecular weight/number of epoxy rings” is excessively small, curability is enhanced, but shrinkage upon curing may be significant. When the ratio of “molecular weight/number of epoxy rings” is excessively large, curability is insufficient, which may result in poor reliability and inferior flatness.

Preferable examples of such compounds include EPOTOHTO YD-115, 118T, 127, YDF-170, YDPN-638 and YDPN-701 (trade names, manufactured by Tohto Kasei Co., Ltd.); PLACCEL GL-61 and GL-62 (trade names, manufactured by Daicel Chemical Industries, Ltd.); 3,5,3′,5′-tetramethyl-4,4′-diglycidyl biphenyl; and CELLOXIDE 2021 and 2081 and EPOLEAD GT-302, GT-403 and EHPE-3150 (trade names, manufactured by Daicel Chemical Industries, Ltd.).

Fluorine-Containing Organic Compound

When a fluorine-containing organic compound is included in the colored photosensitive composition of the invention, the liquid characteristics (particularly, fluidity) of a coating solution containing the colored photosensitive composition can be improved, and thus the uniformity of the coating thickness can be improved and the amount of the coating solution can be decreased.

That is, the surface tension between the substrate and the coating solution containing the colored photosensitive composition is lowered and the wettability on the substrate is improved, whereby the coatability on the substrate is improved. Therefore, even when a thin film having a thickness of approximately a few micrometers is formed with a small amount of the solution, the fluorine-containing organic compound is effective in that a film having a uniform thickness with less thickness unevenness can be formed.

The fluorine content of the fluorine-containing organic compound is preferably from 3% by mass to 40% by mass, more preferably from 5% by mass to 30% by mass, and particularly preferably from 7% by mass to 25% by mass. A fluorine content within the above range is effective in terms of the uniformity of the coating thickness and the effects in decreasing the amount of the solution, and provides a favorable solubility in the composition.

Examples of the fluorine-containing organic compound include MEGAFAC F171, F172, F173, F177, F141, F142, F143, F144, R08, R30, and F437 (trade names, manufactured by DIC Corporation); FLUORAD FC430, FC431, and FC171 (trade names, manufactured by Sumitomo 3M, Ltd.); and SURFLON S-382, SC-101, SC-103, SC-104, SC-105, SC1068, SC-381, SC-383, S393, and KH-40 (trade name, manufactured by Asahi Glass Co., Ltd.).

The fluorine-containing organic compound is particularly effective in, for example, preventing coating unevenness or thickness unevenness when the coated layer formed by using the colored photosensitive composition of the invention is made thin. The compound is also effective in slit coating using the colored photosensitive composition of the invention, in which shortage of liquid supply could easily occur.

The addition amount of the fluorine-containing organic compound is preferably from 0.001% by mass to 2.0% by mass, and more preferably from 0.005% by mass to 1.0% by mass, relative to the total mass of the colored photosensitive composition.

Thermal Polymerization Initiator

It is also effective for the colored photosensitive composition of the invention to include a thermal polymerization initiator.

Examples of the thermal polymerization initiator include various azo compounds and peroxide compounds.

Examples of the azo compounds include azobis compounds. Examples of the peroxide compounds include ketone peroxide, peroxyketal, hydroperoxide, dialkyl peroxide, diacyl peroxide, peroxyester, and peroxydicarbonate.

Surfactant

The colored photosensitive composition of the invention is constituted preferably using various surfactants from the viewpoint of improving the coating properties. As the surfactant, various nonionic, cationic and anionic surfactants may be used as well as the above-described fluorine-containing organic compound.

Among them, fluorine-containing surfactants having a perfluoroalkyl group are preferred as the nonionic surfactants.

Specific examples of the fluorine-containing surfactants include MEGAFAC (registered trademark) Series manufactured by DIC Corporation, and FLUORAD (registered trademark) Series manufactured by 3M Company.

Specific examples of the cationic surfactants include phthalocyanine derivatives (commercially available product: EFKA-745; manufactured by Morishita Chemical Industry Co., Ltd.); organosiloxane polymer KP341 (manufactured by Shin-Etsu Chemical Co., Ltd.); (meth)acrylic (co)polymers POLYFLOW No. 75, No. 90, No. 95 (manufactured by Kyoeisha Chemical Co., Ltd.); and W001 (manufactured by Yusho Co., Ltd.).

Specific examples of the nonionic surfactants include polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid esters (such as, PLURONIC L10, L31, L61, L62, 10R5, 17R2 and 25R2, and TETRONIC 304, 701, 704, 901, 904 and 150R1; all manufactured by BASF SE).

Specific examples of the anionic surfactants include W004, W005 and W017 (Yusho Co., Ltd.);

Other Additives

The colored photosensitive composition for forming a color filter of the invention may include various additives other than the above additives.

Examples of other additives include fillers such as glass and alumina; alkali-soluble resins such as itaconic acid copolymers, crotonic acid copolymers, maleic acid copolymers, partially-esterified maleic acid copolymers, acidic cellulose derivatives, a product obtained by addition of an acid anhydride to a polymer having a hydroxyl group, alcohol-soluble nylon, and a phenoxy resin formed from bisphenol A and epichlorohydrin; polymeric dispersants such as EFKA-46, EFKA-47, EFKA-47EA, EFKA POLYMER-100, EFKA POLYMER-400, EFKA POLYMER-401, EFKA POLYMER-450 (trade names, manufactured by Morishita Chemical Industry Co., Ltd.), DISPERSE AID 6, DISPERSE AID 8, DISPERSE AID 15, and DISPERSE AID 9100 (manufactured by San Nopco, Ltd.); various SOLSPERSE dispersants such as SOLSPERSE 3000, 5000, 9000, 12000, 13240, 13940, 17000, 24000, 26000 and 28000 (available from Lubrizol Corporation); ADEKAPLURONIC L31, F38, L42, L44, L61, L64, F68, L72, P95, F77, P84, F87, P94, L101, P103, F108, L121, P-123 (manufactured by Asahi Denka Kogyo Co., Ltd.) and IONET S-20 (manufactured by Sanyo Chemical Industries, Ltd.); ultraviolet absorbents such as 2-(3-t-butyl-5-methyl-2-hydroxyphenyl)-5-chlorobenzotriazole and alkoxybenzophenone; and aggregation inhibitors such as sodium polyacrylate.

Furthermore, in the case of attempting a further improvement of the developability of the colored photosensitive composition by promoting the alkali solubility of uncured portions, an organic carboxylic acid, preferably a low molecular weight organic carboxylic acid having a molecular weight of 1000 or less, may be added to the colored photosensitive composition for forming a color filter.

Specific examples thereof include aliphatic monocarboxylic acids such as formic acid, acetic acid, propionic acid, butyric acid, valeric acid, pivalic acid, caproic acid, diethylacetic acid, enanthic acid and caprylic acid; aliphatic dicarboxylic acids such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid and citraconic acid; aliphatic tricarboxylic acids such as tricarballylic acid, aconitic acid and camphoronic acid; aromatic monocarboxylic acids such as benzoic acid, toluic acid, cuminic acid, hemimellitic acid and mesitylenic acid; aromatic polycarboxylic acids such as phthalic acid, isophthalic acid, terephthalic acid, trimellitic acid, trimesic acid, mellophanic acid and pyromellitic acid; and other carboxylic acids such as phenylacetic acid, hydroatropic acid, hydrocinnamic acid, mandelic acid, phenylsuccinic acid, atropic acid, cinnamic acid, methyl cinnamate, benzyl cinnamate, cinnamylideneacetic acid, coumaric acid and umbellic acid.

The colored photosensitive composition for forming a color filter of the invention may include a thermal polymerization inhibitor.

Examples of the thermal polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and 2-mercaptobenzimidazole.

The colored photosensitive composition for forming a color filter of the invention may be prepared by adding a photopolymerizable compound and a photopolymerization initiator to the aforementioned pigment-dispersed composition of the invention, and incorporating additives such as an alkali-soluble resin, a solvent, or a surfactant thereto as needed.

It is preferable that the colored photosensitive composition is used for forming a colored region of the color filter which is desired to have better color property.

<<Color Filter Layer and Method for Manufacturing Thereof>>

As the color filter layers of the invention, red, green and blue color filter layers are formed on a surface of an organic light-emitting device described below in detail, by using the colored photosensitive compositions described above.

Examples of the method for manufacturing the color filter layer of the invention include a process of applying the colored photosensitive composition onto an organic light-emitting device to form a colored photosensitive composition layer (colored photosensitive composition layer-forming process), a process of subjecting the colored photosensitive composition layer to pattern exposure (exposure process), and a process of developing the colored photosensitive composition layer after exposure to form a colored pattern (development process).

Hereinafter, the method for manufacturing the color filter layer will be described in detail.

A color filter with a color filter layer is produced by repeating the above-described colored photosensitive composition layer-forming process, exposure process and development process for the desired number of times, so as to form a color pattern having pixels of plural colors (for example, three colors or four colors).

Through these processes, a high-quality color filter for a liquid crystal display element or a solid image sensor can be manufactured at low cost with less difficulty imposed on the manufacture process.

Hereinafter, each process will be explained in detail.

Colored Photosensitive Composition Layer-Forming Process

Coating Process

In the colored photosensitive composition layer-forming process, first, the colored photosensitive composition of the invention is applied on a substrate to form a coated layer.

Examples of the substrate that can be used for the color filter of the invention include an alkali-free glass, soda glass, PYREX (registered trademark) glass, quartz glass and substrates each obtained by attaching a transparent conductive film to any of these materials, which are used in liquid crystal display devices and the like; photoelectric conversion element substrates that are used in image sensors, such as silicon substrate; and plastic substrates.

These substrates may have black stripes that separate the respective pixels. A transparent resin layer may be provided on these substrates in order to promote adhesion and the like.

The plastic substrates each preferably have a gas barrier layer and/or a solvent resistant layer on a surface or surfaces thereof.

A substrate for driving for a thin-film transistor (TFT) color liquid crystal display device (hereinafter, referred to as “substrate for TFT liquid crystal driving”), on which thin-film transistors (TFTs) are disposed, can be used to produce a color filter. Specifically, a colored pattern may be formed, using the colored photosensitive composition of the invention, on the substrate for driving, whereby a color filter is obtained.

Examples of the substrate used for TFT liquid crystal driving include glass, silicone, polycarbonate, polyester, aromatic polyamides, polyamidoimides, and polyimides. These substrates may be subjected to appropriate pretreatment, such as chemical treatment with a silane coupling agent or the like, plasma treatment, ion plating, sputtering, vapor phase reaction, vacuum deposition or the like, as needed. For example, a substrate can be used in which a passivation film, such as a silicon nitride film, is formed on a surface of the substrate for TFT liquid crystal driving.

In the coating process, methods of coating the colored photosensitive composition of the invention to a substrate are not particularly limited, and examples of the methods include slit coating, flow coating, roll coating and bar coating methods. A method using a slit-nozzle (hereinafter, referred to as a slit-nozzle coating method) such as a slit-and-spin coating method or a spinless coating method is preferable.

Regarding the slit-nozzle coating method, conditions for each of the slit-and-spin coating method and the spinless coating method may be varied depending on the size of the substrate to be coated. For example, when coating is conducted by a spinless coating method using a fifth generation glass substrate (1100 mm×1250 mm), the discharge amount of the colored photosensitive composition from the slit nozzle is usually from 500 microliters/second to 2000 microliters/second, and is preferably from 800 microliters/second to 1500 microliters/second, and the coating velocity is usually from 50 mm/second to 300 mm/second and preferably from 100 mm/second to 200 mm/second.

The solids content of the colored photosensitive composition used in the coating process is usually from 10% to 20%, and preferably from 13% to 18%.

When the coated layer is formed on the substrate using the colored photosensitive composition of the invention, the thickness of the coated layer (after prebaking treatment) is generally from 0.3 μm to 5.0 μm, preferably from 0.5 μm to 4.0 μm, and more preferably from 0.5 μm to 3.0 μm.

When the coated layer is used as a color filter for a solid-state image sensor, the thickness of the coated layer (after prebaking treatment) is preferably within the range of from 0.5 μm to 5.0 μm.

The coated film formed in the coating process is usually subjected to a prebaking treatment. As required, a vacuum drying treatment may also be conducted before the prebaking treatment.

The degree of vacuum applied in the vacuum drying treatment is usually from about 0.1 torr to about 1.0 torr, and preferably from about 0.2 torr to about 0.5 torr.

Prebaking of the photosensitive film applied onto the substrate may be performed at a temperature of from about 50° C. to about 140° C., preferably from about 70° C. to about 110° C., for 10 to 300 seconds with a hot plate, an oven or the like. A radio frequency treatment or the like may be used together with the prebaking treatment. The radio frequency treatment may alternatively be performed singly.

A colored photosensitive composition layer is formed as a result of the prebaking treatment.

Exposure Process

In the exposure process, the colored photosensitive composition layer formed in the photosensitive composition layer-forming process is exposed through a mask having a predetermined mask pattern.

As the radiation used at the time of exposure, particularly, ultraviolet rays such as g-line, h-line, i-line or j-line are preferable.

When manufacturing a color filter for a display device, generally, exposure is preferably performed with h-line or i-line using a proximity exposure machine or a mirror projection exposure machine.

When manufacturing a color filter using a substrate for TFT liquid crystal driving, the photomask to be used may have a pattern for forming pixels (colored pattern) and a pattern for forming a through hole and/or a rectangular-shaped depression.

Development Process

Subsequently, by performing the development treatment, the portions that have been unexposed in the exposure process dissolve into the developer solution, and only the photocured portions remain.

The development temperature is usually from 20° C. to 30° C., and the development time may be from 20 to 90 seconds.

As the developer solution, any developer solution which dissolves the layer of the colored photosensitive composition at the unexposed portions but does not dissolve the cured portions may be used.

Specifically, it is possible to use any combination of various organic solvents, or an alkaline aqueous solution.

Examples of organic solvents that can be used in the development process include the above-mentioned solvents that can be used for preparing the colored photosensitive composition of the invention.

As the alkaline aqueous solution, for example, it is preferable to use an alkaline aqueous solution prepared by diluting an alkaline compound such as sodium hydroxide, potassium hydroxide, sodium carbonate, sodium hydrogen carbonate, sodium silicate, sodium metasilicate, ammonia water, ethylamine, diethylamine, dimethylethanolamine, tetramethylammonium hydroxide, tetraethylammonium hydroxide, choline, pyrrole, piperidine, or 1,8-diazabicyclo-[5.4.0]-7-undecene, with pure water to a concentration of from 0.001% by mass to 10% by mass, preferably from 0.01% by mass to 1% by mass.

At least one of a water soluble organic solvent, such as methanol or ethanol, a surfactant or the like may be added, in a suitable amount, to the alkaline aqueous solution.

As the developing method, any one of a dip method, a shower method, and a spray method can be used, and these methods may be combined with at least one of a swing method, a spin method, an ultrasonic method, and the like. The surface to be developed may be wetted with water or the like before the developer solution is brought into contact therewith in order to prevent uneven development. The development may be performed on an inclined substrate.

After the development process, rinsing treatment may be performed to remove excess developer solution by washing, followed by drying, and further followed by heat treatment (post-baking) to achieve thorough curing.

Although pure water is usually used for the rinsing treatment, consumption of the pure water may be reduced by at least one of the following methods: (i) using used water, which was originally pure water, in an initial washing stages and then using pure water in a final washing stage; (ii) performing washing on an inclined substrate; (iii) performing washing while applying ultrasound irradiation.

After the rinsing, draining and drying treatment, heat treatment (post-baking) is usually performed at 100° C. to 250° C. This post-baking is a post-development heat treatment for achieving thorough curing, and is preferably performed at 200° C. to 250° C. (hard baking).

This post-baking treatment on the coated layer after development may be performed in a continuous mode or batch mode, using a heating means such as a hot plate, a convection oven (hot air circulation type dryer) or a high frequency heater, such that the above-described condition is satisfied.

A color filter layer having cured films of plural colors (a colored pattern) may be produced by sequentially repeating the above-described processes for the respective colors, in accordance with the desired number of colors.

<<Organic Light-Emitting Device>>

The organic light-emitting device of the invention is a light-emitting device having a peak wavelength (λ1) with the maximum emission intensity in the range of from 430 nm to 480 nm, or a light-emitting device having a first emission intensity peak wavelength (λ1′) in the range of from 430 nm to 480 nm, a second emission intensity peak wavelength (λ2) in the range of from 500 nm to 550 nm, and a third emission intensity peak wavelength (λ3) in the range of from 600 nm to 650 nm, and when used as an organic display device including color filters, the display device has excellent color properties and transmittance.

The light-emitting device that can be used in the invention includes at least an anode, an organic compound layer including an emitting layer and a cathode disposed in this order on a supporting substrate, the emitting layer further including a blue light-emitting material having an emission wavelength peak in the range of from 400 nm to 500 nm, a green light-emitting material having an emission wavelength peak in the range of from 500 nm to 570 nm and a red light-emitting material having an emission wavelength peak in the range of from 580 nm to 670 nm.

The display device of the invention may have a configuration in which, for example, a color filter layer, a TFT circuit, an organic EL layer, and a common electrode are superposed in this order on a transparent substrate.

As the transparent substrate, glass or plastic may be used. For example, polyethylene terephthalate (PET), polyethylene naphthalate (PEN), polyether sulfone (PES) and polyimide (PI) can be used. When the transparent substrate is plastic, a barrier film of SiO₂, SiON, Al₂O₃, Y₂O₃ or the like is preferably arranged thereon to prevent permeation of moisture and oxygen.

The color filter layers contain at least RGB color filter layers, among which the green color filter layer contains the specific pigment described above.

The layer configuration of the color filter layers is not limited to a configuration containing RGB color filter layers, and may contain RGGB color filter layers or RGBW color filter layers. Herein, W indicates white and a white color filter layer can be used only when the organic EL layer emits white light.

The RGB color filter layers each may be a usual transmission band-limiting type color filter (a color filter that shields or reduces light in a specific wavelength region) or may be a color conversion type color filter which receives blue light and converts it into red or green. The bandpass color filter is a resist having a pigment dispersed therein, and the color conversion type color filter is a resist having a fluorescent pigment mixed therein. These color filters can be formed by exposure, development and baking, similar to usual negative-working resists. Details thereof are as described above.

The TFT circuit used in the invention has for example two or more TFTs and one or more capacitors and may be driven by voltage or current. Alternatively, other known TFT circuit structures may be used.

In the invention, an oxide semiconductor may be used as a semiconductor layer of a TFT. The oxide semiconductor is transparent, so that when transparent materials are used in electrodes and insulating layers, the TFT can be made transparent and reduction in an aperture ratio can be prevented. Conventional amorphous Si and poly-Si require a high-temperature (200° C. or above) process when a film thereof is formed. On the other hand, oxide semiconductors operate well in many cases even when a film thereof is formed at a low temperature such as from room temperature to 200° C., and all subsequent processes (photolithographic process and processes of forming an organic EL layer and a common electrode) may also be carried out at 200° C. or less, and so there is an advantage that the color filter layer may be less damaged by heat. Further, when the color filter layer is prepared at 200° C. or less, plastic can be used as the substrate to prepare a flexible EL display.

All TFT semiconductor layers in a conventional TFT circuit are formed on a single plane. In contrast, when oxide semiconductors are used, inexpensive sputtering can be used, and therefore, two or more oxide semiconductor layers can be used in which conditions for forming the oxide semiconductors may differ from layer to layer, as a result of which the degree of freedom of circuit design is increased. For example, when a scanning TFT semiconductor and a driving TFT semiconductor are formed as separate layers, the properties of the scanning TFT and the properties of the driving TFT may be appropriately made different from each other, such that, for example, the scanning TFT is a TFT with a low off-current and the driving TFT is a TFT with a large on-current. Alternatively, one of the TFTs may be of n-type and the other may be of p-type. Depending on the circuit, necessity for the formation of an opening in a first and/or second insulating layer is eliminated, whereby reliability can be increased and processes can be simplified.

As the oxide semiconductor, an oxide containing at least one element selected from In, Ga, Zn, Sn and Mg can be used. Specific examples of the oxide include indium oxide, zinc oxide, tin oxide, ZnMg oxide, InGaZn oxide, InₓZn₁₋ₓ oxide, InₓSn₁₋ₓ oxide, Inₓ(Zn, Sn)₁₋ₓ oxide, GaSn oxide, InGaSn oxide, and InGaZnMg oxide. Films of these materials can be formed by sputtering, laser abrasion, vapor deposition, or the like.

Particularly, when a film of InGaZn oxide is formed by sputtering at any temperature of from room temperature to 200° C. or less can attain a carrier mobility of at least 5 cm²/Vs easily and reproducibly, and is thus a preferable material. InGaZnMg oxide has a carrier mobility similar to that of InGaZn oxide and is highly resistant to UV rays (does not often malfunction) because of its large band gap. The InGaZn oxide has a compositional ratio where In:Ga:Zn:O is approximately 1:1:1:4. However, in actuality, there are oxygen holes in the InGaZn oxide. Therefore, a slight change in the metal composition does not result in a change in the characteristics thereof, so that a compositional ratio within the range, “In:Ga:Zn:O=(0.7 to 1.3):(0.7 to 1.3):(0.7 to 1.3):(3 to 4)”, is acceptable.

The oxide is basically in an amorphous state, but may partially contain a microcrystal structure. The InGaZnMg oxide is the same as the InGaZn oxide except that a part (50% or less) of Zn is replaced by Mg. Sputtering is preferably RF or DC reactive sputtering.

As an electrode, indium tin oxide (ITO), indium zinc oxide (IZO) or the like is preferably used.

As an insulating layer, an oxide or nitride film is preferably used, such as a film of a silicon oxide SiOx, a silicon nitride SiNx, aluminum oxide Al₂O₃, a tantalum oxide TaOx, yttrium oxide Y₂O₃ or a tantalum nitride TaNx.

Films of these materials can be formed by sputtering, laser abrasion, vapor deposition, or the like at a temperature of from room temperature to 200° C. Particularly, reactive sputtering is preferable. After a film is formed, post-annealing may be conducted. The temperature of this post-annealing is preferably 200° C. or less.

In the invention, a transparent organic insulating layer may be used. For example, fluorine resin, polyvinyl alcohol, epoxy, acrylic or the like may be used. When a photosensitive resin is used, patterning is facilitated. Further, different kinds of insulating layers may be superposed on each other.

When transparent materials are used in each of the electrodes, the semiconductor and the insulating layers, the whole of the resultant TFT circuit can be made transparent to increase an aperture ratio. When patterning the electrodes, the semiconductor and the insulating layers, photolithography and etching is used in which the photolithographic process is conducted usually at 120° C. or less and the etching process is conducted usually at several tens of ° C. or less.

The organic EL layer is formed on a pixel electrode. As the organic EL layer, a layered structure including a hole transport layer and a light-emitting layer is usually used.

Examples of the material constituting the hole transport layer include electroconductive polymer materials such as polyaniline derivatives, polythiophene derivatives, polyvinyl carbazole derivatives, and a mixture of poly(3,4-ethylenedioxythiophene) and polystyrenesulfonic acid (PEDOT:PSS).

The hole transport material may be dissolved or dispersed in toluene, xylene, acetone, methyl ethyl ketone, methyl isobutyl ketone, cyclohexanone, methanol, ethanol, isopropyl alcohol, ethyl acetate, butyl acetate or water, or in a mixed solvent thereof, and then applied by spin coating, bar coating, wire coating or slit coating. Patterning may be conducted as necessary.

If necessary, a surfactant, an antioxidant, a viscosity regulator, a UV absorbent or the like may be added to the hole transport layer. The thickness of the hole transport layer is preferably in the range of from 10 nm to 200 nm. Low-molecular materials such as TPD (triphenyldiamine) or α-NPD (bis[N-naphthyl-N-phenyl]benzidine) may be used as a hole transport material.

An emitting layer is superposed on the hole transport layer. The emitting layer is not limited to a single-layer structure and may be a multilayer structure provided with a charge transport layer or the like. The emitting layer includes an organic light-emitting material soluble in an organic solvent, such as: a coumarin light-emitting material, a perylene light-emitting material, a pyran light-emitting material, an anthrone light-emitting material, a polyphylline light-emitting material, a quinacridone light-emitting material, an N,N′-dialkyl-substituted quinacridone light-emitting material, a naphthalimide light-emitting material, an N,N′-diaryl-substituted pyrrolopyrrole light-emitting material or an iridium complex light-emitting material; or a material in which any of these organic light-emitting materials is dispersed in a polymer such as polystyrene, polymethyl methacrylate or polyvinyl carbazole; or a polymeric light-emitting material such as a polyarylene light-emitting material, a polyarylene vinylene light-emitting material, or a polyfluorene light-emitting material.

The polymeric light-emitting material may be dissolved or dispersed in toluene, xylene, acetone, methyl ethyl ketone, methyl isobutyl ketone, cyclohexanone, methanol, ethanol, isopropyl alcohol, ethyl acetate, butyl acetate or water, or in a mixed solvent thereof, and then applied by spin coating, curtain coating, bar coating, wire coating or slit coating. The emitting layer may be formed alternatively by printing.

As necessary, at least one of a surfactant, an antioxidant, a viscosity regulator, a UV absorbent, and the like may be added to a layer of the polymeric light-emitting material.

The total thickness of the emitting layer is preferably in the range of 1000 nm or less, and more preferably from 50 nm to 150 nm, regardless of whether the emitting layer has a monolayer structure or a multilayer structure.

Other examples of an emitting layer material include a low-molecular light-emitting material in which an aluminum-quinoline complex or a distyryl derivative is doped with quinacridone, a coumarin derivative, rubrene, a DCM (4-(dicyanomethylene)-2-methyl-6-(p-dimethylaminostyryl)-4H-pyran) derivative, perylene, or an iridium complex.

The emission color of the low-molecular light-emitting material is determined by the material itself and the dopant contained therein. For blue emission, a distyrylarylene derivative doped with a styrylarylene derivative or with a styrylamine derivative may be used; for green emission, an aluminum-quinoline complex may be used; for red emission, an aluminum-quinoline complex doped with DCM may be used; and for white emission, a structure containing a blue light-emitting material and a yellow to orange light-emitting material are superposed on each other may be used. The emission color of the polymeric light-emitting material can be regulated by replacement of a side chain thereof, and polymers having the same fundamental skeleton may be used for all of the RGB colors. By mixing them, white light can be obtained.

When the organic EL layer is formed by an shadow-mask patterning method and the emitting layer includes a low-molecular light-emitting material, the emitting layer may be formed by mask vapor-deposition, in which case shadow-mask patterning of RGB emitters onto a large area in a uniform manner is difficult. When the emitting layer includes a polymeric light-emitting material, the emitting layer may be formed using a printing method, with which shadow-mask patterning of RGB emitters onto a large area in a uniformly manner is possible. Examples of the printing method include ink-jet printing, reverse printing, and flexographic printing. In particular, flexographic printing is preferable owing to its capability of uniform printing on a large area in a short time. The substrate temperature may be room temperature regardless of whether the method used is mask vapor-deposition or a printing method such as ink-jet printing, reverse printing or flexographic printing.

The common electrode may be selected in accordance with the emission properties of the organic EL layer. Examples of the electrode material include a metal as a simple substance such as lithium, magnesium, calcium, ytterbium or aluminum, an alloy thereof, and an alloy thereof with a stable metal such as gold or silver may be used. These materials can be disposed by a vacuum vapor deposition method with usual resistance heating or EB heating. The coating thickness is not particularly limited, but is preferably in the range of from 1 nm to 500 nm. A thin film of lithium fluoride may be disposed between the cathode and the emitting layer. Further, a protective layer including an insulating inorganic material or a resin may be disposed on the cathode. During these processes, the substrate temperature may be room temperature.

Hereinafter, the method for manufacturing the color EL display of the invention will be described in more detail by reference to the drawings.

Preparation of Color Filter Layer

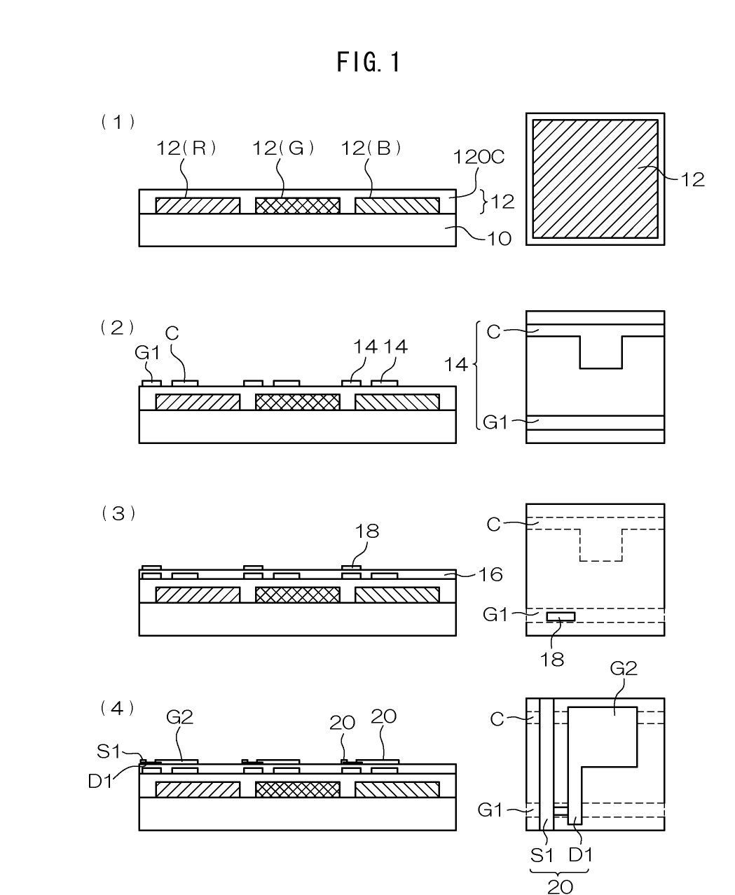

A glass plate was used as a transparent substrate 10, on which color filter layer 12 was formed by application of a pigment-dispersed resist, followed by exposure, development and baking (step (1) of FIG. 1). 12 (R), 12 (G) and 12 (B) indicate red, green and blue color filter layers, respectively, and 12OC indicates an overcoat layer.

Exposure and development are not necessary for the overcoat layer 12OC. The baking temperature was 220° C.

In this manner, color filter layer 12 was formed.

Subsequently, as a first electrode layer 14 containing a gate electrode G1 and a capacitor electrode C, a film of ITO was formed by reactive sputtering (room temperature, DC sputtering) with ITO as the target in an Ar+O₂ gas, and then patterned by application of a photoresist, exposure, development, wet etching with hydrochloric acid, and separation of the resist (step (2) of FIG. 1). Then, a film of SiON was formed as a first insulating layer 16 by reactive sputtering (room temperature, RF sputtering) with SiN as the target in an Ar+O₂+N₂ gas, and, successively, a film of an InGaZn oxide was formed as a first semiconductor layer 18 by reactive sputtering (room temperature, RF sputtering) with InGaZnO₄ as the target in an Ar+O₂ gas, and the first semiconductor layer 18 was patterned by application of a photoresist, exposure, development, wet etching with hydrochloric acid, and separation of the resist (step (3) of FIG. 1).

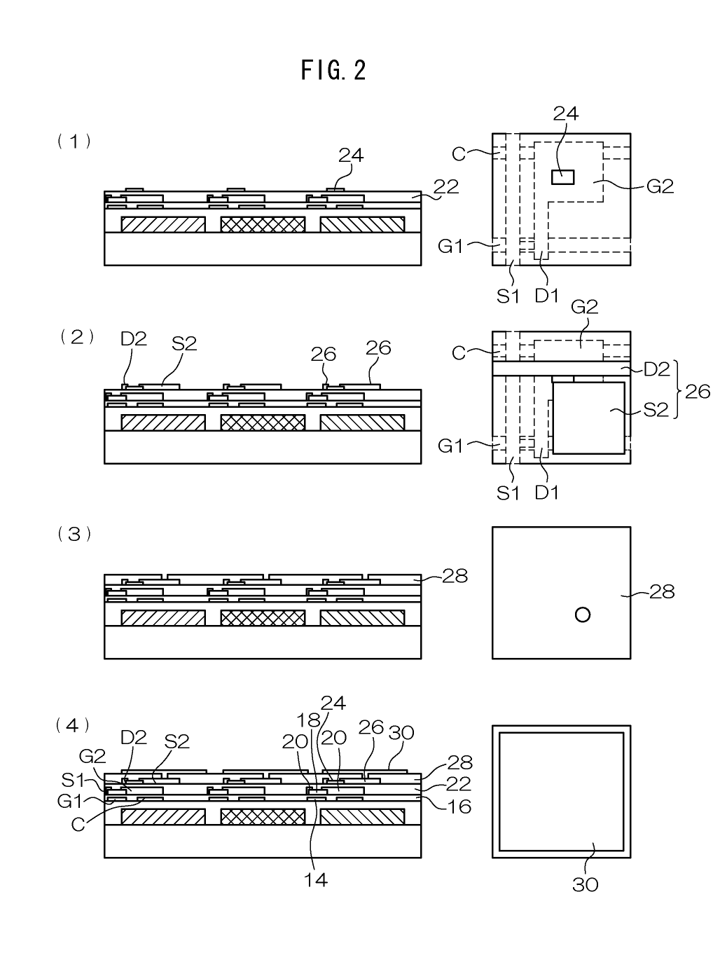

After formation of the photoresist pattern, a film of ITO was formed as a second electrode layer 20 containing a source electrode S1 and a gate electrode G2 also serving as a drain electrode D1 by the same reactive sputtering as for the first electrode layer 14, and then patterned by lift-off (step (4) of FIG. 1). Then, a film of SiON was formed as a second insulating layer 22, and, successively, a film of InGaZn oxide was formed as a second semiconductor layer 24 by reactive sputtering, and the second semiconductor layer 24 was patterned by application of a photoresist, exposure, development, wet etching with hydrochloric acid, and separation of the resist (step (1) of FIG. 2).

The flow rate of O₂ during formation of the second semiconductor layer 24 was lower than in formation of the first semiconductor layer 18. After formation of the photoresist pattern, a film of ITO was formed as a third electrode layer 26 containing a source electrode S2 and a drain electrode D2 by reactive sputtering and then patterned by lift-off (step (2) of FIG. 2).

After formation of a photoresist pattern on the source electrode S2 for the third electrode layer 26, a film of SiON was formed as a third insulating layer 28 by reactive sputtering, the source electrode S2 was patterned to have an opening by lift-off, and then a photosensitive acrylic resin was applied, exposed and developed, thereby forming a two-layer insulating film (step (3) of FIG. 2). Further, a film of ITO was formed as a fourth electrode layer 30 and then patterned by application of a photoresist, exposure, development, wet etching with hydrochloric acid, and separation of the resist (step (4) of FIG. 2). Here, the fourth electrode layer serves as a pixel electrode.

Thereafter, an organic EL layer 32 is formed.

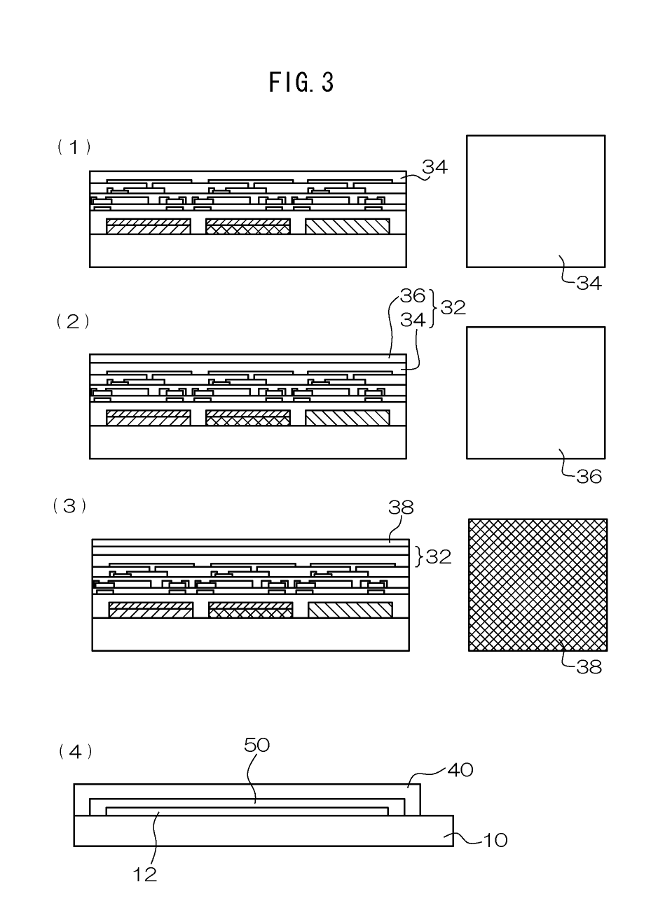

First, an aqueous solution of PEDOT:PSS was spin-coated as a hole transport layer 34 onto the whole of the above surface and baked at 110° C. (step (1) of FIG. 3). Then, LED-b5 manufactured by Nichia Corporation was spin-coated thereon as an emitting layer 36 and baked at 100° C. (step (2) of FIG. 3).

As a common electrode 38, calcium and silver were deposited to form 10 nm and 300 nm films respectively on the whole surface by vapor deposition (step (3) of FIG. 3). Finally, the whole body of a laminated body 50 consisting of members designated herein by reference numerals 16 to 38 was covered with sealing glass 40 (step (4) of FIG. 3).

The display device of the invention is provided with the organic light-emitting device and the color filter layer containing the specific pigments, thereby achieving high transmittance and excellent color reproducibility.

The organic light-emitting device in the display device of the invention is not limited to the above-described embodiments, and may be any organic EL device having the emission properties described above. For example, excellent effects of the invention are produced also when an organic EL device having a micro-cavity structure and having the maximum emission intensity in the wavelength range of from 500 nm to 600 nm is used in combination with the color filter layer containing the specific pigments according to the invention.

### EXAMPLES

Hereinafter, the present invention will be described more specifically by way of Examples, but the invention is not intended to be limited to the following Examples. Further, “parts” and “%” are on a mass basis unless mentioned otherwise.

First, a preparation method of a pigment-dispersed composition used for forming a color filter layer is shown.

In the following Tables 1 and 2, the structures of pigment derivatives and dispersants used in the Examples are shown.

TABLE 1

| Pigment | |
|---|---|
| Derivative | Structure |
| a | 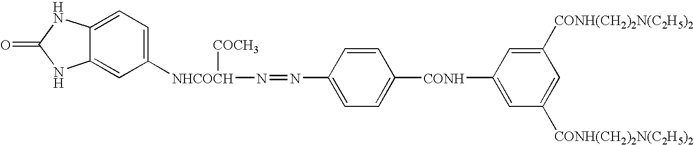 |
| b | 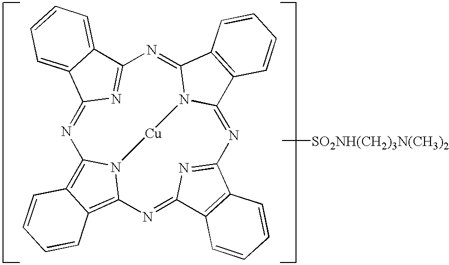 |
| c | 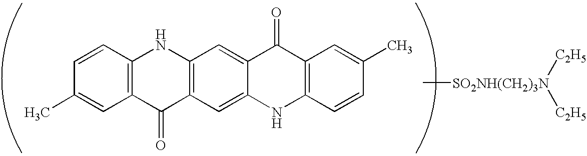 |

TABLE 2

| Dispersant | Structure | M.W. |
|---|---|---|
| I | 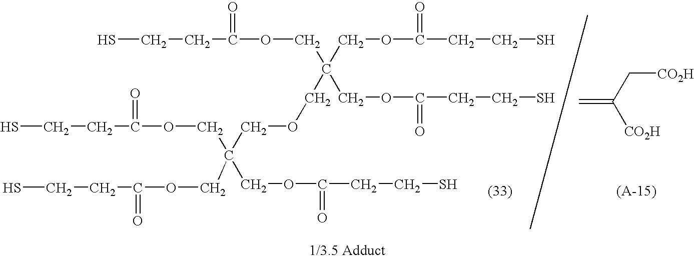 | 10,000 |
| II | BzMA/MMA = 70/30 wt % | 10,000 |

BzMA/MMA: benzyl methacrylate/methacrylic acid copolymer

<Preparation of Green Pigment-Dispersed Composition (I)>

Dispersion Composition (1)

| | |
|---|---|
| C.I. Pigment Green 7 (PG7) | 13.50 parts |
| Pigment derivative (b) (the above structure) | 1.50 parts |
| Dispersant I (the above structure) solution in propylene | 30.00 parts |
| glycol monomethyl ether acetate (solid content: | |
| 30% by mass) | |
| Propylene glycol monomethyl ether acetate | 55.00 parts |

The dispersion composition (1) was stirred for 1 hour using a homogenizer at a rotation speed of 3,000 rpm, to prepare a mixed solution. The obtained mixed solution was subjected to a dispersion treatment for 3 hours with a bead disperser (trade name: DISPERMAT, manufactured by Getzmann GmbH) using zirconia beads having a diameter of 0.3 mm to obtain a pigment-dispersed composition (1).

<Pigment-Dispersed Composition (2)>

Pigment-dispersed composition (2) was prepared in the same manner as the pigment-dispersed composition (1), except that C.I. Pigment Green 7 of pigment-dispersed composition (1) was replaced by an aluminum phthalocyanine (above Structural Formula (II)).

<Pigment-Dispersed Composition (3)>

Pigment-dispersed composition (3) was prepared in the same manner as the pigment-dispersed composition (1), except that C.I. Pigment Green 7 of pigment-dispersed composition (1) was replaced by C.I. Pigment Green 36.

<Pigment-Dispersed Composition (4)>

Pigment-dispersed composition (4) was prepared in the same manner as the pigment-dispersed composition (1), except that C.I. Pigment Green 7 and the pigment derivative (b) of pigment-dispersed composition (1) were replaced by C.I. Pigment Yellow 150 and a pigment derivative (a), respectively.

<Pigment-Dispersed Composition (5)>

Method for Manufacturing Treated Pigment 1 by Salt Milling

98 g of Pigment Yellow 185 (primary particle diameter under TEM: 45 nm, hereinafter referred to sometimes as PY185), 1000 g of sodium chloride (average particle diameter 10 μm), and 2 g of a pigment derivative (a) were introduced into a kneader (manufactured by INOUE MFG., INC.), then charged with 200 g of diethylene glycol, and kneaded for 8 hours at a temperature kept at 50° C.

The resulting kneaded product was introduced into heated water (about 12 L) and stirred with a high-speed mixer for about 1 hour under heating at about 80° C. to form slurry which was then filtered and washed with water to remove the sodium chloride and solvent, and then dried in a hot-air oven at 80° C. for about 24 hours to give a treated pigment 1.

<Preparation of Pigment-Dispersed Composition>

A pigment-dispersed composition was prepared as follows.

Composition (1)

| | |
|---|---|
| Treated pigment 1 obtained above | 13.78 parts |
| Pigment derivative (a) (the above structure) | 1.22 parts |
| Dispersant I (the above structure) solution in propylene | 30.00 parts |
| glycol monomethyl ether acetate (solid content: 30% | |
| by mass) | |
| Propylene glycol monomethyl ether acetate | 55.00 parts |

The composition (1) was stirred for 1 hour using a homogenizer at a rotation speed of 3,000 rpm, to prepare a mixed solution. The obtained mixed solution was subjected to a dispersion treatment for 3 hours with a bead disperser (trade name: DISPERMAT, manufactured by Getzmann GmbH) using zirconia beads having a diameter of 0.3 mm to obtain a pigment-dispersed composition (5).

<Pigment-Dispersed Composition (6)>

Pigment-dispersed composition (6) was prepared in the same manner as the pigment-dispersed composition (5), except that the amounts of PY 185 and pigment derivative (a) in manufacturing treated pigment 1 were changed to 95 g and 5 g, respectively, and that the amounts of treated pigment 1 and pigment derivative (a) in composition (1) were changed to 14.21 parts and 0.79 parts, respectively.

<Pigment-Dispersed Composition (7)>

Pigment-dispersed composition (7) was prepared in the same manner as the pigment-dispersed composition (5), except that pigment derivative (a) in manufacturing treated pigment 1 was replaced by pigment derivative (c).

<Pigment-Dispersed Composition (8)>

Pigment-dispersed composition (8) was prepared in the same manner as the pigment-dispersed composition (5), except that pigment derivative (a) in manufacturing treated pigment 1 was replaced by pigment derivative (c) and that dispersant I solution was replaced by dispersant II solution in propylene glycol monomethyl ether acetate (solid content: 30% by mass).

<Pigment-Dispersed Composition (9)>

Pigment-dispersed composition (9) was prepared in the same manner as the pigment-dispersed composition (5), except that treated pigment 1 (including PY185) was replaced by untreated PY185.

<Pigment-Dispersed Composition (10)>

Pigment-dispersed composition (10) was prepared in the same manner as the pigment-dispersed composition (5), except that dispersant I solution was replaced by dispersant II solution in propylene glycol monomethyl ether acetate (solid content: 30% by mass).

—Measurement and Evaluation of Viscosity—

With respect to the obtained pigment-dispersed composition, the viscosity η¹ of the pigment-dispersed composition immediately after the dispersing, and the viscosity η² of the pigment-dispersed composition after the pigment-dispersed composition is left at room temperature for one week from the dispersing, were measured using an E type viscometer, and the degree of viscosity increase was evaluated. Here, a lower viscosity indicates suppression of viscosity increase caused by dispersants and suggests better dispersibility and dispersion stability.

The results are shown in Table 3 below. As shown in Table 3, in the pigment-dispersed compositions (1) to (7) and (9) containing the specific pigment derivative of the invention and the specific dispersant of the invention, excellent dispersibility and dispersion stability were obtained.

TABLE 3

| | Primary Particle | Pigment | Viscosity | |
|---|---|---|---|---|
| | Diameter of | Derivative/ | (mPa · s) | |
| | Pigment (nm) | Dispersant | η1 | η2 |
| Pigment-Dispersed Composition (1) | 35 | b/I | 12.8 | 13.3 |
| Pigment-Dispersed Composition (2) | 35 | b/I | 14.3 | 15.2 |
| Pigment-Dispersed Composition (3) | 30 | b/I | 10.7 | 10.9 |
| Pigment-Dispersed Composition (4) | 25 | a/I | 18.2 | 19.5 |
| Pigment-Dispersed Composition (5) | 30 | a/I | 15.2 | 15.3 |
| Pigment-Dispersed Composition (6) | 19 | a/I | 18.6 | 19.2 |
| Pigment-Dispersed Composition (7) | 30 | c/I | 16.8 | 17.5 |
| Pigment-Dispersed Composition (8) | 30 | c/II | 34.6 | 42.1 |
| Pigment-Dispersed Composition (9) | 45 | a/I | 14.8 | 15.0 |
| Pigment-Dispersed Composition (10) | 45 | a/II | 28.3 | 32.5 |

Hereinafter, the method for manufacturing the display device of the invention will be described with reference to FIG. 1 to FIG. 3.

### (Preparation of a Color Filter Layer)

A glass plate was used as a transparent substrate 10, on which a color filter layer 12 was formed by application of pigment-dispersed resists, followed by exposure, development and baking (step (1) of FIG. 1). 12 (R), 12 (G) and 12 (B) indicate red, green and blue color filter layers, respectively, and 12OC indicates an overcoat layer.

The overcoat layer 12OC was formed by applying a coating solution and then drying the coating without conducting exposure and development. Thereafter, the coating was baked at a temperature of 220° C. In this manner, the color filter layer 12 containing the overcoat layer 12OC was formed on the substrate 10.

(Green Color Filter Layer)

In formation of the color filter layer described above, the following colored photosensitive composition (G) was used as a coating liquid for green color filter layer 12 (G).

Composition of Coating Solution (G)

### Example 1

| | | |
|---|---|---|
| Pigment-dispersed composition (1) | 30.80 | parts |
| Pigment-dispersed composition (5) | 19.10 | parts |
| Polymerizable compound: dipentaerythritol hexaacrylate | 5.30 | parts |
| Alkali-soluble resin: solution of benzyl methacrylate/ | 3.50 | parts |
| methacrylic acid copolymer = 75/25 (mass ratio) (weight- | | |
| average molecular weight Mw: 1000) in propylene glycol | | |
| monomethyl ether acetate (solid content: 45% | | |
| by mass) | | |
| Photopolymerization initiator: 1,3-bistrihalomethyl-5- | 3.00 | parts |
| benzooxolan triazine | | |
| Photopolymerization initiator: 2-benzyl-2-dimethylamino-1- | 2.00 | parts |
| (4-morpholinophenyl)-butan-1-one | | |
| Photopolymerization initiator: diethylthioxanthone | 1.00 | part |
| Epoxy resin (trade name: EHPE-3150, manufactured by | 1.00 | part |
| Daicel Chemical Industries, Ltd.) | | |
| Polymerization inhibitor: p-methoxyphenol | 0.001 | parts |
| Fluorine-containing surfactant (trade name: MEGAFAC | 0.02 | parts |
| R08, manufactured by DIC Corporation) | | |
| Solvent: propylene glycol monomethyl ether acetate | 34.80 | parts |

In Examples 2 to 8 and Comparative Examples 1 to 6, each of colored photosensitive compositions was prepared in the same manner as in Example 1 except that the kinds and quantity ratios of the pigment-dispersed compositions were changed as shown in Table 4 and the amounts of the alkali-soluble resin and the solvent were adjusted such that the respective total solids contents were the same as that of Example 1.

<Formation of Pixels>

The obtained colored photosensitive composition (G) was spin-coated on a glass substrate such that the thickness of the coated layer after pre-baking was 3.0 μm, and then dried for 80 seconds on a hot plate at 100° C. (pre-baking). Thereafter, the whole surface of the coated layer was exposed via a mask at a dose of 200 mJ/cm² (illuminance: 20 mW/cm²). The coated layer after exposure was developed with a 1% aqueous solution of an alkali developer solution CDK-1 (manufactured by FUJIFILM Electronic Materials Co., Ltd.) by spraying the developer solution like a shower. Thereafter, the developer solution was washed away by spraying pure water like a shower. Then, the coated layer, which had been cured by exposure and developed as described above, was subjected to a heat treatment in an oven at 220° C. for 30 minutes (post-baking), to thereby form a colored resin coated layer (a colored pattern) for a color filter layer on the glass substrate. Thus, a substrate having the colored resin coated layer (colored substrate) was prepared.

<Formation of Overcoat Layer>

An overcoat layer was formed on the colored substrate using the following composition.

| | |
|---|---|
| Acrylic resin containing a polymerizable unsaturated | 7.50 parts |
| group (thermosetting resin component) [butyl methacrylate/ | |
| methacrylic acid/methacrylic acid-epoxycyclohexylmethyl | |
| methacrylate adduct (= 20/8/72 [molar ratio]) copolymer | |
| having an acid value 15 mg KOH/g, a polymerizable | |
| unsaturated group equivalent (eq) of 298, and a weight- | |
| average molecular weight 8600] | |
| Ethyl ethoxy propionate/propylene glycol monomethyl | 150.00 parts |
| ether acetate (= 40/60 [mass ratio]) | |
| Fluorine-containing surfactant (trade name: MEGAFAC | 0.02 parts |
| R08, manufactured by DIG Corporation) | |

Exposure and development were not necessary for the overcoat layer. The overcoat layer was subjected to a heat treatment in an oven at 220° C. for 10 minutes (post-baking).

In this manner, the color filter layer 12 was formed.

<Evaluation of Colored Pattern>

Evaluation of Developability

With respect to the colored pattern formed as described above, the developability of a non-image region was confirmed at 20,000-fold magnification under a scanning electron microscope (SEM), and the number of granular residues remaining in the non-image region was determined to evaluate the developability according to the following criteria:
A: The number of observed granular residues is 5 or less.
B: The number of observed granular residues is 6 to 10.
C: The number of observed granular residues is 11 or more.

Subsequently, as a first electrode layer 14 containing a gate electrode G1 and a capacitor electrode C, a film of ITO was formed by reactive sputtering (room temperature, DC sputtering) with ITO as the target in an Ar+O₂ gas, and then patterned by application of a photoresist, exposure, development, wet etching with hydrochloric acid, and separation of the resist (step (2) of FIG. 1). Then, a film of SiON was formed as a first insulating layer 16 by reactive sputtering (room temperature, RF sputtering) with SiN as the target in an Ar+O₂+N₂ gas, and, successively, a film of InGaZn oxide was formed as a first semiconductor layer 18 by reactive sputtering (room temperature, RF sputtering) with InGaZnO₄ as the target in an Ar+O₂ gas, and the first semiconductor layer 18 was patterned by application of a photoresist, exposure, development, wet etching with hydrochloric acid, and separation of the resist (step (3) of FIG. 1).

After formation of the photoresist pattern, a film of ITO was formed as a second electrode layer 20 containing a source electrode S1 and a gate electrode G2 also serving as a drain electrode D1 by the same reactive sputtering as for the first electrode layer 14, and then patterned by lift-off(step (4) of FIG. 1). Then, a film of silicon oxynitride (SiON) was formed as a second insulating layer 22, and, successively, a film of InGaZn oxide was formed as a second semiconductor layer 24 by reactive sputtering, and the second semiconductor layer 24 was patterned by application of a photoresist, exposure, development, wet etching with hydrochloric acid, and separation of the resist (step (1) of FIG. 2).

The flow rate of O₂ during formation of the second semiconductor layer 24 was lower than the flow rate of O₂ during the formation of the first semiconductor layer 18. After formation of the photoresist pattern, a film of ITO was formed as a third electrode layer 26 containing a source electrode S2 and a drain electrode D2 by reactive sputtering and then patterned by lift-off (step (2) of FIG. 2).

After formation of a photoresist pattern on the source electrode S2 of the third electrode layer 26, a film of SiON was formed as a third insulating layer 28 by reactive sputtering, and was patterned to have an opening at the source electrode S2 by lift-off, and then a photosensitive acrylic resin was applied, exposed and developed, thereby forming a two-layer insulating film (step (3) of FIG. 2). Further, a film of ITO was formed as a fourth electrode layer 30 and then patterned by application of a photoresist, exposure, development, wet etching with hydrochloric acid, and separation of the resist (step (4) of FIG. 2). Here, the fourth electrode layer serves as a pixel electrode.

Thereafter, an organic EL layer 32 is formed.

First, an aqueous solution of PEDOT:PSS was spin-coated as a hole transport layer 34 onto the whole surface and baked at 110° C. (step (1) of FIG. 3). Then, LED-b5 manufactured by Nichia Corporation was spin-coated thereon as an emitting layer 36 and baked at 100° C. (step (2) of FIG. 3).

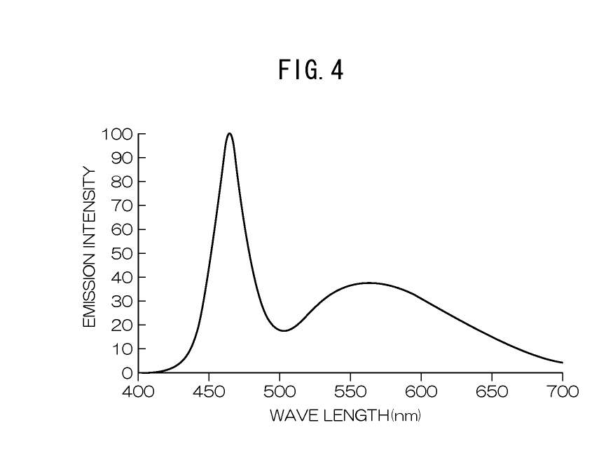

The emission spectrum of the obtained organic EL device is shown in FIG. 4. As is evident from FIG. 4, this organic EL device is a light-emitting device having a peak wavelength (λ1) with the maximum emitting intensity in the range of from 430 nm to 480 nm.

As a common electrode 38, calcium and silver were deposited to form 10 nm and 300 nm films, respectively, on the whole of the above surface by vapor deposition (step (3) of FIG. 3). Finally, the whole body of a laminated body 50 consisting of members designated herein by reference numerals 16 to 38 was covered with sealing glass 40 to give a display device (step (4) of FIG. 3).

Hereinabove, all processes after formation of the TFT circuit were carried out at a temperature of 200° C. or less.

—Panel Evaluation—

The display device obtained above was subjected to panel evaluation to evaluate color property and transmittance. The results are shown in Table 4.

Using a Source-Measure Unit 2400 (manufactured by Toyo Corporation), a DC voltage was applied to the organic EL device to cause light emission.

Using SR-3 (manufactured by KONICA MINOLTA), the chromaticity and transmittance of the light-emitting panel were evaluated by measurement of the y value and the Y value.

—Color Reproducibility—

Color reproducibility was evaluated according to the following criteria. Here, a higher y value indicates superior color reproducibility.
A: Chromaticity can be adjusted to a value of y=0.68.
B: Chromaticity cannot be adjusted to a value of y=0.68.

—Transmittance—

Transmittance was evaluated according to the following criteria. Here, a higher Y value indicates a higher transmittance.
A: Y=28.5 or more
B: Y=less than 28.5

### Examples 2 to 12, Comparative Examples 1 and 2

Display devices in Example 2 to 12 and Comparative Examples 1 and 2 were prepared and evaluated in the same manner as in Example 1 except that the colored photosensitive composition (G) used in Example 1 was changed to the compositions shown in Table 4. The results are shown in Table 4.

TABLE 4

| | Color Filter Layer (3 μm) | | | Colored | | | | | | |
|---|---|---|---|---|---|---|---|---|---|---|
| | | | Pigment | Photosensitive | Panel Evaluation | | | | | |
| | | Dispersion | Conc. | Composition | Color Property | | | Color | | |
| | Pigment Ratio | Composition | (%) | Developability | x | y | Y | Reproducibility | Transmittance | Remarks |
| Example 1 | PG7/PY185 = 100/62 | 1/5 | 34 | A | 0.230 | 0.680 | 32.3 | A | A | |
| Example 2 | Aluminum | 2/5 | 25 | A | 0.230 | 0.680 | 32.5 | A | A | |
| | phthalocyanine/ | | | | | | | | | |
| | PY185 = 100/126 | | | | | | | | | |
| Example 3 | PG7/PY185 = 100/52 | 1/6 | 32 | A | 0.230 | 0.680 | 30.1 | A | A | |
| Example 4 | Aluminum | 2/6 | 30 | A | 0.230 | 0.680 | 29.5 | A | A | |
| | phthalocyanine/ | | | | | | | | | |
| | PY185 = 100/36 | | | | | | | | | |
| Example 5 | PG7/PY185 = 100/49 | 1/7 | 32 | B | 0.230 | 0.680 | 29.8 | A | A | |
| Example 6 | Aluminum | 2/7 | 30 | B | 0.230 | 0.680 | 29.3 | A | A | |
| | phthalocyanine/ | | | | | | | | | |
| | PY185 = 100/35 | | | | | | | | | |
| Example 7 | PG7/PY185 = 100/50 | 1/8 | 34 | A | 0.230 | 0.680 | 32.4 | A | A | |
| Example 8 | Aluminum | 2/8 | 26 | A | 0.230 | 0.680 | 32.4 | A | A | |
| | phthalocyanine/ | | | | | | | | | |
| | PY185 = 100/130 | | | | | | | | | |
| Example 9 | PG7/PY185 = 100/48 | 1/9 | 33 | A | 0.230 | 0.680 | 28.1 | A | B | Slightly low Y |
| | | | | | | | | | | value |
| Example 10 | Aluminum | 2/9 | 29 | A | 0.230 | 0.680 | 27.7 | A | B | Slightly low Y |
| | phthalocyanine/ | | | | | | | | | value |
| | PY185 = 100/24 | | | | | | | | | |
| Example 11 | PG7/PY185 = 100/45 | 1/10 | 32 | B | 0.230 | 0.680 | 27.8 | A | B | Slightly low Y |
| | | | | | | | | | | value |
| Example 12 | Aluminum | 2/10 | 45 | B | 0.230 | 0.680 | 27.5 | A | B | Slightly low Y |
| | phthalocyanine/ | | | | | | | | | value |
| | PY185 = 100/23 | | | | | | | | | |
| Comparative | PG36/PY150 = 100/10 | 3/4 | 70 | C | 0.230 | 0.637 | 34.9 | B | A | y value is too |
| Example 1 | | | | | | | | | | low to design |
| | | | | | | | | | | color |
| Comparative | PG36/PY185 = 100/5 | 3/5 | 70 | C | 0.230 | 0.643 | 33.2 | B | A | y value is too |
| Example 2 | | | | | | | | | | low to design |
| | | | | | | | | | | color |

As is evident from Table 4, the display devices in Examples 1 to 12 having color filter layers using a combination of specific pigments were excellent in pattern formability of the colored photosensitive composition used, and the formed color filter layers were excellent in color reproducibility and showed high transmittance even at a relatively low pigment concentration. It is also understood that the effects are conspicuous when the particle diameter of the pigment is 10 nm to 40 nm or when the specific pigment derivative and the specific dispersant are contained.

The invention provides a display device including an organic EL device and a color filter with high transmittance and excellent color reproducibility.

All publications, patent applications, and technical standards mentioned in this specification are herein incorporated by reference to the same extent as if each individual publication, patent application, or technical standard was specifically and individually indicated to be incorporated by reference.

What is claimed is:

1. A display device, comprising an organic light-emitting device and red, green and blue color filter layers, wherein each of the color filter layers comprises a pigment, a pigment derivative and a dispersant, the pigment contained in a colored pattern constituting the green color filter layer contains Pigment Yellow 185 and at least one of an aluminum phthalocyanine or Pigment Green 7, and the concentration of the pigment in the green filter layer is 60% or less.

2. The display device according to claim 1, wherein the organic light-emitting device is a light-emitting device having a peak wavelength (λ1) with the maximum emission intensity in the range of from 430 nm to 480 nm, or a light-emitting device having a first emission intensity peak wavelength (λ1′) in the range of from 430 nm to 480 nm, a second emission intensity peak wavelength (λ2) in the range of from 500 nm to 550 nm, and a third emission intensity peak wavelength (λ3) in the range of from 600 nm to 650 nm.

3. The display device according to claim 1, wherein the average particle diameter of primary particles of Pigment Yellow 185 is from 10 nm to 40 nm.

4. The display device according to claim 3, wherein the average particle diameter of primary particles of the at least one of an aluminum phthalocyanine or Pigment Green 7 is from 10 nm to 40 nm.

5. The display device according to claim 1, wherein the total content of C.I. Pigment Yellow 185, aluminum phthalocyanine and C.I. Pigment Green 7 is 30 parts by mass or more with respect to the total amount of pigment contained in the green color filter layer.

6. The display device according to claim 1, wherein the pigment derivative is a compound represented by the following Formula (1):
A-N═N—X—Y Formula (1)
wherein in Formula (1), A represents a component which can form an azo dye together with X—Y, wherein X represents a single bond or a group selected from divalent linking groups represented by the following structural formulae, and Y represents a group represented by the following Formula (2): 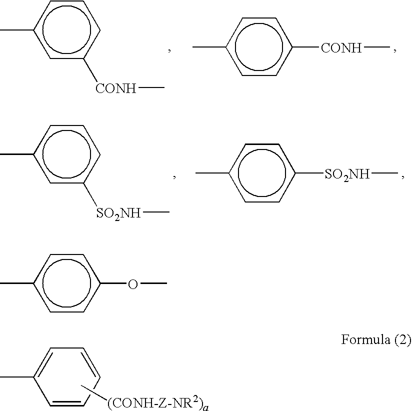
wherein in Formula (2), Z represents an alkylene group having 1 to 5 carbon atoms, —NR² represents a dialkylamino group in which each alkyl group has 1 to 4 carbon atoms, or a saturated 5- to 6-membered heterocyclic group containing a nitrogen atom, and a represents 1 or 2.

7. The display device according to claim 1, wherein the dispersant is a polymer compound represented by the following Formula (3): 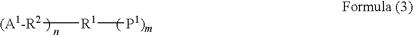
wherein in Formula (3), R¹ represents an organic linking group having a valency of (m+n), R² represents a single bond or a divalent organic linking group; A¹ represents a monovalent organic group containing at least one moiety selected from an organic dye structure, a heterocyclic structure, an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group and a hydroxyl group; each A¹, the number of which is n, may be the same as or different from each other; each R², the number of which is n, may be the same as or different from each other; m represents 1 to 8 and n represents 2 to 9 provided m+n represents 3 to 10; P¹ represents a polymer skeleton; and each P¹, the number of which is m, may be the same as or different from each other.

8. The display device according to claim 1, wherein the aluminum phthalocyanine is represented by the following Structural Formula (II):

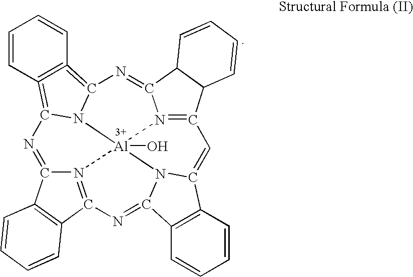

9. The display device according to claim 1, wherein the total content of aluminum phthalocyanine or Pigment Green 7 in the green color filter layer is from 5 parts by mass to 200 parts by mass with respect to 100 parts by mass of Pigment Yellow 185.
